(19) United States
(12) Patent Application Publication
(10) Pub. No.: US 2007/0029676 A1
(43) Pub. Date: Feb. 8, 2007

(54) Semiconductor device and method for manufacturing the same

(76) Inventors: Norikatsu Takaura, Tokyo (JP); Nozomu Matsuzaki, Kokubunji (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/489,668

(22) Filed: Jul. 20, 2006

(30) Foreign Application Priority Data
Aug. 2, 2005 (JP) JP2005-224389

(51) Int. Cl. H01L 23/52

(52) U.S. Cl. 257/758

(57) ABSTRACT

A resistor element formed of a peel-preventive film, a recording layer made of chalcogenide, and an upper electrode film is formed on a semiconductor substrate, first and second insulation films are formed so as to cover the resistor element, a via hole for exposing the upper electrode film is formed through the first and second insulation films, and a plug for electrical connection to the upper electrode film is formed in the via hole. To form the via hole, the first insulation film made of silicon nitride is used as an etching stopper to perform dry etching on the second insulation film. Then, dry etching is performed on the first insulation film to expose the upper electrode film from the via hole.

### CROSS-REFERENCE TO RELATED APPLICATION

The present application claims priority from Japanese Patent Application No. JP 2005-224389 filed on Aug. 2, 2005, the content of which is hereby incorporated by reference into this application.

### TECHNICAL FIELD OF THE INVENTION

The present invention relates to semiconductor devices and semiconductor device manufacturing methods and, particularly, to a technology effective when applied to a semiconductor device including a phase-change memory and a method of manufacturing such a semiconductor device.

### BACKGROUND OF THE INVENTION

In a non-volatile semiconductor storage device for data storage, various schemes for storing data in a memory cell can be adopted. In one scheme, a phase-change memory is utilized, which is a non-volatile memory using a phase-change film.

The phase-change memory is a non-volatile memory in which information to be stored is written, with a crystalline state of a storage element being changed in accordance with Joule heat generated by a current flowing the storage element itself. A write current tends to be large because a recording layer is once melted at the time of amorphization by heating with Joule heat to a temperature over 600 degrees Celsius, and a resistance value is changed by as much as two to three orders of magnitude depending on the crystalline state. Since the resistance value is used in this memory as a signal, a large read signal and an easy sensing operation can be achieved.

U.S. Pat. No. 5,883,827 discloses a technology regarding a phase-change memory.

According to the structure of the phase-change memory of FIG. 12 in U.S. Pat. No. 5,883,827, the phase-change memory includes a memory array, row decoders XDEC, bit (column) decoders YDEC, read circuits RC, and write circuits WC. The memory array has a memory cell MCpr disposed at a point of intersection of a word line WLp (p=1, . . . , n) and a data line DLr (r=1, . . . , m). Each memory cell is configured such that a storage element R and a select transistor QM connected in series are inserted between the bit line DL and the ground potential. The word line WL is connected to the gate of the select transistor, whilst a bit selection line YSr (r=1, . . . , m) is connected to a corresponding bit selection switch QAr respectively.

With such a structure, the select transistor on the word line selected by the row decoder XDEC becomes conductive, and the bit selection switch corresponding to the bit selection line selected by the bit decoder YDEC becomes conductive, thereby forming a current path in the selected memory cell to generate a read signal on a common bit line I/O. Since the resistance value of the selected memory cell may vary depending on the storage information, the voltage output to the common bit line I/O may vary depending on the storage information. Such variations are detected by the read circuit RC, thereby reading the storage information of the selected memory cell.

The phase-change memory uses a chalcogenide material, such as a Ge—Sb—Te group containing antimony (Sb), germanium (Ge), and tellurium (Te), as recording layer (phase-change layer) material. Characteristics of the phase-change memory using such a chalcogenide material have also been reported (for example, refer to IEEE International Electron Devices meeting, TECHNICAL DIGEST, (US), 2001, pp. 803-806).

According to studies by the inventors of the present invention, the following has been revealed.

In the phase-change memory, high integration of memory cells, enhancement of yield of memory cell bits, and improvement in the number of rewritable times have been demanded. To achieve these, improvement in reliability is important.

The phase-change memory is configured such that an upper electrode film made of tungsten is formed on a recording layer (phase-change film) made of chalcogenide and, on an interlayer insulation film covering the above-mentioned components, a via hole and a plug embedded therein are formed on the upper electrode film to connect the plug to the upper electrode film. With this, a predetermined voltage can be applied to the upper electrode film and the recording layer from wiring via the plug.

However, when the via hole for forming the plug is formed on the upper electrode film, the upper electrode film may be thinned at the bottom of the via hole due to over-etching. Since the thinned portion of the upper electrode film has an increased resistance value, this will cause variations in resistance value of a resistor element formed of the recording layer and the upper electrode film. Moreover, the thinned portion of the upper electrode film is susceptible to etching damage at the time of dry etching and heat-load damage at the time of forming a conductive film for plug. With this, the characteristics of the recording layer in an area immediately below the thinned portion tend to be changed, thereby decreasing a multiple rewrite cycle, for example. This will cause deterioration in reliability of electrical characteristics of the phase-change memory. A reason for deterioration in reliability of the electrical characteristics is that the chalcogenide material for use in the phase-change memory has a crystalline temperature of approximately 400 degrees Celsius and a melting point of approximately 625 degrees Celsius, both of which are lower than those of the material for use in the conventional memory technology.

Also, when the via hole for forming the plug is formed on the upper electrode film, the occurrence of misalignment (alignment deviation) may cause a sidewall of the recording layer (phase-change film) to be exposed from the via hole. The recording layer with its sidewall exposed from the via hole may be damaged by heat hysteresis at the time of forming a metal film for forming a plug in that via hole to deteriorate the characteristics as the phase-change material. In particular, the exposed recording layer may be partially sublimated. For example, the plug can be formed from a conductive barrier film made of titanium nitride or the like and a tungsten film. With the film-forming temperature of the conductive barrier film being, for example, approximately 500 degrees Celsius or higher, and the sublimation temperature of the chalcogenide in vacuum being approximately 400 degrees Celsius, sublimation of the recording layer made of chalcogenide occurs from the exposed sidewall. Sublimation of the recording layer made of chalcogenide will cause open-bit defects or variations in resistance value of an element. Such a problem of open-bit defects in the phase-change memory occurs because the phase-change material has an easy-to-sublimate property due to the sublimation temperature of chalcogenide as low as approximately 400 degrees Celsius. This problem does not occur in materials with a high sublimation temperature for use in the conventional memory technology, and seems to be newly discovered by the inventors.

Due to these problems, there are possibilities of decreasing reliability of a semiconductor device having a phase-change memory.

### SUMMARY OF THE INVENTION

An object of the present invention is to provide a technology capable of improving reliability of semiconductor devices.

The above and other objects and novel characteristics of the present invention will be apparent from the description of this specification and the accompanying drawings.

The typical ones of the inventions disclosed in this application will be briefly described as follows.

The present invention is directed to a semiconductor device in which an interlayer insulation film is formed so as to cover a laminated pattern having a recording layer and an upper electrode film on the recording layer, an opening is formed on the interlayer insulation film so as to expose at least a part of the upper electrode film, and a conductive portion electrically connected to the upper electrode film is formed in the opening, wherein a first insulation film is formed on an upper surface of the upper electrode film other than the part exposed from the opening, and below the interlayer insulation film, the first insulation film being thinner than the interlayer insulation film and being made of a material different from a material of the interlayer insulation film.

Also, in the present invention, a laminated pattern having a recording layer and an upper electrode film on the recording layer, and a first insulation film positioned on an upper surface of the upper electrode film are formed; an interlayer insulation film is formed so as to cover the laminated pattern; with the first insulation film being used as an etching stopper film, dry etching is performed on the interlayer insulation film to form an opening on the interlayer insulation film; dry etching is performed on the first insulation film exposed from the opening to expose at least a part of the upper electrode film from the opening; and a conductive portion is formed in the opening for electrical connection to the upper electrode film.

Furthermore, a semiconductor device according to the present invention includes: a laminated pattern having a recording layer formed on an insulation film and an upper electrode film on the recording layer; another insulation film formed so as to cover the lamination pattern; a first conductive portion formed in an opening of the insulation film and electrically connected to a lower surface side of the recording layer; and a second conductive portion formed in an opening of the other insulation film and electrically connected to the upper electrode film, wherein the first conductive portion and the second conductive portion are disposed so as to be prevented from being two-dimensionally overlaid with each other.

The effects obtained by typical aspects of the present invention will be briefly described below.

According to the present invention, reliability of semiconductor devices can be improved.

Also, manufacturing yield of semiconductor devices can be enhanced.

### BRIEF DESCRIPTIONS OF THE DRAWINGS

FIG. 1 is a plan view of a schematic structure of a semiconductor device according to a first embodiment of the present invention;

FIG. 2 is a circuitry diagram depicting an example of the structure of a memory array in a phase-change memory area in the semiconductor device according to the first embodiment of the present invention;

FIG. 3 is a plan view depicting a plan layout corresponding to the array structure of FIG. 2;

FIG. 4 is a cross-section view of main parts of the semiconductor device according to the first embodiment of the present invention;

FIG. 5 is a table for describing a correlation between the state of a phase-change film of the phase-change memory and the resistance of the phase-change film;

FIG. 6 is a graph for describing the operation of the phase-change memory;

FIG. 7 is another graph of describing the operation of the phase-change memory;

FIG. 8 is a graph for schematically describing operation principles of a storage element using a chalcogenide material;

FIG. 9 is a diagram for describing read operation timing of the memory array;

FIG. 10 is a diagram for describing write operation timing of the memory array;

FIG. 11 is a cross-section view of main parts of the semiconductor device according to the first embodiment of the present invention during a manufacturing process;

FIG. 12 is a cross-section view of the main parts of the semiconductor device during the manufacturing process continued from FIG. 11;

FIG. 13 is a cross-section view of the main parts of the semiconductor device during the manufacturing process continued from FIG. 12;

FIG. 14 is a cross-section view of the main parts of the semiconductor device during the manufacturing process continued from FIG. 13;

FIG. 15 is a cross-section view of the main parts of the semiconductor device during the manufacturing process continued from FIG. 14;

FIG. 16 is a cross-section view of the main parts of the semiconductor device during the manufacturing process continued from FIG. 15;

FIG. 17 is a cross-section view of the main parts of the semiconductor device during the manufacturing process continued from FIG. 16;

FIG. 18 is a cross-section view of the main parts of the semiconductor device during the manufacturing process continued from FIG. 17;

FIG. 19 is a cross-section view of the main parts of the semiconductor device during the manufacturing process continued from FIG. 18;

FIG. 20 is a cross-section view of the main parts of the semiconductor device during the manufacturing process continued from FIG. 19;

FIG. 21 is a cross-section view of the main parts of the semiconductor device during the manufacturing process continued from FIG. 20;

FIG. 22 is a cross-section view of the main parts of the semiconductor device during the manufacturing process continued from FIG. 21;

FIG. 23 is a cross-section view of main parts of a semiconductor device according to a first comparative example during a manufacturing process;

FIG. 24 is a cross-section view of the main parts of the semiconductor device according to the first comparative example during the manufacturing process continued from FIG. 23;

FIG. 25 is a cross-section view of the main parts of the semiconductor device according to the first comparative example during the manufacturing process continued from FIG. 24;

FIG. 26 is a cross-section view of main parts of a semiconductor device according to another comparative example during a manufacturing process;

FIG. 27 is a cross-section view of main parts of a semiconductor device according to a second comparative example during a manufacturing process;

FIG. 28 is a cross-section view of the main parts of the semiconductor device according to the second comparative example during the manufacturing process continued from FIG. 27;

FIG. 29 is another cross-section view of other main parts of the semiconductor device according to the first embodiment of the present invention during a manufacturing process;

FIG. 30 is a cross-section view of the other main parts of the semiconductor device during the manufacturing process continued from FIG. 29;

FIG. 31 is a cross-section view of the other main parts of the semiconductor device during the manufacturing process continued from FIG. 30;

FIG. 32 is another cross-section view of the other main parts of the semiconductor device during the manufacturing process continued from FIG. 29;

FIG. 33 is another cross-section view of the other main parts of the semiconductor device during the manufacturing process continued from FIG. 32;

FIG. 34 is a cross-section view of the main parts of the semiconductor device during the manufacturing process continued from FIG. 33;

FIG. 35 is a cross-section view of main parts of a semiconductor device according to a second embodiment of the present invention during a manufacturing process;

FIG. 36 is a cross-section view of the main parts of the semiconductor device during the manufacturing process continued from FIG. 35;

FIG. 37 is a cross-section view of the main parts of the semiconductor device during the manufacturing process continued from FIG. 36;

FIG. 38 is a cross-section view of the main parts of the semiconductor device during the manufacturing process continued from FIG. 37;

FIG. 39 is a cross-section view of the main parts of the semiconductor device during the manufacturing process continued from FIG. 38;

FIG. 40 is a cross-section view of the main parts of the semiconductor device during the manufacturing process continued from FIG. 39;

FIG. 41 is a cross-section view of main parts of a semiconductor device according to a third embodiment of the present invention during a manufacturing process;

FIG. 42 is a cross-section view of the main parts of the semiconductor device during the manufacturing process continued from FIG. 41;

FIG. 43 is a cross-section view of main parts of a semiconductor device according to a fourth embodiment of the present invention during a manufacturing process;

FIG. 44 is a cross-section view of the main parts of the semiconductor device during the manufacturing process continued from FIG. 43;

FIG. 45 is a cross-section view of the main parts of the semiconductor device during the manufacturing process continued from FIG. 44;

FIG. 46 is a cross-section view of the main parts of the semiconductor device during the manufacturing process continued from FIG. 45;

FIG. 47 is a cross-section view of the main parts of the semiconductor device during the manufacturing process continued from FIG. 46;

FIG. 48 is a cross-section view of the main parts of the semiconductor device during the manufacturing process continued from FIG. 47;

FIG. 49 is a cross-section view of the main parts of the semiconductor device during the manufacturing process continued from FIG. 48;

FIG. 50 is a cross-section view of the main parts of the semiconductor device during the manufacturing process continued from FIG. 49;

FIG. 51 is another cross-section view of other main parts of the semiconductor device according to the fourth embodiment of the present invention during a manufacturing process;

FIG. 52 is a cross-section view of the other main parts of the semiconductor device during the manufacturing process continued from FIG. 51;

FIG. 53 is a cross-section view of the other main parts of the semiconductor device during the manufacturing process continued from FIG. 52;

FIG. 54 is a cross-section view of the other main parts of the semiconductor device during the manufacturing process continued from FIG. 53;

FIG. 55 is a cross-section view of main parts of a semiconductor device according to a fifth embodiment of the present invention during a manufacturing process;

FIG. 56 is a cross-section view of the main parts of the semiconductor device during the manufacturing process continued from FIG. 55;

FIG. 57 is a cross-section view of main parts of a semiconductor device according to a sixth embodiment of the present invention during a manufacturing process;

FIG. 58 is a cross-section view of the main parts of the semiconductor device during the manufacturing process continued from FIG. 57;

FIG. 59 is a cross-section view of the main parts of the semiconductor device during the manufacturing process continued from FIG. 58;

FIG. 60 is a cross-section view of the main parts of the semiconductor device during the manufacturing process continued from FIG. 59;

FIG. 61 is a cross-section view of the main parts of the semiconductor device during the manufacturing process continued from FIG. 60;

FIG. 62 is a cross-section view of the main parts of the semiconductor device during the manufacturing process continued from FIG. 61;

FIG. 63 is a cross-section view of main parts of a semiconductor device according to a seventh embodiment of the present invention;

FIG. 64 is a partially-enlarged cross-section view of an area near a resistor element of the semiconductor device of FIG. 63; and

FIG. 65 is a plan view of main parts of the area near the resistor element of the semiconductor device of FIG. 63.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted. Also, in principle, in the embodiments described below, the same or similar portions are not repeatedly described unless otherwise required. Furthermore, in the drawings for use in the embodiments, hatching may be omitted even from a section view for the sake of drawing visibility. Still further, hatching may be provided even to a plan view for the sake of drawing visibility.

### First Embodiment

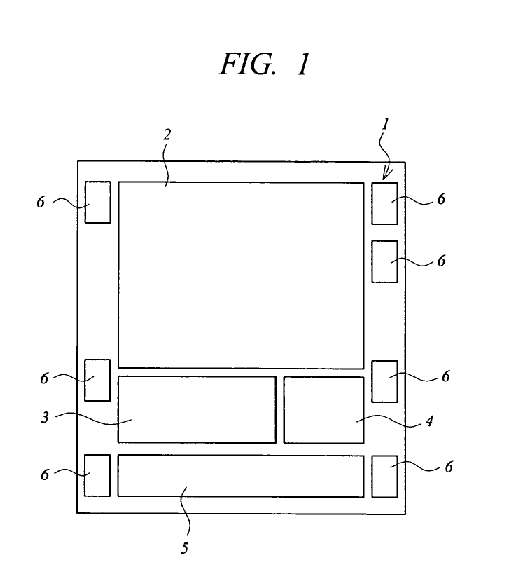

A semiconductor device and semiconductor device manufacturing method according to a first embodiment is described with reference to drawings. FIG. 1 is a plan view (plan layout or chip layout) of a schematic structure of a semiconductor device (non-volatile semiconductor storage device or semiconductor chip) according to the first embodiment of the present invention;

A semiconductor device (semiconductor chip) 1 according to the present invention is a semiconductor device (semiconductor storage device) including a phase-change memory (phase-change non-volatile memory, PCM (Phase Change Memory), OUM (Ovonic Unified Memory)), which is a phase-change non-volatile memory (non-volatile storage element).

As shown in FIG. 1, the semiconductor device 1 according to the present invention has a phase-change memory area 2 having formed therein a memory cell array of phase-change memory. Furthermore, the semiconductor device 1 includes, as required, a RAM area 3 having formed therein a RAM (Random Access Memory) circuit, such as DRAM (Dynamic RAM) or SRAM (Static RAM), a CPU area 4 having formed therein a logic circuit, such as a CPU or MPU, an analog circuit area 5 having formed therein an analog circuit, an I/O area 6 having formed therein an input/output circuit, and other areas.

In the phase-change memory area 2, as one of main circuits of the semiconductor device 1, a non-volatile memory for storing a relatively large amount of information is formed of a phase-change memory, which is a phase-change non-volatile memory. The phase-change memory is a non-volatile memory configured so that a recording layer (that corresponds to a recording layer 45, which will be described further below) of each memory cell is phase-changed between an amorphous state and a crystalline state to change its resistivity (resistance value), thereby changing a passing current of each memory cell at the time of access depending on the stored information. In the phase-change memory, the phase state of this recording layer (phase-change film) (that is, whether the phase-change film is in an amorphous state or a crystalline state) represents the stored information and, with the passing current of the selected memory cell to be accessed, the stored information of the selected memory cell can be read at the time of access.

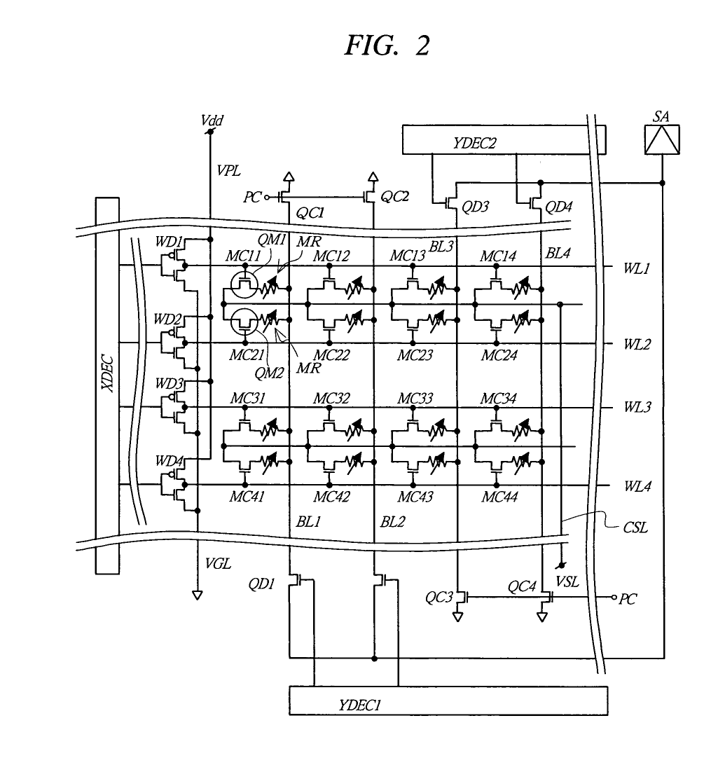

Next, an example of the memory array of the phase-change memory area 2 is described with reference to a circuitry diagram of FIG. 2.

The structure of the memory array shown in FIG. 2 is known as an NOR type, which allows high-speed reading, and is therefore suitable for storing a system program and is used as a single memory chip or combined with logical LSI in a microcomputer or the like. In FIG. 2, for the sake of brevity of the drawing, only a part of the array is shown, including four word lines WL1 to WL4 and four bit lines BL1 to BL4. MC11 to MC14 represent four memory cells connected to WL1. Similarly, MC21 to MC24, MC31 to MC34, and MC41 to MC44 represent memory cells connected to WL2 to WL4, respectively. BL1 represents a bit line to which the memory cells MC11, MC21, MC31, and MC41 are connected. Similarly, the memory cells MC12, MC22, MC32, and MC42 are connected to the bit line BL2, the memory cells MC13, MC23, MC33, and MC43 are connected to the bit line BL3, and the memory cells MC14, MC24, MC34, and MC44 are connected to the bit line BL4.

Each memory cell is formed of one MISFET (corresponding to either one of a MISFET QM1 and a MISFET QM2, which will be described further below) and a storage element or memory material MR (corresponding to a recording layer 52 or a resistor element 54 including the recording layer 52, which will be described further below) connected in series to the MISFET. Each of the word lines (WL1 to WL4) is connected to the gate electrode of each MISFET forming the memory cell. Each of the bit lines (BL1 to BL4) is connected to each memory material MR forming the memory cell. The word lines WL1 to WL4 are driven by word drivers WD1 to WD4, respectively. Which of the word drivers WD1 to WD4 is selected is determined by a signal from a row decoder (X address decoder) XDEC.

VPL represents a power supply line to each word driver, and a power supply voltage is represented by Vdd. VGL represents a potential drawing line of each word driver and is herein fixed to the ground potential. QD1 represents a select transistor for pre-charging the bit line BL1. Similarly, QD2 to QD4 are select transistors for pre-charging the bit lines BL2 to BL4, respectively. Each of the select transistors (QD1 to QD4) are selected in accordance with an address input through a bit decoder YDEC1 or a bit decoder YDEC2. In this example, the bit decoder YDEC1 and a bit decoder YDEC2 are alternately in charge of two consecutive selected bit lines. An output by reading is detected by a sense amplifier SA.

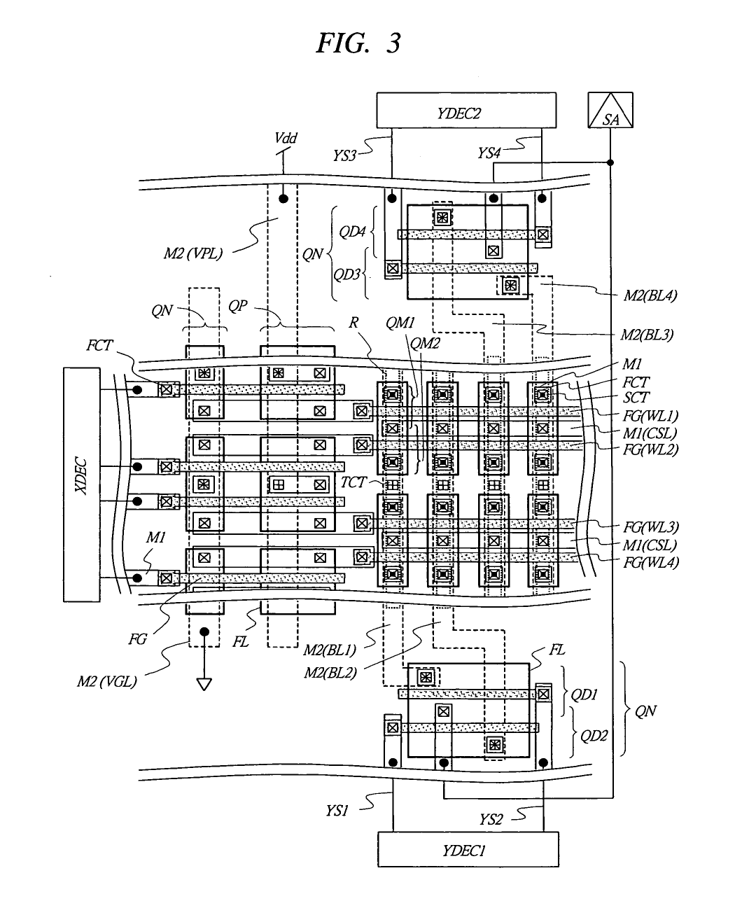

FIG. 3 is a plan view (plan layout) corresponding to the array structure of FIG. 2.

In FIG. 3, FL represents an active area. M1 is a first metal layer (corresponding to a wiring 37, which will be described further below). M2 is a second metal layer (corresponding to a wiring 72, which will be described further below). A gate electrode pattern FG (corresponding to a conductive film pattern for forming gate electrodes 16a, 16b, and 16c, which will be described further below) is a layer for use as a gate electrode of a transistor formed on a silicon substrate. FCT represents a contact hole (corresponding to a contact hole 32, which will be described further below) connecting the upper surface of FL and the lower surface of M1 together. R represents a laminated film of a storage element (corresponding to a recording layer 52, which will be described further below) and its upper electrode layer (corresponding to an upper electrode film 53, which will be described further below). SCT represents a contact hole (corresponding to a via hole 42, which will be described below) connecting the upper surface of M1 and the lower surface of R together. TCT represents a contact hole (corresponding to a via hole 65, which will be described below) connecting the upper surface of M1 and the lower surface of M2 together.

R is drawn up to M2 through TCT between the memory cells connected to the same bit line. This M2 is used as a bit line for each of them. The word lines WL1 to WL4 are each formed of FG. For FG, a layer of polysilicon and silicide (alloy of silicon and high-melting-point metal) is used. One MISFET forming the memory cell MC11 is represented by QM1. A MISFET QM2 forming MC21 shares the source region with QM1. As shown in FIG. 3, the same goes for MISFETs forming other cells. The bit lines BL1 to BL4 are connected to the source side of the transistors (MISFETs) QD1 to QD4, respectively, disposed at the outer rim of the memory array. Drain regions of QD1 and QD2 and drain regions of QD3 and QD4 are common to one another. These transistors have a function of pre-charging each bit line. At the same time, they also have a function of selecting a specified bit line upon reception of a signal from YDEC1 or YDEC2. In FIG. 3, the transistors are n-channel type. Circuitry elements forming each block are not particularly restrictive, and are typically formed on one semiconductor substrate made of, for example, single-crystal silicon, through a semiconductor integrated circuit technology for CMISFETs (Complementary MISFETs) or others. Furthermore, a chalcogenide material exhibiting phase changes is hybridized in an integrated circuit fabrication technology. For patterning of these patterns, well-known optical lithography and dry etching can be used. Manufacturing processes will be described in more detail below.

Next, the structure of the semiconductor device according to the present embodiment is described in more detail.

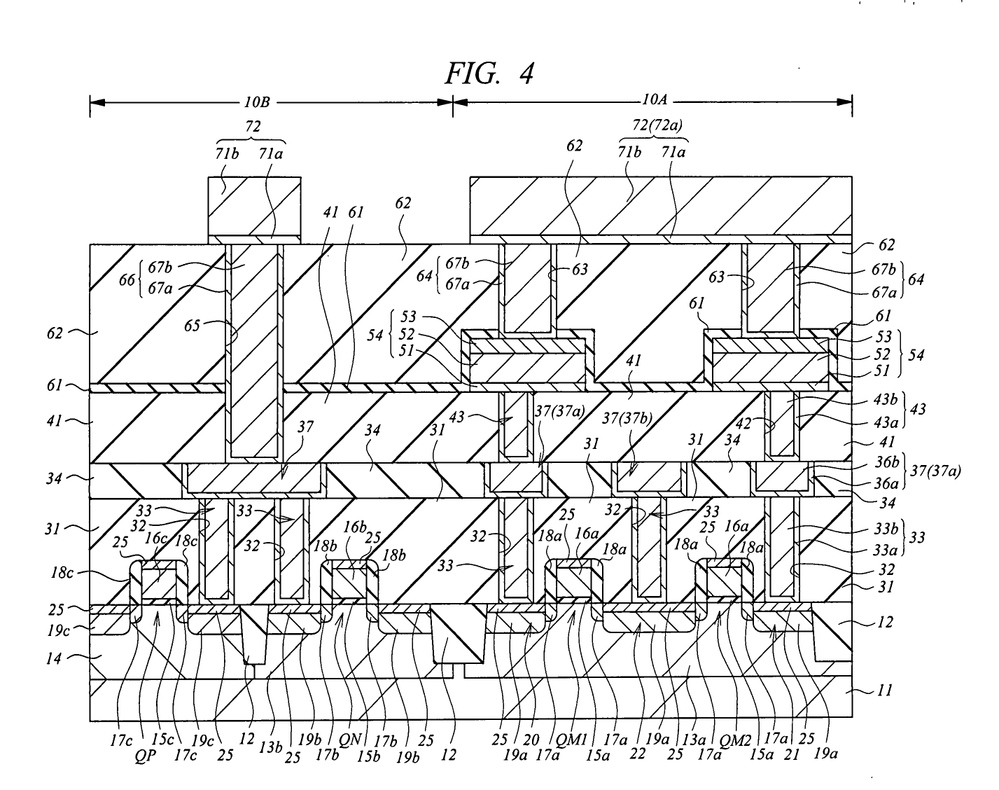

FIG. 4 is a cross-section view of main parts of the semiconductor device 1 according to the present embodiment. In FIG. 4, a cross-section (cross-section of main parts) of a phase-change memory area 10A and a cross-section (cross-section of main parts) of a peripheral circuit area (logical circuit area) 10B are shown. The phase-change memory area 10A corresponds to a phase-change memory 2 of the semiconductor device 1. The peripheral circuit area 10B corresponds to a peripheral circuit area of the semiconductor device 1 (an area on which an n-channel MISFET and a p-channel MISFET are formed). With the MISFETs forming a peripheral circuit (MISFETs formed on the peripheral circuit area 10B) and others, an X decoder circuit, a Y decoder circuit, a sense amplifier circuit, an input/output circuit (input/output circuit of the I/O area 6), a logic circuit (logic circuit of the CPU area 4), and others are formed. Here, in FIG. 4, for the sake of easy understanding, the section of the phase-change memory area 10A and the peripheral circuit area 10B are shown as being adjacent to each other. Alternatively, the positional relation between the section of the phase-change memory area 10A and the peripheral circuit area 10B can be changed as required.

As shown in FIG. 4, isolation areas 12 are formed on the main surface of a semiconductor substrate (semiconductor wafer) 11 made of p-type single-crystal silicon. On active areas isolated by these isolation areas 12, p-wells 13a and 13b and an n-well 14 are formed. Of these, the p-well 13a is formed on the phase-change memory area 10A, whilst the p-well 13b and the n-well 14 are formed on the peripheral circuit area 10B.

The p-well 13a of the phase-change memory area 10A has formed thereon n-channel MISFETs (Metal Insulator Semiconductor Field Effect Transistors) QM1 and QM2. The p-well 13b of the peripheral circuit area 10B has formed thereon an n-channel MISFET (Metal Insulator Semiconductor Field Effect Transistor) QN. The n-well 14 of the peripheral circuit area 10B has formed thereon a p-channel MISFET (Metal Insulator Semiconductor Field Effect Transistor) QP.

The MISFETs QM1 and QM2 of the phase-change memory area 10A are MISFETs for selecting a memory cell of the phase-change memory area 10A (2). The MISFETs QM1 and QM2 are formed on the p-well 13a so as to be separated from each other, and each has a gate insulation film 15a on the surface of the p-well 13a and a gate electrode 16a on the gate insulation film 15a. The gate electrode 16a has sidewalls on which sidewalls (side-wall spacers) 18a made of silicon oxide, a silicon nitride film, or a laminated film thereof are formed. The p-well 13a has formed therein a semiconductor region (n-type impurity diffusion layer) 20 as a drain region of the MISFET QM1, a semiconductor region (n-type impurity diffusion layer) 21 as a drain region of the MISFET QM2, and a semiconductor region (n-type impurity diffusion layer) 22 as a source region of the MISFETs QM1 and QM2. Each of the semiconductor region 20, 21, and 22 has an LDD (Lightly Doped Drain) structure, and is formed of an n⁻-type semiconductor region 17a, and an n⁺-type semiconductor region 19a with an impurity concentration higher than that of the n⁻-type semiconductor region 17a. The n⁻-type semiconductor region 17a is formed in the p-well 13a under the sidewalls 18a, whilst the n⁺-type semiconductor region 19a is formed in the p-well 13a outside of the gate electrode 16a and the sidewalls 18a. The n⁺-type semiconductor region 19a is formed in the p-well 13a at a position spaced apart from the channel area by the amount of the n⁻-type semiconductor region 17a. The semiconductor region 22 serves as a common source region shared by the adjacent MISFETs QM1 and QM2 formed on the same device active area. Here, although the case described in the present embodiment is such that the source region is common to the MISFETs QM1 and QM2, the drain region may be common to these MISFETS in another embodiment. In the latter case, the semiconductor region 22 serves as a drain region, whilst the semiconductor regions 20 and 21 serve as source regions.

A MISFET QN formed in the peripheral circuit area 10B has a structure similar to that of the MISFETs QM1 and QM2. That is, the MISFET QN has a gate insulation film 15b on the surface of the p-well 13b and a gate electrode 16b on the gate insulation film 15b, and the gate electrode 16b has sidewalls on which sidewalls (side-wall spacer) 18b made of silicon oxide or the like are formed. An n⁻-type semiconductor region 17b is formed in the p-well 13b under the sidewalls 18b, whilst an n⁺-type semiconductor region 19b with an impurity concentration higher than that of the n⁻-type semiconductor region 17b is formed outside of the n⁻-type semiconductor region 17b. The n⁻-type semiconductor region 17b and the n⁺-type semiconductor region 19b form source/drain regions having an LDD structure of the MISFET QN.

A MISFET QP formed in the peripheral circuit area 10B has a gate insulation film 15c on the surface of an n-well 14 and a gate electrode 16c on the gate insulation film 15c, and the gate electrode 16c has sidewalls on which sidewalls (side-wall spacers) 18c made of silicon oxide or the like are formed. A p⁻-type semiconductor region 17c is formed in the n-well 14 under the sidewalls 18c, whilst a p⁺-type semiconductor region 19c with an impurity concentration higher than that of the p⁻-type semiconductor region 17c is formed outside of the p⁻-type semiconductor region 17c. The p⁻-type semiconductor region 17c and the p⁺-type semiconductor region 19c form source/drain regions having an LDD structure of the MISFET QP.

Each of the gate electrodes 16a, 16b, and 16c, the n⁺-type semiconductor region 19a and 19b, and the p⁺-type semiconductor region 19c has a surface on which a metal silicide layer (for example, a cobalt silicide (CoSi₂) layer) 25 is formed. With this, diffusion resistance of areas such as the n⁺-type semiconductor region 19a and 19b and the p⁺-type semiconductor region 19c, and a contact resistance can be reduced.

On the semiconductor substrate 11, an insulation film (interlayer insulation film) 31 is formed so as to cover the gate electrodes 16a, 16b, and 16c. The insulation film 31 is formed of, for example, a silicon oxide film, and has an upper surface flatly formed so that the phase-change memory area 10A and the peripheral circuit area 10B have approximately the same height.

The insulation film 31 has contact holes (openings, or connection holes) 32 formed therethrough. Each of the contact holes 32 has a plug (contact electrode) 33 formed therein. The plug 33 is formed of a conductive barrier film 33a and a tungsten (W) film (main conductive film) 33b, the conductive barrier film 33a being formed on the bottom and sidewalls of the contact hole 32 and made of a titanium film, a titanium nitride film, or a laminated film, and the tungsten film 33b being formed on the conductive barrier film 33a so as to fill the contact hole 32. The contact hole 32 and the plug 33 are formed on the n⁺-type semiconductor region 19a and 19b, the p⁺-type semiconductor region 19c, and the gate electrodes 16a, 16b, and 16c.

The insulation film 31 with the plugs 33 embedded therein has formed thereon an insulation film 34 formed of, for example, a silicon oxide film. In wiring grooves (openings) formed in the insulation film 34, wirings as first-layer wirings (first wiring layers) 37 are formed. Each wiring 37 is formed of a conductive barrier film 36a and a main conductive film 36b, the conductive barrier film 36a formed on the bottom and sidewalls of the wiring groove and made of, for example, a titanium film, a titanium nitride film, or a laminated film thereof, and the main conductive film 36b being formed on the conductive barrier film 36a so as to fill the wiring groove and made of, for example, a tungsten film. The wirings 37 are electrically connected via the plugs 33 to the n⁺-type semiconductor region 19a and 19b, the p⁺-type semiconductor region 19c, and the gate electrodes 16a, 16b, and 16c, for example. In the phase-change memory area 10A, the wiring 37 connected via the plug 33 to the semiconductor region 22 for source of the MISFETs QM1 and QM2 (n⁺-type semiconductor region 19a) forms a source wiring 37b.

The insulation film 34 with the wirings 37 embedded therein is formed thereon an insulation film (interlayer insulation film) 41 formed of, for example, a silicon oxide film. In the phase-change memory area 10A, the insulation film 41 has via holes (openings, or connection holes) 42 formed therethrough. Each of the via holes 42 has a plug (contact electrode) 43 formed therein. The plug 43 is formed of a conductive barrier film 43a and a tungsten (W) film (main conductive film) 43b, the conductive barrier film 43a being formed on the bottom and sidewalls of the via hole 32 and made of a titanium film, a titanium nitride film, or a laminated film thereof, and the tungsten film 43b being formed on the conductive barrier film 43a so as to fill the via hole 42. Therefore, the plug 43 is a conductive portion formed (embedded) in the opening (via hole 42) of the insulation film 41, which is an interlayer insulation film. The via hole 42 and the plug 43 are formed on a wiring 37a, which is one of the wirings 37 that is connected via the plug 33 to the relevant one of the semiconductor regions 20 and 21 for drain of the MISFETs QM1 and QM2 in the phase-change memory area 10A (n⁺-type semiconductor regions 19a), and are electrically connected to the relevant wiring 37a.

In the phase-change memory area 10A, a resistor element 54 has formed of a peel-preventive film (phase-change-material peel-preventive film) 51, a recording layer (storage layer, recording material film, phase-change film, or phase-change recording material film) 52 on the peel-preventive film 51, and an upper electrode film (upper electrode or metal film) 53 on the recording layer 52. That is, the resistor element 54 is formed of a laminated pattern of the peel-preventive film 51, the recording layer 52, and the upper electrode film 53.

The peel-preventive film 51 is interposed between the insulation film 41 having the plug 43 embedded therein and the recording layer 52, thereby being operative so as to improve cohesion (adhesiveness) of the insulation film 41 and the recording layer 52 and to prevent the recording layer 52 from being peeled off. Also, the peel-preventive film 51 is operative as a heat-generate resistor layer for heating the recording layer 52. The peel-preventive film 51 is made of, for example, tantalum oxide (for example, Ta₂O₅), and can have a film thickness of, for example, 0.5 to 5 nm. Formation of the peel-preventive film 51 can be omitted if unnecessary and, in this case, the recording layer 52 is directly formed on the insulation film 41 having the plug 43 embedded therein. Therefore, a laminated pattern of the recording layer 52 and the upper electrode film 53 on the recording layer 52 can be taken as the resistor element 54. That is, the resistor element 54 is a laminated pattern having at least the recording layer 52 and the upper electrode film 53 on the recording layer 52.

The recording layer 52 is a phase-change film made of a phase-change material (phase-change substance), and is a material film (semiconductor film) capable of making a transition (phase change) between two states, that is, a crystalline state and an amorphous state. The recording layer 52 can make a transition (phase change) between a crystalline state and an amorphous state (non-crystalline state), and this recording layer 52 can be operative as a storage element. For example, the recording layer 52 is formed of a material (semiconductor) containing chalcogenide elements (S, Se, Te), that is, a chalcogenide layer made of chalcogenide (chalcogenide semiconductor or chalcogenide material). For example, the recording layer 52 can be formed of GeSbTe (for example, Ge₂Sb₂Te₅ or Ge₅Sb₂Te₈), AgInSbTe, or the like. The recording layer 52 can have a film thickness of, for example, on the order of 50 to 200 nm. Here, chalcogenide is a material containing at least one element of sulfur (S), selenium (Se), and tellurium (Te).

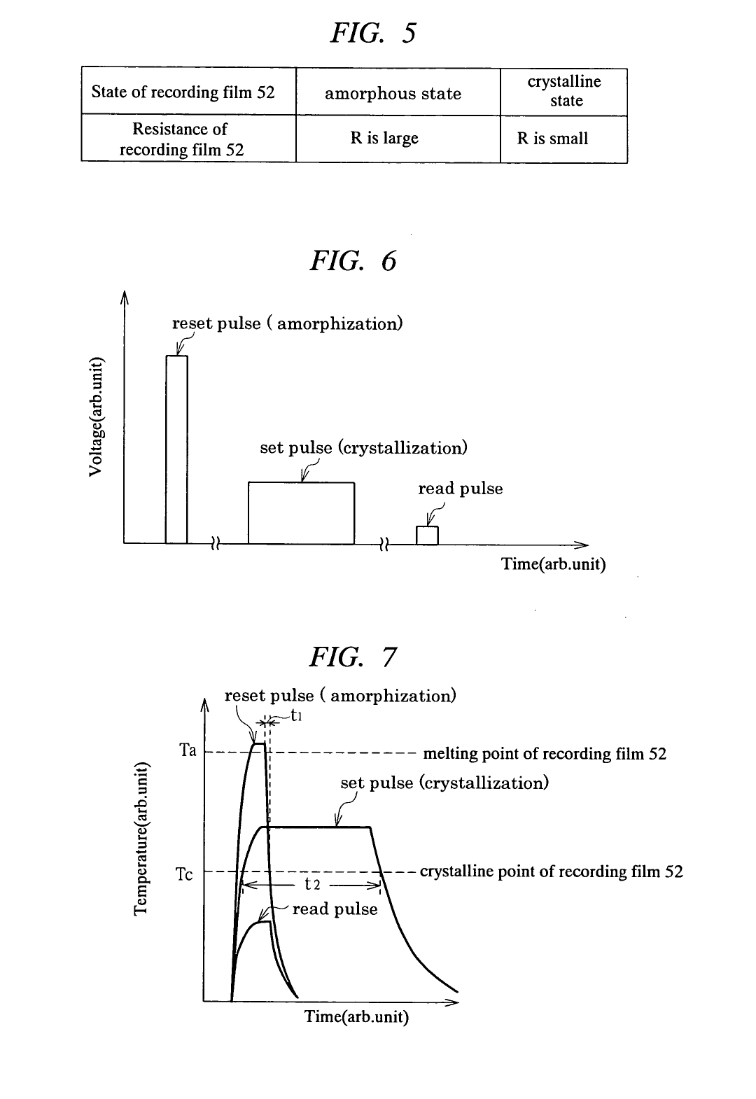

FIG. 5 is a table for describing a correlation between the state (phase state) of the recording layer 52 and the resistance (resistivity) of the recording layer 52. As shown in FIG. 5, the recording layer 52 has different resistivities between an amorphous state and a crystalline state. The resistance is high (high resistivity) in an amorphous state, whilst the resistance is low (low resistivity) in a crystalline state. For example, the resistivity of the recording layer 52 in an amorphous state is 10 to 10000 times larger than the resistivity of the recording layer 52 in a crystalline state. Therefore, the recording layer 52 can make a transition (phase change) between two states, that is, a crystalline state and an amorphous state. With such a transition between two states, the recording layer 52 can function as a resistor element with its resistance value being changed. As will be described further below, the recording layer 52 can make a transition (phase change) between two states, that is, a crystalline state and an amorphous state, through a heat treatment (heat process with Joule heat). Therefore, the recording layer 52 is made of a phase-change material with its resistance value being changed through a heat treatment, and can function as a resistor element with its resistance value being changed through a heat treatment. Also, as will be described further below, the recording layer 52 is a recording layer (storage layer, or storage element) for information of the phase-change memory.

The upper electrode film 53 is formed of a conductive film, such as a metal film, and can be formed of, for example, a tungsten (W) film or a tungsten alloy film. Its film thickness can be, for example, on the order of 50 to 20 nm. The upper electrode film 53 can function so as to reduce a contact resistance between a plug 64 and the resistor element 54, which will be described further below, and to prevent the recording layer 52 from sublimation when a conductive barrier film 67a is formed after formation of a via hole 63.

A lower portion of the resistor element 54 (the lower surface of the peel-preventive film 51) is electrically connected to the plug 43, and is electrically connected via the plug 43, the wiring 37a, and the plug 33 to the drain regions 20 and 21 (n⁺-type semiconductor region 19a) of the MISFETs QM1 and QM2 in the phase-change memory area 10A. Therefore, the plug 43 is electrically connected to the lower surface side of the recording layer 52.

As shown in FIG. 4, on the insulation film 41, an insulation film 61 and an insulation film (interlayer insulation film) 62 on the insulation film 61 are formed so as to cover the insulation film 41. That is, the insulation film 61 is formed on the insulation film 41 including the upper surface of the upper electrode film 53 and the sidewalls of the resistor element 54 (recording layer 52), and the insulation film 62 is formed on that insulation film 61 as an interlayer insulation film. The insulation film 61 has a film thickness that is thinner than the film thickness of the insulation film 62 (for example, several hundred nanometers) and that can be, for example, on the order of 5 to 20 nm. The insulation film 61 is formed of, for example, a silicon nitride film, whilst the insulation film 62 is formed of, for example, a silicon oxide film.

Although details will be described further below, the insulation film 61 is formed of a material film allowing an etching speed (etching selectivity) to be different from that of the insulation film 62. More preferably, the insulation film 61 and the insulation film 62 are formed of different materials. Also, preferably, the insulation film 61 has a film thickness thinner than the film thickness of the upper electrode film 53 of the resistor element 54. The insulation film 62 has an upper surface flatly formed so that the phase-change memory area 10A and the peripheral circuit area 10B have approximately the same height.

In the phase-change memory area 10A, the insulation films 61 and 62 have via holes (openings, or connection holes) 63 formed therethrough. At the bottom of each via hole 63, at least a part of the upper electrode film 53 of the resistor element 54 is exposed. The via hole 63 has a plug (contact electrode) 64 formed therein. The plug 64 is formed of a conductive barrier film 67a and a tungsten (W) film (main conductive film) 67b, the conductive barrier film 67a being formed on the bottom and sidewalls of the via hole 63 and made of a titanium film, a titanium nitride film, or a laminated film thereof, and the tungsten film 67b formed on the conductive barrier film 67a so as to fill the via hole 63. In place of the tungsten film 67b, an aluminum film or the like can be used. The via hole 63 and the plug 64 are formed on an upper portion of the resistor element 54, and the plug 64 is electrically connected to the upper electrode film 53 of the resistor element 54. Therefore, the plug 64 is a conductive portion formed (embedded) in the opening (via hole 63) of the insulation film 62, which is an interlayer insulation film, and electrically connected to the upper electrode film 53.

Here, as will be described further below, the insulation film 61 is a film that functions as an etching stopper film when the via holes 63 are formed, that is, a film that functions as an etching stopper when dry etching is performed on the insulation film 62 to form each via hole 63, so as to prevent the resistor element 54 (in particular, the upper electrode film 53) from being subjected to etching when the via hole 63 is formed.

Also, as will be described further below, in a stage before formation of the via holes 63, the state is such that the insulation film 61 is formed on the entire upper surface of the upper electrode film 53. At the time of formation of the via holes 63, the insulation film 61 on the upper electrode film 53 is removed at the bottom of the via holes 63. Therefore, in the manufactured semiconductor device, the insulation film 61 is formed under the insulation film 62 and on the upper surface of the upper electrode film 53 other than the portion exposed from the via holes 63.

In the peripheral circuit area 10B, the insulation films 41, 61, and 62 have a via hole (opening, or connection hole) 65 formed therethrough. At the bottom of the via hole 65, the upper surface of the wiring 37 is exposed. The via hole 65 has a plug (contact electrode) 66 formed therein. The plug 66 is formed of the conductive barrier film 67a and the tungsten (W) film (main conductive film) 67b, the conductive barrier film 67a being formed on the bottom and sidewalls of the via hole 65 and made of a titanium film, a titanium nitride film, or a laminated film thereof, and the tungsten film 67b formed on the conductive barrier film 67a so as to fill the via hole 65. The via hole 65 and the plug 66 are electrically connected to the wiring 37.

On the insulation film 62 having the plugs 64 and 66 embedded therein, a wiring (second wiring layer) 72 is formed as a second layer wiring. For example, the wiring 72 is formed of a conductive barrier film 71a formed of a titanium film, a titanium nitride film, or a laminated film thereof and an aluminum (Al) film or an aluminum alloy film (main conductive film) 71b on the conductive barrier film 71a. Furthermore, a conductive barrier film similar to the conductive barrier film 71a can be further formed on the aluminum alloy film 71b to form the wiring 72.

In the phase-change memory area 10A, a wiring (bit line) 72a of the wiring 72 is electrically connected via the plug 64 to the upper electrode film 53 of the resistor element 54. Therefore, the wiring 72a forming a bit line of the phase-change memory area 10A is electrically connected via the plug 64, the resistor element 54, the plug 43, the wiring 37a, and the plug 33 to the drain regions 20 and 21 (n⁺-type semiconductor region 19a) of the MISFETs QM1 and QM2 in the phase-change memory area 10A.

In the peripheral circuit area 10B, the wiring 72 is electrically connected via the plug 66 to the wiring 37, and is further electrically connected via the plug 33 to the n⁺-type semiconductor region 19b of the MISFET QN and the p⁺-type semiconductor region 19c of the MISFET QP.

On the insulation film 62, an insulation film (not shown) is formed as an interlayer insulation film so as to cover the wiring 72, and further upper wiring layers (third-layer wiring and onward) and others are formed. However, these are not shown or described herein.

In this manner, the semiconductor integrated circuit including the phase-change memory in the phase-change memory area 10A (phase-change non-volatile memory) and the MISFETs in the peripheral circuit area 10B is formed, thereby configuring the semiconductor device according to the present embodiment.

As described above, the recording layer 52 (or the resistor element 54 including the recording layer 52) and the MISFETs QM1 and QM2 as memory cell transistors (transistors for memory cell selection) connected to the recording layer 52 (resistor elements 54) form memory cells of the phase-change memory. The gate electrodes 16a of the MISFETs QM1 and QM2 are electrically connected to the word lines (corresponding to the above-described word lines WL1 to WL4). The upper surface side of the resistor element 54 (upper electrode film 53) is electrically connected via the plug 64 to the bit lines (corresponding to the above-described bit lines BL1 to BL4) formed of the above-described wiring 72a. The lower surface side of the resistor element 54 (the lower surface side of the recording layer 52) is electrically connected via the plug 43, the wiring 37a, and the plug 33 to the semiconductor regions 20 and 21 for drain of the MISFETs QM1 and QM2. The semiconductor region 22 for source of the MISFETs QM1 and QM2 is electrically connected via the plug 33 to the source wiring 37b (source line).

Here, in the present embodiment, the case is described in which the n-channel MISFETs QM1 and QM2 are used as memory cell transistors for phase-change memory (transistors for memory cell selection). In another embodiment, in place of the n-channel MISFETs QM1 and QM2, other field-effect transistors, such as p-channel MISFETs, can be used. However, as memory cell transistors for phase-change memory, MISFETs are preferably used in view of high integration, and n-channel MISFETs QM1 and QM2 are more suitable compared with p-channel MISFETs because n-channel MISFETs have a lower channel resistance in an ON state.

Next, the operation of the phase-change memory (phase-change memory formed in the phase-change memories 2 and 10A) is described.

FIGS. 6 and 7 are graphs for describing the operation of the phase-change memory. The vertical axis of the graph shown in FIG. 6 represents voltages (in arbitrary unit) of a reset pulse, a set pulse, and a read pulse to be applied to the phase-change memory, whilst the horizontal axis thereof represents time (in arbitrary unit). The vertical axis of the graph shown in FIG. 7 represents temperatures (in arbitrary unit) of the recording layer 52 when the reset pulse, the set pulse, or the read pulse is applied, whilst the horizontal axis thereof represents time (in arbitrary unit).

When storage information “0” is written in a storage element (memory cell of the phase-change memory), that is, at the time of a reset operation for the phase-change memory (amorphization of the recording layer 52), a reset pulse as shown in FIG. 6 is applied via the bit line (wiring 72a) and the plug 64 to the resistor element 54 (recording layer 52). To the source (semiconductor region 22) of the MISFETs QM1 and QM2, a fixed potential (for example, 0 V) is applied via the source wiring 37b and the plug 33. To the gate electrode 16a of the selected MISFET, a predetermined voltage is applied via the word line. This reset pulse is a voltage pulse that causes the recording layer 52 to be heated at a temperature equal to or higher than its melting point (amorphization temperature) Tₐ and then be rapidly cooled, for applying a relatively high voltage (for example, on the order of 3V) for a relatively short time. At the time of applying the reset pulse, a relatively large current flows, thereby increasing, as shown in FIG. 7, the temperature of the recording layer 52 to a temperature equal to or higher than the melting point (amorphization temperature) Tₐ of the recording layer 52 to melt or amorphize the recording layer 52. Upon completion of application of the reset pulse, the recording layer 52 is rapidly cooled to be in an amorphous state. By shortening the reset-pulse applying time to decrease total energy to be supplied and shortening a cooling time t₁ at, for example, approximately 1 ns, the recording layer 52 becomes in an amorphous state with high resistance.

Conversely, when the storage information “1” is written, that is, at the time of a set operation for the phase-change memory (crystallization of the recording layer 52), a set pulse as shown in FIG. 6 is applied via the bit line (wiring 72a) and the plug 64 to the resistor element 54 (recording layer 52). To the source (semiconductor region 22) of the MISFETs QM1 and QM2, a fixed potential (for example, 0 V) is applied via the source wiring 37b and the plug 33. To the gate electrode 16a of the selected MISFET, a predetermined voltage is applied via the word line. This set pulse is a voltage pulse that keeps the recording layer 52 to be at a temperature lower than the melting point in a temperature range higher than a crystallization temperature T_{c} equal to or higher than a glass transition temperature, and is for applying a voltage lower than that of the reset pulse (for example, on the order of 1V) for a period longer than that of the reset pulse (equal to or longer than a crystallization period). At the time of applying a set pulse, a current lower than that at the time of reset flows for a relatively long time. Then, as shown in FIG. 7, the temperature of the recording layer 52 is increased to a temperature equal to or higher than the crystallization temperature T_{c} and lower than the melting point (amorphization temperature) Tₐ to crystallize the recording layer 52. Upon completion of application of the set pulse, the recording layer 52 is cooled to be in a crystalline state (polycrystalline state). A time t₂ required for crystallization varies depending on the composition of the chalcogenide material forming the recording layer 52 and is, for example, approximately 50 ns. The temperature of the recording layer 52 (resistor element 54) shown in FIG. 7 depends on Joule heat dissipated from the recording layer 52 itself or thermal diffusion to the surroundings.

At the time of a read operation of the phase-change memory, a read pulse as shown in FIG. 6 is applied via the bit line (wiring 72a) and the plug 64 to the resistor element 54 (recording layer 52). To the source (semiconductor region 22) of the MISFETs QM1 and QM2, a fixed potential (for example, 0 V) is applied via the source wiring 37b and the plug 33. To the gate electrode 16a of the selected MISFET, a predetermined voltage is applied via the word line. With the read pulse, a voltage further lower than that of the set pulse (for example, on the order of 0.3 V) is applied for a period shorter than that of the set pulse. The voltage of the read pulse is relatively low, and even with the application of the read pulse, as shown in FIG. 7, the temperature of the recording layer 52 is not raised above a temperature equal to or higher than the crystallization temperature T_{c}. Therefore, the phase state of the recording layer 52 is not changed. When the recording layer 52 is in a crystalline state, the recording layer 52 (resistor element 54) has a relatively low resistance. When the recording layer 52 is in an amorphous state, the recording layer 52 (resistor element 54) has a relatively high resistance. Therefore, a current flowing through the MISFET (QM1 or QM2) to which the recording layer 52 (resistor element 54) is connected with the read pulse being applied is relatively large when the recording layer 52 is in a crystalline state, and is relatively small when the recording layer 52 is in an amorphous state. Therefore, depending on the magnitude of the flowing current, data (whether the recording layer 52 is in a crystalline state or in an amorphous state) can be determined.

As such, with the reset operation and the set operation, the state of the recording layer 52 is changed to an amorphous state or a crystalline state, thereby recording (storing, saving, or writing) data in the phase-change memory. With information indicative of whether the recording layer 52 is in an amorphous state or in a crystalline state as stored information of the phase-change memory, the data (stored information) recorded in the phase-change memory can be read through a read operation. Therefore, the above-described recording layer 52 serves as a recording layer for the information of the phase-change memory.

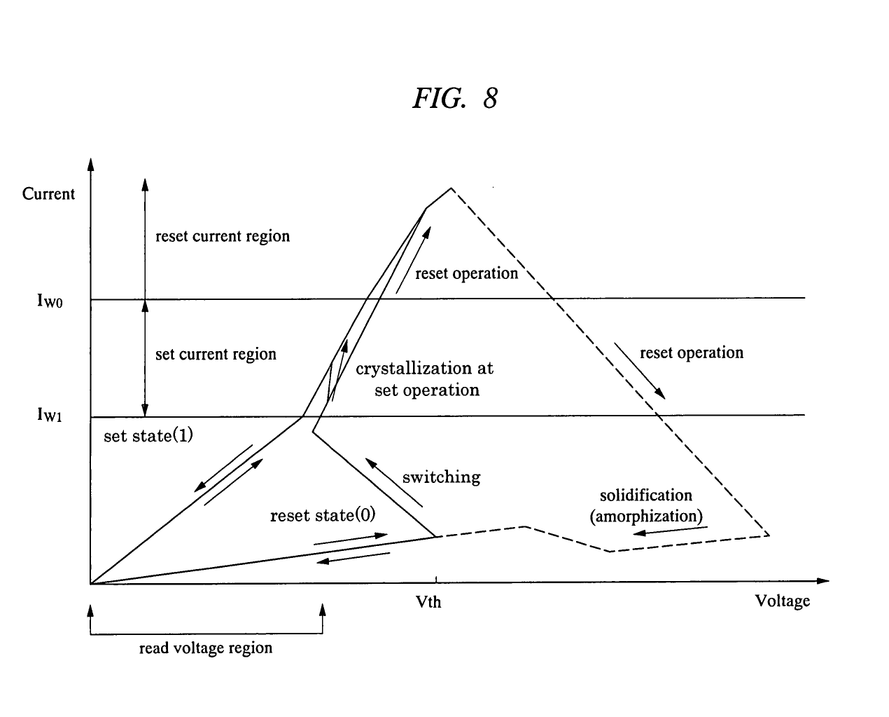

FIG. 8 is a graph for schematically describing operation principles of the storage element (recording layer 52) using a chalcogenide material, and depicting I-V characteristics of the storage element. The horizontal axis of the graph shown in FIG. 8 corresponds to a voltage applied to the storage element (recording layer 52), whilst the vertical axis thereof corresponds to a current flowing through the storage element (recording layer 52). In FIG. 8, storage information “1” is written when a set current within a range of I_{W1} to I_{W0} is applied, and storage information “0” is written when a reset current over I_{W0} is applied. As shown in the I-V characteristics of FIG. 8, by applying a current pulse corresponding to write information to the storage element (recording layer 52), the crystalline state of the storage element is controlled. However, whichever state may correspond to “0” or “1”. In accordance with FIG. 8, four types of write operations are described in detail below.

As can be seen from FIG. 8, firstly, when “1” is written in the storage element (recording layer 52) in an initial state of “1”, a set current (set pulse) is applied. With this, the current goes along a low resistance curve of a set (crystalline) state between the initial state and a set region, thereby maintaing the state. Secondly, when “0” is written in the storage element (recording layer 52) in an initial state of “1”, a reset current (reset pulse) is applied. With this, the current goes along a low resistance curve of the set state to reach a reset current. Next, melting partially starts due to Joule heat, and therefore conductivity is gradually decreased. Furthermore, when melting proceeds, the state becomes in a high resistance state. When the storage element in the liquid phase is rapidly cooled, the phase is changed to an amorphous state, and therefore the current goes along a high resistance curve in a reset (amorphous) state slightly lower than that of the resistance at the time of the liquid state to return to the initial state. A dotted line in FIG. 8 is a virtual line indicating that the current is supposed to be changed that way with changes in resistance value if the voltage is continuously applied as it is even though the reset pulse is already cut off. Thirdly, when “1” is written in the storage element (recording layer 52) in an initial state of “0”, upon application of a set current (set pulse), the state is switched to a low resistance state when a terminal voltage of the storage element goes over a threshold voltage Vth. After switching, crystallization proceeds due to Joule heat. When the current value reaches the set current, the crystallization region is expanded to cause a phase change, thereby further decreasing the resistance value. Therefore, the current goes along the low resistance curve to return to the initial state. The tilt of the voltage-current curve becomes gentle in midstream because the region switching to a low resistance state is switched OFF to cause only a decrease in resistance due to crystallization to remain. Fourthly, when “0” is written in the storage element (recording layer 52) in an initial state of “0”, hardly a time for crystallization is present after the above-described switching, and the current goes along a low resistance curve due to switching to reach the reset region, where melting, rapid cooling, and solidification are preformed to return to the initial state.

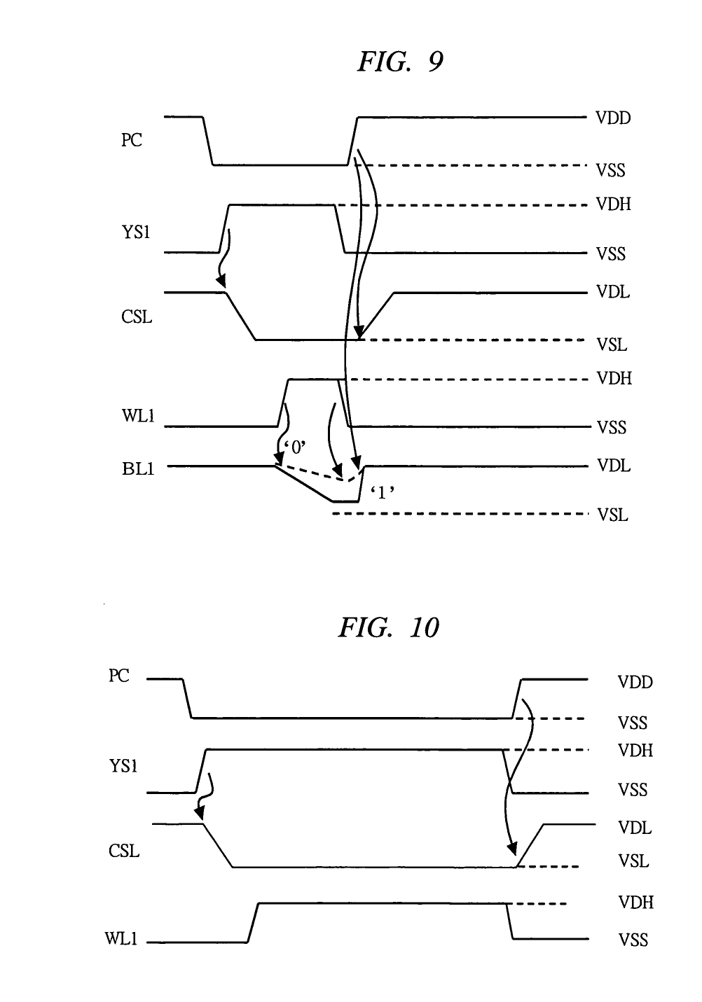

Next, with reference to FIG. 9 and above-described FIG. 2, the operation of a memory cell for use in the array structure shown in FIG. 2 is described. Here, FIG. 9 depicts an example of operational waveforms (applied voltage waveforms) when a memory cell MC11 is selected.

First, in a wait state, a pre-charge enable signal PC is retained at a power supply voltage Vdd (for example, 1.5 V). Therefore, with n-channel MIS transistors (MISFETs) QC1 to QC4, the bit line BL1 is sustained at a pre-charge voltage VDL. Here, the pre-charge voltage VDL has a value dropped from Vdd by a threshold voltage of the transistor, and is, for example, 1.0 V. Also, a common bit line I/O is pre-charged at the pre-charge voltage VDL.

When a read operation starts, with the pre-charge enable signal PC at the power supply voltage Vdd being driven to a ground potential GND and a bit selection line YS1 at the ground potential GND (corresponding to Vss) being driven to a boosting potential VDH (for example, equal to or higher than 1.5 V), a transistor (MISFET) QD1 becomes conductive. At this time, the bit line BL1 is retained at the pre-charge voltage VDL, whilst a source line CSL is driven to a source voltage VSL (for example, 0 V). These source voltage VSL and pre-charge voltage VDL are set so that the pre-charge voltage VDL is higher than the source voltage VSL and a difference therebetween is such that a terminal voltage of a resistor R is within a range of a read voltage region as shown in FIG. 8.

Next, when the word line WL1 at the ground potential GND is driven to the boosting potential VDH, transistors (MISFETs) QMp (p=1, 2, . . . , m) in all memory cells on the word line WL1 become conductive. At this time, a current route is generated in the memory cell MC11 where a potential difference occurs at the storage element R, and a discharge occurs at the bit line BL1 toward the source voltage VSL at a speed corresponding to the resistance value of the storage element R. Since it is assumed in FIG. 9 that the resistance value at the time of retaining storage information of “1” is smaller than the resistance value at the time of retaining storage information of “0”, a high-speed discharge occurs. Therefore, a signal voltage is generated in accordance with the stored information. In non-selected memory cells MC12 to MC1m, the potential difference of the storage element R is 0, and therefore the non-selected bit lines BL2 to BL4 are retained at the pre-charge voltage VDL. That is, only the memory cell MC11 selected with the word line WL1 and the bit line BL1 allows a read current to flow through the bit line BL1.

Here, in a wait state, when the bit lines and the source line of the memory array are taken as floating, the capacitance of the bit line with non-constant voltage is charged from the common bit line when the bit line and the common bit line are connected together at the time of starting a read operation. Therefore, in FIG. 9, the bit selection line YS1 is lowered in accordance with the word line WL1 and further the pre-charge enable signal PC at the ground potential GND is driven to the power supply voltage Vdd, thereby causing the bit line and the source line to be driven to the pre-charge potential VDL for a wait state. Also, the boosting potential VDH is set so as to satisfy a relation of VDH>Vdd+VTN by using the power supply voltage Vdd and a threshold voltage VTN of the n-channel MIS transistor. For example, in a write operation of the phase-change memory, as will be described further below, a current larger than that of a read operation has to flow. For this reason, in the present invention, the word line and the bit selection line are driven to the boosting potential VDH to decrease the resistance of the n-channel MIS transistor, thereby allowing an accurate write operation. Also, by setting the pre-charge voltage VDL higher than the source voltage VSL, the selected source line is taken as a source of the transistor (MISFET) QMm in the selected memory cell, thereby allowing a gate-source voltage of the transistor to be ensured irrespectively of the resistance of the storage element R. Here, even with an inverse potential relation, a similar selection operation is possible as long as the potential difference is set within a range of a read voltage area as shown in FIG. 8.

Here, FIG. 9 depicts an example in which the source line CSL is first driven and then the word line WL1 is driven. Alternatively, depending on the convenience of design, the word line WL1 may be first driven, and then the source line CSL may be driven. In this case, the word line WL1 is first driven to cause the selected transistor QM1 to become conductive, and therefore the terminal voltage of the storage element R is kept at 0 V. Then, when the source line CSL is driven, the terminal voltage of the storage element R is increased from 0 V, but can be controlled with a driving speed of the source line CSL within a range of the above-described read voltage region.

In the foregoing, the example of selecting the memory cell MC11 has been described. Memory cells on the same bit line are not selected because their word line voltage is fixed at the ground potential GND. Also, since the other bit lines and the source line have the same potential VDL, the remaining memory cells are sustained in a state of non-selected cells.

In the above description, it is assumed that the word line in a wait state is at the ground potential GND and the source line in a selected state is at the source voltage VSL. Such a voltage relation is set so that the current flowing through unselected memory cells does not affect the operation. That is, the relation is set so that, when a memory cell for which the source line is selected and the word line is not selected, for example, the memory cell MC11, is selected, transistors (MISFET) QM of unselected memory cells MC21 to MCn1 are sufficiently turned off. As described herein, with the word line voltage in a wait state being set at the ground potential GND and the source voltage VSL being set at a positive voltage, the threshold voltage of the transistor QM can be decreased. Depending on the case, the selected source line can be set at the ground potential of 0 V, and the word line in a wait state can be set at a negative voltage. Even in that case, the threshold voltage of the transistor QM can be decreased. Although a negative voltage has to be generated for the word line at the time of waiting, the voltage of the source line at the time of selection is at the ground potential GND, which is externally applied, and therefore is easy to stabilize. If the threshold voltage of the transistor QM is sufficiently high, the source line at the time of selection and the word line in a wait state may be at the ground potential of 0 V. In this case, in addition to the fact that these lines are at the ground potential GND, which is externally applied, the capacitance of the word line in a wait state functions as a capacitance for stabilization, and therefore the voltage of the source line at the time of selection can be further stabilized.

Still further, in accordance with FIG. 10, a write operation of the memory cell using the array structure shown in FIG. 2 is described. Here, FIG. 10 depicts operational waveforms when the memory cell MC11 is selected. First, an operation of selecting the memory cell MC11 is performed in a manner similar to that of the read operation. When the memory cell MC11 is selected, a write current is generated. When “0” is written, a reset current set at a value within the range shown in FIG. 8 is applied to the memory cell MC11. The reset current has a short pulse width, and returns to a wait state immediately after driving to have a current value of 0. With such a reset current, Joule heat is generated identical to that of the reset pulse shown in FIGS. 6 and 7. By contrast, when “1” is written, a set current set at a value within the range shown in FIG. 8 is applied. This set current has a pulse width of approximately 50 ns. With such a set current, Joule heat is generated identical to that of the set pulse shown in FIGS. 6 and 7. In this manner, the applying time and the current value of the write pulse are controlled by a write circuit. Therefore, in writing either storage information, the memory cell is in a selected state for a pulse width of the set current.

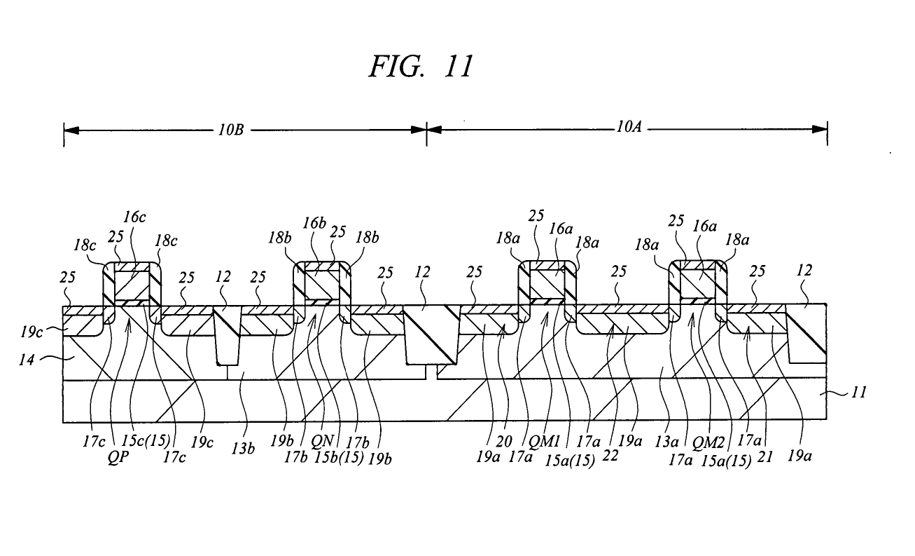

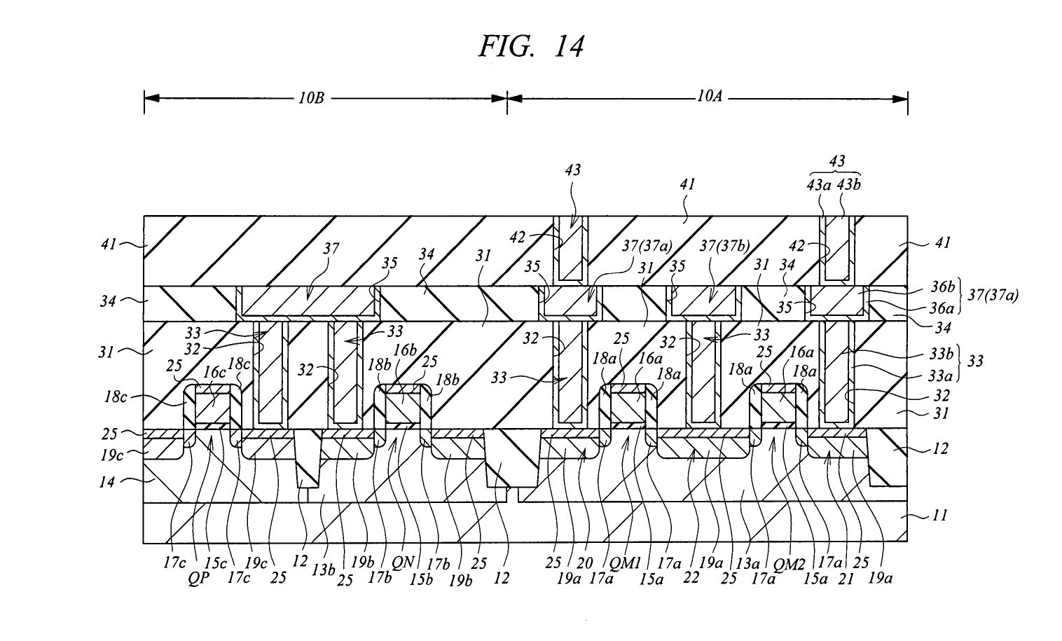

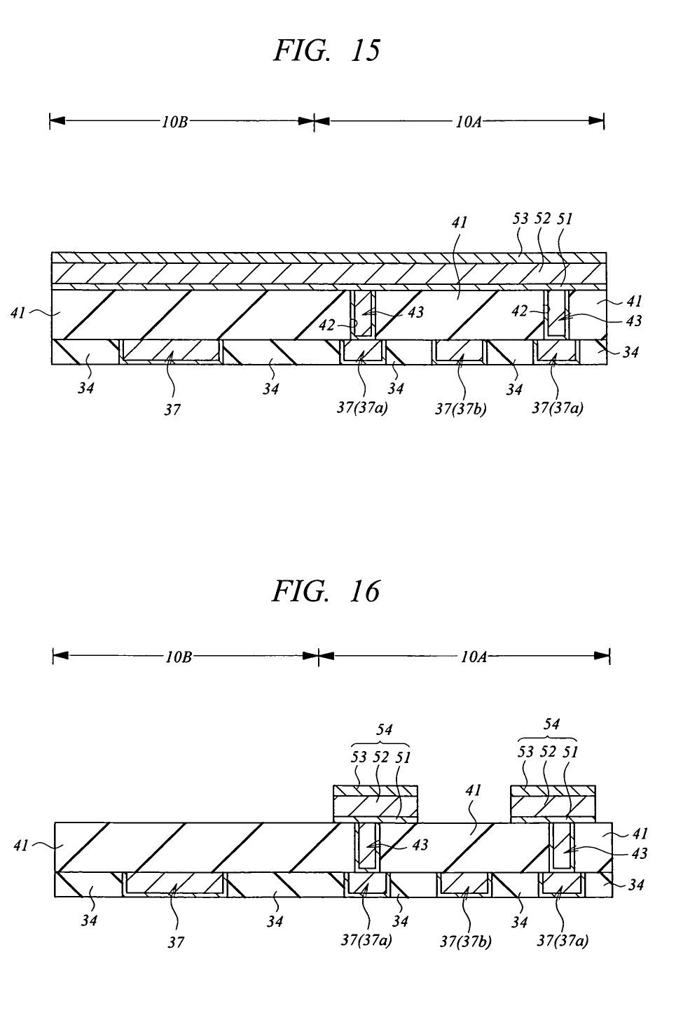

Next, a process of manufacturing the semiconductor device 1 according to the present embodiment is described with reference to the drawings. FIGS. 11 to 22 are cross-section views of main parts of the semiconductor device 1 according to the first embodiment of the present invention during the manufacturing process, depicting an area corresponding to that of FIG. 4 described above. Here, for ease of understanding, in FIGS. 15 to 22, the insulation film 31 and portions corresponding to the structure therebelow in FIG. 14 are omitted.

First, as shown in FIG. 11, the semiconductor substrate (semiconductor wafer) 11 made of, for example, p-type single-crystal silicon is prepared. Then, on the main surface of the semiconductor substrate 11, the isolation areas 12 made of an insulating material are formed through, for example, STI (Shallow Trench Isolation) or LOCOS (Local Oxidization of Silicon). With the formation of the isolation areas 12, active areas with its surroundings being defined by the isolation areas 12 are formed on the main surface of the semiconductor substrate 11.

Next, the p-wells 13a and 13b and the n-well 14 are formed on the main surface of the semiconductor substrate 11. Of these, the p-well 13a is formed in the phase-change memory area 10A, whilst the p-well 13b and the n-well 14 are formed in the peripheral circuit area 10B. For example, the p-wells 13a and 13b can be formed through ion implantation of p-type impurities (for example, boron (B)) into a part of the semiconductor substrate 11, whilst the n-well 14 can be formed through ion implantation of n-type impurities (for example, phosphorus (P) or arsenic (As)) into another part of the semiconductor substrate 11.

Next, by using thermal oxidation, for example, an insulation film 15 for a gate insulation film formed of a thin silicon oxide film is formed on the surface of the p-wells 13a and 13b and the n-well 14 of the semiconductor substrate 11. As the insulation film 15, a silicon oxynitride film or the like can be used. The insulation film 15 has a film thickness of, for example, the order of 1.5 to 10 nm.

Next, the gate electrodes 16a, 16b, and 16c are formed on the insulation film 15 of the p-wells 13a and 13b and the n-well 14. For example, a polycrystalline silicon film with a low resistance is formed as a conductive film on the entire surface, including on the insulation film 15, of the main surface of the semiconductor substrate 11, and then that polycrystalline silicon film is patterned through a photoresist scheme or dry etching, for example, thereby forming the gate electrodes 16a, 16b, and 16c formed of the patterned polycrystalline silicon film (conductive film). The insulation film 15 remaining under the gate electrode 16a serves as the gate insulation film 15a, the insulation film 15 remaining under the gate electrode 16b serves as the gate insulation film 15b, and the insulation film 15 remaining under the gate electrode 16c serves as the gate insulation film 15c. Here, doped with impurities at the time of or after film formation, the gate electrodes 16a and 16b are formed of a polycrystalline silicon film (doped polysilicon film) with n-type impurities introduced thereto, and the gate electrode 16c is formed of a polycrystalline silicon film (doped polysilicon film) with p-type impurities introduced thereto.

Next, through ion implantation of n-type impurities, such as phosphorus (P) or arsenic (As), the n⁻-type semiconductor region 17a is formed in an area on both sides of the gate electrode 16a of the p-well 13a, and the n⁻-type semiconductor region 17b is formed in an area on both sides of the gate electrode 16b of the p-well 13b. Also, through ion implantation of p-type impurities, such as boron (B), the p⁻-type semiconductor region 17c is formed in an area on both sides of the gate electrode 16c of the n-well 14.

Next, on the sidewalls of the gate electrodes 16a, 16b, and 16c, the sidewalls 18a, 18b, and 18c are formed. These sidewalls 18a, 18b, and 18c can be formed by, for example, depositing an insulation film formed of a silicon oxide film, a silicon nitride film, or a laminated film thereof on the semiconductor substrate 11 and then performing anisotropic etching on this insulation film.

Next, through ion implantation of n-type impurities, such as phosphorus (P) or arsenic (As), the n⁺-type semiconductor region 19a is formed in an area on both sides of the gate electrode 16a and the sidewalls 18a of the p-well 13a, and the n⁺-type semiconductor region 19b is formed in an area on both sides of the gate electrode 16b and the sidewalls 18b of the p-well 13b. Also, through ion implantation of p-type impurities, such as boron (B), the p⁺-type semiconductor region 19c is formed in an area on both sides of the gate electrode 16c and the sidewalls 18c of the n-well 14. After ion implantation, annealing (heat treatment) can be performed for activating the introduced impurities.

With this, in the phase-change memory area 10A, the n-type semiconductor regions 20 and 21 functioning as drain regions of the MISFETs QM1 and QM2 and the n-type semiconductor region 22 functioning as a common source region thereof are formed of the n⁺-type semiconductor region 19a and the n⁻-type semiconductor region 17a, respectively. Also, in the peripheral circuit area 10B, the n-type semiconductor region functioning as a drain region of the MISFET QN and the n-type semiconductor region functioning as a source region thereof are formed of the n⁺-type semiconductor region 19b and the n⁻-type semiconductor region 17b, respectively, and the p-type semiconductor region functioning as a drain region of the MISFET QP and the p-type semiconductor region functioning as a source region thereof are formed of the p⁺-type semiconductor region 19c and the p⁻-type semiconductor region 17c, respectively.

Next, the surfaces of the gate electrodes 16a, 16b, and 16c, the n⁺-type semiconductor regions 19a and 19b, and the p⁺-type semiconductor region 19c are exposed. Then, a metal film, for example, a cobalt (Co) film, is deposited on the exposed surface for heat treatment, thereby forming the metal silicide layer 25 on the surfaces of the gate electrodes 16a, 16b, and 16c, the n⁺-type semiconductor regions 19a and 19b, and the p⁺-type semiconductor region 19c. Then, an unreacted cobalt film (metal film) is removed.

In this manner, the structure shown in FIG. 11 can be obtained. With the processes described above, the n-channel MISFETs QM1 and QM2 are formed in the phase-change memory area 10A, whilst the n-channel MISFET QN and the p-channel MISFET QP are formed in the peripheral circuit area 10B. Therefore, the MISFETs QM1 and QM2 in the phase-change memory area 10A and the MISFETs QN and QP in the peripheral circuit area 10B can be formed with the same manufacturing processes.

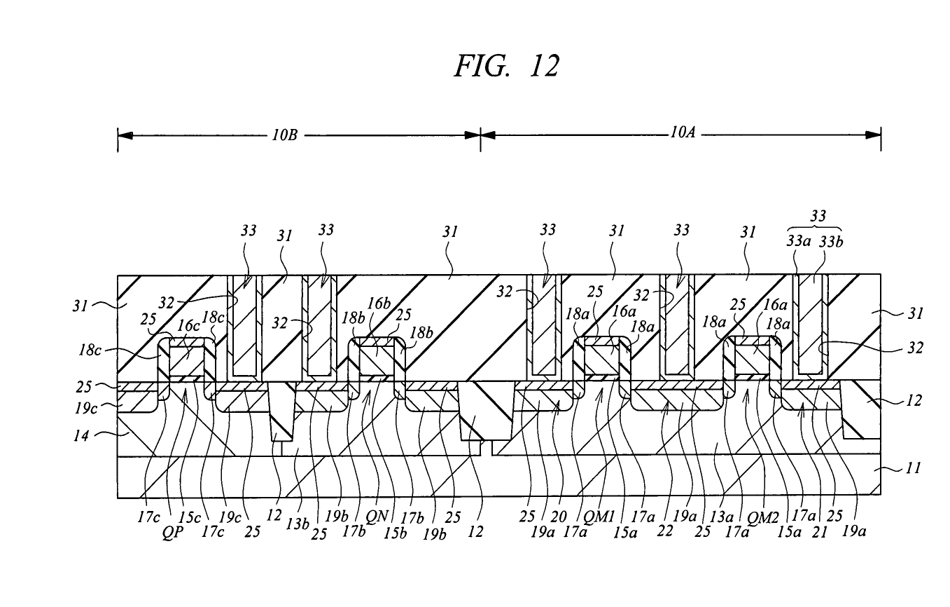

Next, as shown in FIG. 12, the insulation film (interlayer insulation film) 31 is formed on the semiconductor substrate 11 so as to cover the gate electrodes 16a, 16b, and 16c. The insulation film 31 can be formed of, for example, a silicon oxide film. The insulation film 31 can be formed of a laminated film of a plurality of insulation films. After formation of the insulation film 31, the upper surface of the insulation film 31 is planarized, as required, through, for example, CMP. With this, the phase-change memory area 10A and the peripheral circuit area 10B have an approximately same height on the upper surface of the insulation film 31.

Next, with a photoresist pattern (not shown) formed on the insulation film 31 through photolithography being used as an etching mask, dry etching is performed on the insulation film 31, thereby forming the contact holes 32 on the insulation film 31. At the bottom of the contact holes 32, a part of the main surface of the semiconductor substrate 11, for example, a part of (the metal silicide layer 25 on the surface of) the n⁺-type semiconductor regions 19a and 19b and the p⁺-type semiconductor region 19c and a part of (the metal silicide layer 25 on the surface of) the gate electrodes 16a, 16b, and 16c, is exposed.

Next, the plug 33 is formed in each of the contact holes 32. At this time, for example, the conductive barrier film 33a is formed through spattering or the like on the insulation film 31 including the inside of the contact hole 32, and then the tungsten film 33b is formed through CVD or the like on the conductive barrier film 33a so as to fill the contact hole 32. Then, unnecessary portions of the tungsten film 33b and the conductive barrier film 33a on the insulation film 31 are removed through CMP, an etch-back technique, or the like. With this, the plug 33 formed of the tungsten film 33b and the conductive barrier film 33a remaining and embedded in the contact hole 32 can be formed.

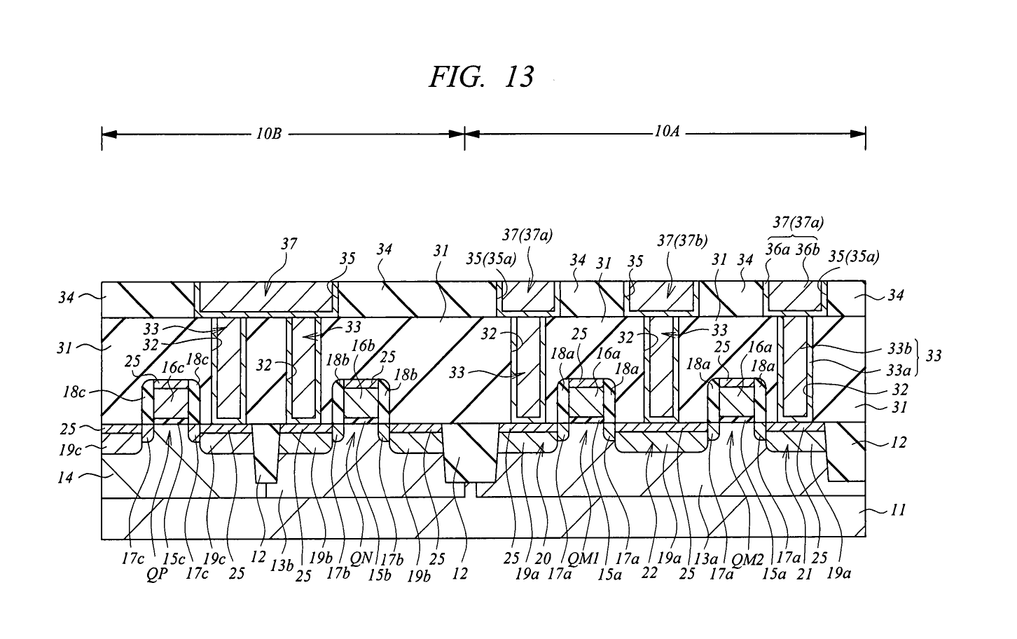

Next, as shown in FIG. 13, the insulation film 34 is formed on the insulation film 31 with the plugs 33 embedded therein. Then, with a photoresist pattern (not shown) formed by using photolithography on the insulation film 34 as an etching mask, dry etching is performed on the insulation film 34 to form wiring grooves (openings) 35 on the insulation film 34. At the bottom of the wiring grooves 35, the upper surface of the plugs 33 are exposed. Here, of the wiring grooves 35, the wiring grooves 35, that is, openings 35a, for exposing the plugs 33 formed on the drain regions (semiconductor regions 20 and 21) of the MISFETs QM1 and QM2 in the phase-change memory area 10A can be each formed not as a groove-shaped pattern but as a hole-shaped (connection-hole-shaped) pattern having a plane dimension larger than that of the plug 33 exposed therefrom. Also, in the present embodiment, the openings 35a are formed simultaneously with the other wiring grooves 35. Alternatively, the openings 35a and the other wiring grooves 35 can be formed with different processes by separately using a photoresist pattern for forming the openings 35a and a photoresist pattern for forming the other wiring grooves 35.

Next, the wirings 37 are formed in the wiring grooves 35. At this time, for example, the conductive barrier film 36a is formed on the insulation film 34 including the inside (bottom and sidewalls) of the wiring grooves 35 through spattering or the like; and then the main conductive film 36b formed of a tungsten film or the like is formed through CVD or the like on the conductive barrier film 36a so as to fill the wiring groove 35. Then, unnecessary portions of the main conducive film 36b and the conductive barrier film 36a on the insulation film 34 are removed through CMP, an etch-back technique, or the like. With this, the wirings 37 formed of the main conductive film 36b and the conductive barrier film 36a left and embedded in the wiring grooves 35 can be formed of the wirings 37, the wiring 37a formed in the opening 35a in the phase-change memory area 10A is electrically connected via the plug 33 to the relevant one of the drain regions (semiconductor regions 20 and 21) of the MISFETs QM1 and QM2 in the phase-change memory area 10A. The wiring 37a does not extend over the insulation film 31 so as to connect semiconductor elements formed on the semiconductor substrate 11, but locally exists on the insulation film 31 so as to electrically connect the plug 43 and the plug 33 together, and is interposed between the plug 43 and the plug 33. Therefore, the wiring 37a can be regarded not as a wiring but as a conductive portion for connection (contact electrode). Also, in the phase-change memory area 10A, the source wiring 37bconnected via the plug 33 to the semiconductor region 22 for source of the MISFETs QM1 and QM2 (n⁺-type semiconductor region 19a) is formed of the wiring 37.

The wiring 37 is not restricted to the embedded tungsten wiring as described above, but can be variously modified. For example, the wiring 37 can be a non-embedded tungsten wiring or an aluminum wiring.

Next, as shown in FIG. 14, the insulation film (interlayer insulation film) 41 is formed on the insulation film 34 with the wirings 37 being embedded therein.

Next, with a photoresist pattern (not shown) formed by using photolithography on the insulation film 41 as an etching mask, dry etching is performed on the insulation film 41 to form the via holes (openings, or connection holes) 42 through the insulation film 41. The via holes 42 are formed in the phase-change memory area 10A. At the bottom of each of the via holes 42, the upper surface of the wiring 37a is exposed.

Next, the plug 43 is formed in the via hole 42. At this time, for example, the conductive barrier film 43a is formed through spattering or the like on the insulation film 41 including the inside of the via hole 42, and then the tungsten film 43b is formed on the conductive barrier film 43a through CVD or the like so as to fill the via hole 42. Then, unnecessary portions of the tungsten film 43b and the conductive barrier film 43a on the insulation film 41 are removed through CMP, an etch-back technique, or the like. With this, the plug 43 formed of the tungsten film 43b and the conductive barrier film 43a left and embedded in the contact hole 42 can be formed. In this manner, the plug 43 is formed by filling the opening (via hole 42) formed through the insulation film 41 with a conductive material.

In the present embodiment, the plug 43 is formed by filling the via hole 42 by using the tungsten film 43b. Alternatively, in place of the tungsten film 43b, a film made of a metal allowing the upper surface of the plug 43 to be highly planarized at the time of the CMP process (a metal suitable for CMP planarization) can be used. For example, as such a metal suitable for CMP planarization, a molybdenum (Mo) film with a small crystal grain diameter can be used in place of the tungsten film 43b. The above-mentioned metal suitable for CMP planarization has an effect of suppressing local changes of the recording layer 52 due to concentration of the electric field occurring due to asperities of the upper surface of the plug 43. As a result, uniformity of electrical characteristics of the memory cell elements, reliability of the number of rewriting, and resistance to operations at high temperature can be further improved.

Next, as shown in FIG. 15, on the insulation film 41 with the plugs 43 embedded therein, the peel-preventive film 51, the recording layer 52, and then the upper electrode film 53 are formed (deposited) in this order. Here, as described above, in FIGS. 15 to 22, the insulation film 31 and portions corresponding to the structure therebelow in FIG. 14 are omitted. The peel-preventive film 51 has a film thickness (deposition film thickness) of, for example, on the order of 0.5 to 5 nm, the recording layer 52 has a film thickness (deposition film thickness) of, for example, on the order of 50 to 200 nm, and the upper electrode film 53 has a film thickness (deposition film thickness) of, for example, on the order of 50 to 200 nm.

Next, as shown in FIG. 16, by using photolithography and dry etching, a laminated film formed of the peel-preventive film 51, the recording layer 52, and the upper electrode film 53 is patterned. With this, the resistor element 54 formed of the laminated pattern of the upper electrode film 53, the recording layer 52, and the peel-preventive film 51 is formed on the insulation film 41 with the plugs 43 embedded therein. The peel-preventive film 51 can be used as an etching stopper film when the dry etching is performed on the upper electrode film 53 and the recording layer 52.

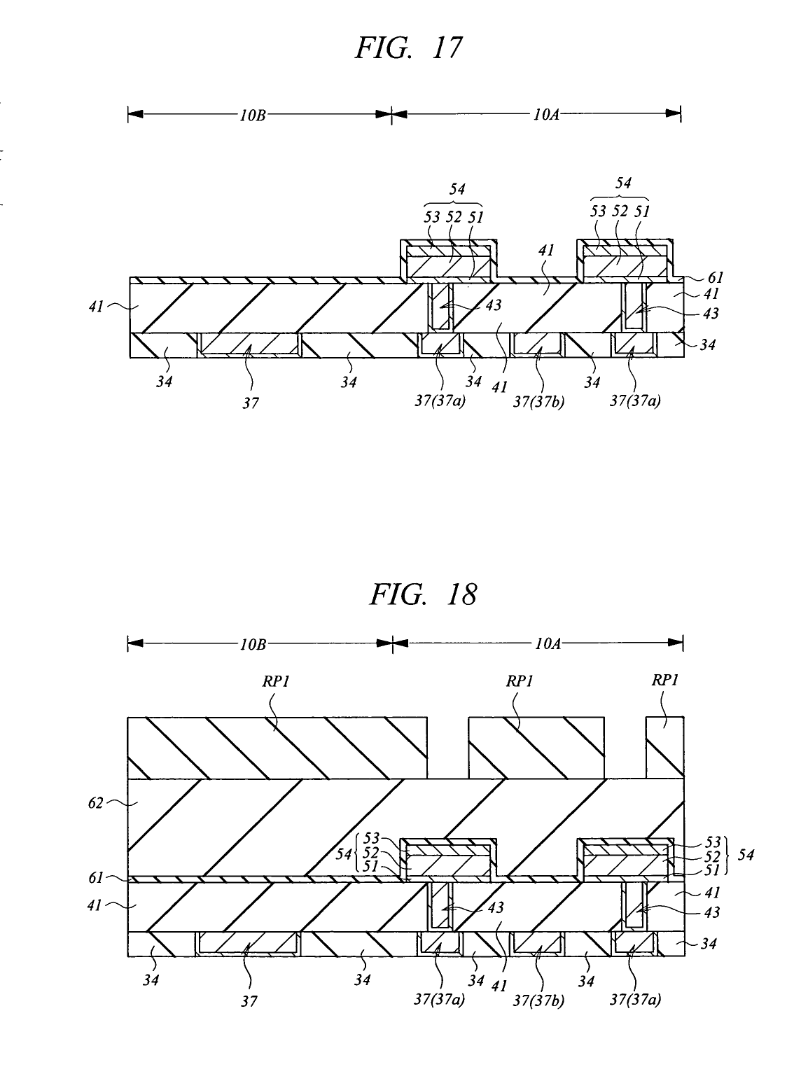

Next, as shown in FIG. 17, the insulation film (etching stopper film) 61 is formed on the insulation film 41 so as to cover the resistor element 54. Thus, the insulation film 61 is formed on the insulation film 41 including the upper surface of the resistor element 54 and sidewalls (side surfaces). With this, the state is such that the insulation film 61 is formed on the upper surface of the upper electrode film 53 and the sidewalls (side surfaces) of the recording layer 52.

As the insulation film 61, it is preferable to use a material film allowing film formation at a temperature at which the recording layer 52 does not sublimate (for example, equal to or lower than 400 degrees Celsius). More preferably, if a silicon nitride film is used as the insulation film 61, film formation is possible through, for example, plasma CVD, at a temperature at which the recording layer 52 does not sublimate (for example, equal to or lower than 400 degrees Celsius). With this, sublimation of the recording layer 52 at the time of film formation of the insulation film 61 can be prevented.

Next, as shown in FIG. 18, the insulation film (interlayer insulation film) 62 is formed as an interlayer insulation film on the insulation film 61. Therefore, the insulation film 62 is formed on the insulation film 61 so as to cover the laminated pattern (resistor element 54) of the upper electrode film 53, the recording layer 52, and the peel-preventive film 51. After formation of the insulation film 62, as required, by performing CMP or the like, the upper surface of the insulation film 62 can be planarized. Then, by using photolithography, a photoresist pattern RP1 is formed on the insulation film 62.

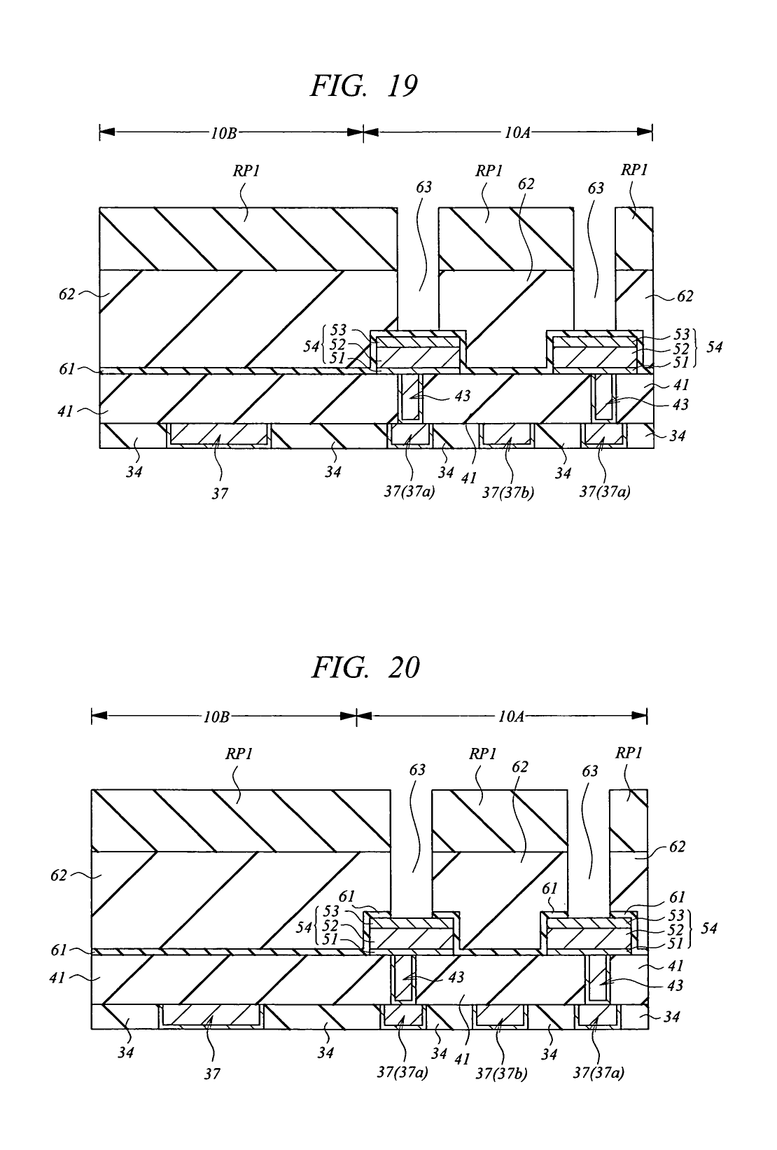

Next, as shown in FIG. 19, with the photoresist pattern RP1 as an etching mask, dry etching (first dry etching) is performed on the insulation film 62, thereby forming the via holes (openings, or connection holes) 63 through the insulation film 62. At the time of this dry etching (first dry etching) of the insulation film 62, dry etching is performed under conditions where the insulation film 62 (silicon oxide) is more prone to be etched than the insulation film 61 (silicon nitride) (that is, under conditions where an etching speed (etch rate) of the insulation film 62 is higher than an etching speed of the insulation film 61), with the insulation film 61 functioning as an etching stopper film. In this dry etching, for example, the insulation film 62 made of silicon oxide is etched, whilst the insulation film 61 as an etching stopper is not etched. For example, an etching method with a selectivity of 10 or higher is used. At this stage, the insulation film 61 is exposed at the bottom of the via holes 63. However, since the insulation film 61 functions as an etching stopper, etching stops with the insulation film 61 being exposed at the bottom of the via holes 63, and the upper electrode film 53 of the resistor element 54 is not exposed.

Then, as shown in FIG. 20, dry etching (second dry etching) is performed under conditions where the insulation film 61 (silicon nitride) is more prone to be etched than the insulation film 62 (silicon oxide) (that is, under conditions where an etching speed (etch rate) of the insulation film 61 is higher than an etching speed of the insulation film 62). This dry etching is performed on the insulation film 61 exposed at the bottom of the via holes 63 for removal. With this, at the bottom of the via holes 63, at least a part of the upper electrode film 53 of the resistor element 54 is exposed. The second dry etching is preferably performed by anisotropic dry etching. Then, the photoresist pattern RP1 is removed.

The above-described first dry etching (dry etching on the insulation film 62) can be performed by using mixed gas of C₄F₈ gas, O₂ gas, and Ar gas as etching gas, whilst the above-described second dry etching (dry etching on the insulation film 61) can be performed by using mixed gas of CF₄ gas, CHF₃ gas, and Ar gas as etching gas.

The dry etching (first dry etching) on the insulation film 62 with the insulation film 61 as an etching stopper film and the subsequent dry etching (second dry etching) on the insulation film 61 at the bottom of the via holes 63 can be performed through separate processes, and can also be performed in a successive manner such that the semiconductor substrate 11 is disposed in the same etching apparatus with the type of gas or the amount of flow for etching being changed. If the above-described first dry etching and the above-described second dry etching are successively performed, the number of manufacturing processes for semiconductor devices can be reduced, thereby also reducing time required for manufacturing semiconductor devices.

Here, in a stage before formation of the via holes 63, the state is such that the insulation film 61 is formed on the entire upper surface of the upper electrode film 53. At the time of formation of the via holes 63, the insulation film 61 on the upper electrode film 53 is removed at the bottom of the via holes 63. Therefore, after formation of the via holes 63 and the plug 64 (after the semiconductor device is manufactured), the insulation film 61 is formed under the insulation film 62 and on the upper surface of the upper electrode film 53 other than the portion exposed from the via holes 63.

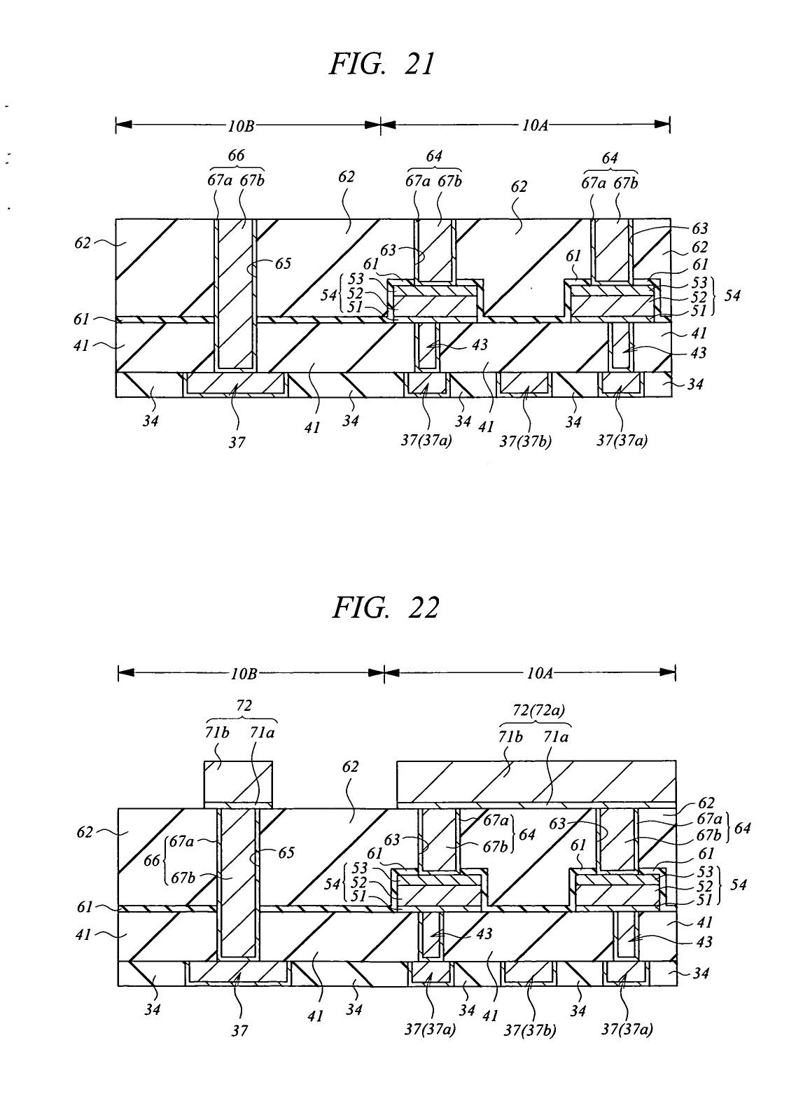

Next, as shown in FIG. 21, with a photoresist pattern (not shown) formed on the insulation film 62 by using photolithography as an etching mask, dry etching is performed on the insulation films 62, 61 and 41, thereby forming the via hole (opening, or connection hole) 65 through the insulation films 62, 61, and 41. The via hole 65 is formed in the peripheral circuit area 10B, and the upper surface of the wiring 37 is exposed at the bottom of the via hole 65. Then, the photoresist pattern is removed. Here, the via hole 65 can be first formed before the via holes 63 are formed. Also, the via hole 65 and the via holes 63 are preferable to be formed through different processes, but can be formed through the same process.

Next, the plug 64 is formed in each of the via holes 63, and the plug 66 is formed in the via hole 65. At this time, for example, the conductive barrier film 67a is formed through spattering or the like on the insulation film 62 including the inside of the via holes 63 and 65, and then the tungsten film 67b is formed through CVD or the like on the conductive barrier film 67a so as to fill the via holes 63 and 65. Then unnecessary portions of the tungsten film 67b and the conductive barrier film 67a on the insulation film 62 are removed through CMP, an etch-back technique, or the like. With this, the plug 64 formed of the tungsten film 67b and the conductive barrier film 67a left and embedded in the via hole 63 and the plug 66 formed of the tungsten film 67b and the conductive barrier film 67a left and embedded in the via hole 65 can be formed. In place of the tungsten film 67b, an aluminum (Al) film, an aluminum alloy film (main conductive film), or the like can be used. In this manner, the plugs 64 and 66 are formed by filling the openings (via holes 63 and 65) formed through the insulation film with the conductive material.

In the present embodiment, after the via holes 63 and 65, the plugs 64 and 66 are formed through the same process. With this, the number of manufacturing processes can be reduced. In another embodiment, via holes and plugs can be formed in a manner such that, after either the via holes 63 or the via hole 65 is first formed, a plug(s) (the relevant one(s) of the plugs 64 and the plug 66) for filling that via hole(s) is formed, and then the other one(s) of the via hole 63 and the via hole 65 is formed and a plug(s) (the other one(s) of the plugs 64 and the plug 66) is formed.

Next, as shown in FIG. 22, the wiring 72 is formed as a second-layer wiring on the insulation film 62 with the plugs 64 and 66 embedded therein. For example, on the insulation film 62 with the plugs 64 and 66 embedded therein, the conductive barrier film 71a and the aluminum film or aluminum alloy film 71b are sequentially formed through spattering or the like, and are then patterned through photolithography, dry etching, or the like, thereby forming the wiring 72. The wiring 72 is not restricted to the aluminum wiring as described above, but can be variously modified. For example, a tungsten wiring or a copper wiring (embedded copper wiring) can be used.

Then, an insulation film (not shown) as an interlayer insulation film is formed on the insulation film 62 so as to cover the wiring 72, and further upper wiring layers (third-layer wiring and onward) and others are formed. However, these are not shown or described herein. Then, after hydrogen annealing at approximately 400 degrees Celsius to 450 degrees Celsius is performed, a semiconductor device (semiconductor memory device) is completed.

Next, effects according to the present embodiment are described in detail below.

Chalcogenide for use as a material of the recording layer (52) of the phase-change memory has a low adhesiveness with an interlayer insulation film made of silicon oxide, for example, and is prone to be peeled off by stress caused from the upper electrode film (53) formed on the recording layer (52). Therefore, in order to prevent such peeling as described above, the upper electrode film (53) formed on the recording layer (52) is preferable to be made thinner (for example, made thinner so as to have a film thickness on the order of 50 nm). With this, the stress caused from the upper electrode film (53) onto the recording layer (52) can be reduced, thereby making it difficult for the recording layer (52) to be peeled off and improving reliability of the semiconductor device having a phase-change memory. However, making the upper electrode film (53) thinner may pose problems to the upper electrode film (53) and the recording layer (52) when the via hole (63) for the plug (64) connected to the upper electrode film (53) is made.

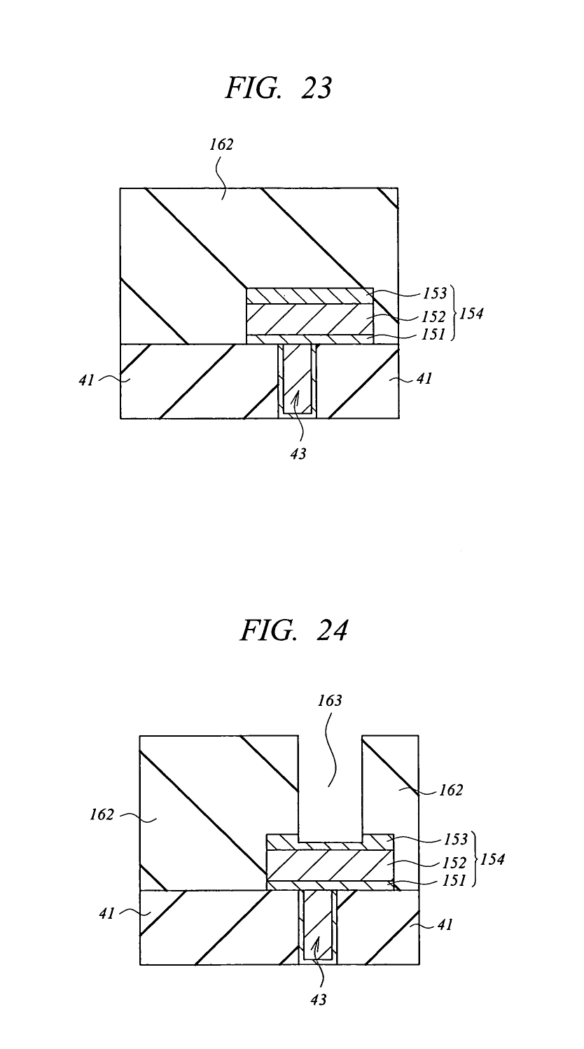

A first problem is over-etching of the upper electrode film (53) at the time of etching for forming the via hole (63) on the upper portion of the upper electrode film (53). Damage caused by over-etching of the upper electrode film (53) is one of the problems unique to the phase-change memory. This first problem is described with reference to a first comparative example. FIGS. 23 to 25 are cross-section views of main parts of a semiconductor device according to the first comparative example during a manufacturing process, depicting an area near a resistance element 154.

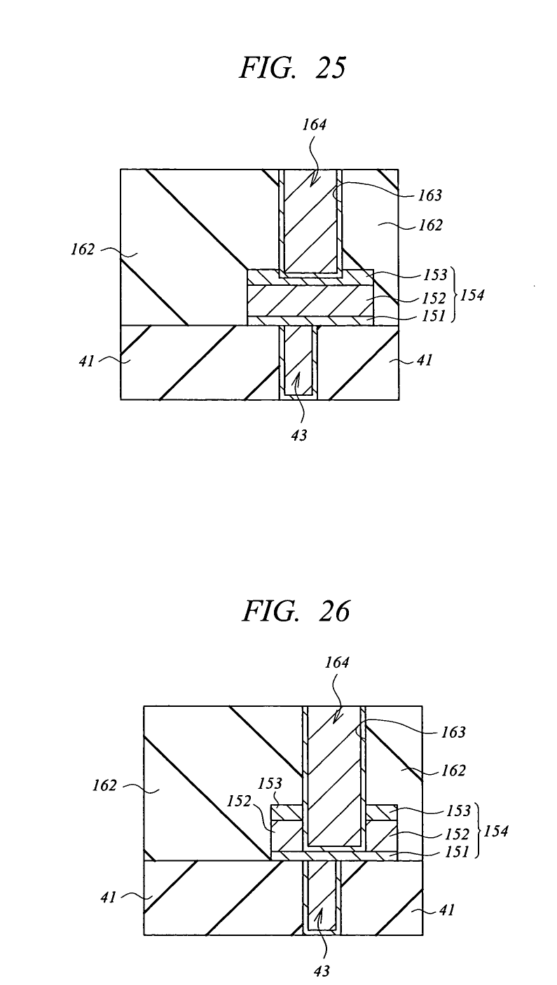

In the first comparative example, as shown in FIG. 23, approximately similarly with the present embodiment, the insulation film 41 with the plug 43 embedded therein has formed thereon the resistor element 154 formed of a laminated pattern of a peel-preventive film 151, a recording layer 152 made of chalcogenide, and an upper electrode film 153. However, unlike the present embodiment, no etching stopper film as the insulation film 61 is formed, and an interlayer insulation film 162 of a single film made of silicon oxide is formed on the insulation film 41 so as to cover the resistor element 154. Here, the peel-preventive film 151, the recording layer 152, the upper electrode film 153, and the resistor element 154 correspond to the peel-preventive film 51, the recording layer 52, the upper electrode film 53, and the resistor element 54 in the present embodiment, respectively. FIG. 23 is a cross-section view of the main parts at a process stage corresponding to FIG. 18 described above. Then, as shown in FIG. 24, dry etching is performed on the interlayer insulation film 162 to form a via hole 163 (corresponding to the via hole 63 in the present embodiment) from which the upper electrode film 153 of the resistor element 154 is exposed. Then, as shown in FIG. 25, a plug 164 (corresponding to the plug 64 in the present embodiment) connected to the upper electrode film 153 of the resistor element 154 is formed in the via hole 164.

As described above, since the recording layer 152 made of chalcogenide is prone to be peeled off and the stress from the upper electrode film 153 has to be suppressed in order to prevent peeling, the film thickness of the upper electrode film 153 of the memory cell of the phase-change memory is preferably made thinner. A metal for use as the upper electrode film 153 of the phase-change memory is, for example, tungsten, and has a film thickness of, for example, 50 nm. On the other hand, for the interlayer insulation film 162 for covering the memory cell (resistor element 154), silicon oxide is used, for example, and has a film thickness of, for example, 500 nm. Normally, a selectivity of dry etching of silicon oxide to tungsten is approximately 10 and, when dry etching is performed on the interlayer insulation film 162 (silicon oxide) to form the via hole 163, if over-etching is done, the upper electrode film 153 made of tungsten is etched. For example, the amount of cutting (amount of etching) of the upper electrode film 153 made of tungsten with over-etching of 150% is on the order of 25 nm. FIGS. 24 and 25 depict the state where, in the process of dry etching for forming the via hole 163, the upper electrode film 153 is over-etched to cause the film thickness of the upper electrode film 153 to partially become thinner at the bottom of the via hole 163.

As shown in FIGS. 24 and 25, the portion of the upper electrode film 153 having a thinner film thickness due to over-etching has an increased resistance value, which will cause variations in resistance value of the resistor element 154. Also, the thinned portion of the upper electrode film 153 is susceptible to etching damage at the time of dry etching and heat-load damage at the time of forming the conductive film for the plug 164. With this, the characteristics of the recording layer 152 (chalcogenide characteristics) in an area immediately below the thinned portion tend to be changed, thereby causing deterioration in reliability of electrical characteristics of the phase-change memory. A reason for deterioration in reliability of the electrical characteristics is that the chalcogenide material for use in the phase-change memory has a crystallization temperature of approximately 400 degrees Celsius and a melting point of approximately 625 degrees Celsius, both of which are lower than those of the material for use in the conventional memory technology.

FIG. 26 depicts a cross-section view of the main parts of the semiconductor device according to another comparative example when the amount of over-etching of the interlayer insulation film 162 at the time of formation of the via hole 163 is further increased, for example, when 200% over-etching is performed. In the case of 200% over-etching, as shown in FIG. 26, the upper electrode film 153 made of tungsten is penetrated, and the recording layer 152 made of chalcogenide is exposed at the bottom of the via hole 163. This will cause reduction in yields and deterioration in reliability of the electrical characteristics of the semiconductor device having a phase-change memory.

To prevent the upper electrode film 153 from being etched at the time of formation of the via hole 163, the amount of over-etching of the interlayer insulation film 162 can be decreased. In this case, however, a possibility arises where the via hole 163 may not reach the upper electrode film 153, thereby possibly decreasing reliability of electrical connection between the plug 164 and the upper electrode film 153. This will decrease semiconductor devices' manufacturing yields.

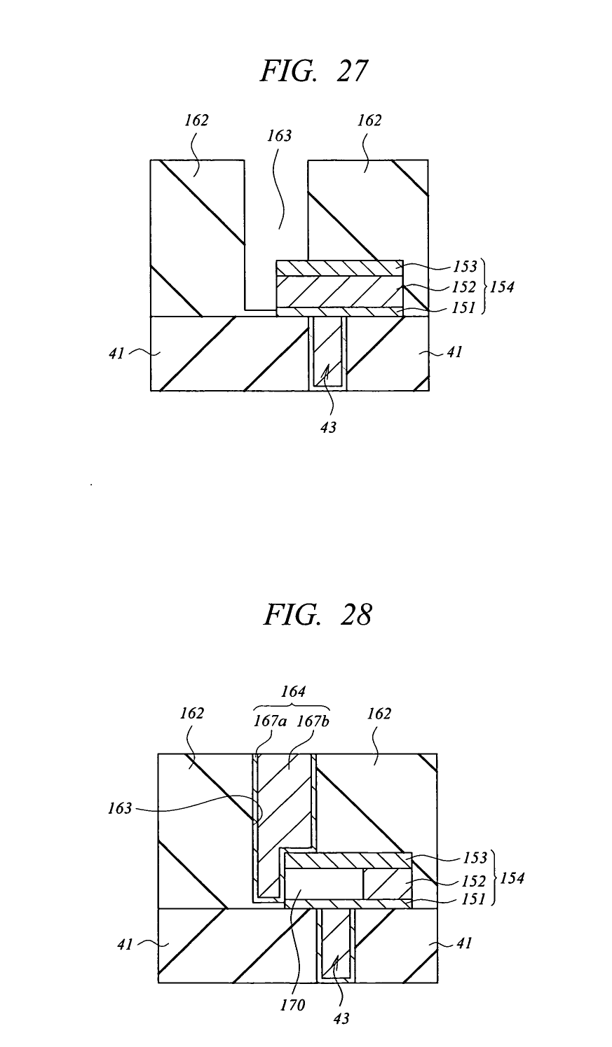

A second problem is that when the via hole for forming the plug is formed on the upper electrode film, the occurrence of misalignment (alignment deviation) will cause a sidewall of the recording layer (phase-change film) to be exposed from the via hole, from which the recording layer will be partially sublimated. This is also another one of the problems unique to the phase-change memory. This second problem is described with reference to a second comparative example. FIGS. 27 and 28 are cross-section views of main parts of a semiconductor device according to the second comparative example during a manufacturing process, depicting an area corresponding to those in FIGS. 24 and 25 in the first comparative example described above.

After a structure similar to that shown in FIG. 23 depicting the first comparative example is obtained, as shown in FIG. 27, dry etching is performed on the interlayer insulation film 162 to form the via hole 163. At this time, the occurrence of misalignment (alignment deviation) will cause a sidewall of the recording layer 152 to be exposed from a sidewall of the via hole 163.

Then, as shown in FIG. 28, the plug 164 is formed in the via hole 163. The plug 164 is formed of a conductive barrier film 167a (corresponding to the conductive barrier film 67a in the present embodiment) and a tungsten film 167b (corresponding to the tungsten film 67b in the present embodiment). The recording layer 152 may be damaged by temperature hysteresis at the time of forming the conductive barrier film 167a. The recording layer 152 has a relatively low sublimation temperature in vacuum of, for example, approximately 400 degrees Celsius, and therefore has a property of being prone to be sublimated. On the other hand, the conductive barrier film 167a has a film-forming temperature of, for example, approximately 500 degrees Celsius or higher, which is higher than the sublimation temperature of the recording layer 152. Therefore, after the via hole 163 is formed and before or during the formation of the conductive barrier film 167a, the recording layer 152 with its sidewall exposed may be partially sublimated. When the recording layer 152 is partially sublimated, as shown in FIG. 28, a cavity 170 is formed where the recording layer 152 is partially lost and not present. This will cause open-bit defects or variations in resistance value of the resistor element 154, thereby possibly decreasing manufacturing yields and reliability of the semiconductor device having a phase-change memory.

Also, when sublimation of the recording layer 152 occurs, a foreign substance is generated near the lower portion of the via hole 163. This foreign substance acts as a parasitic resistance with respect to the resistor element 154 of the phase-change memory. With this parasitic resistance, deterioration in characteristics, reliability, and yields of the phase-change memory may occur.

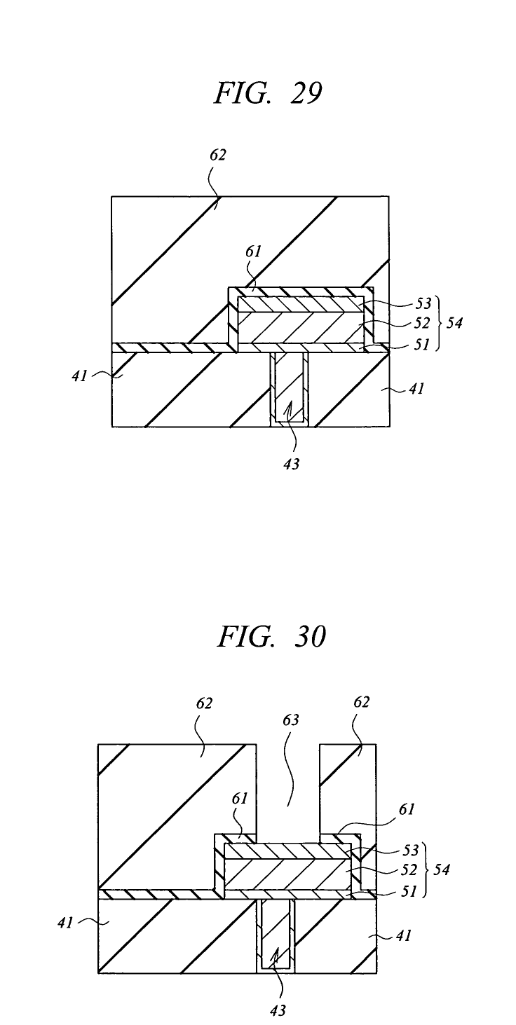

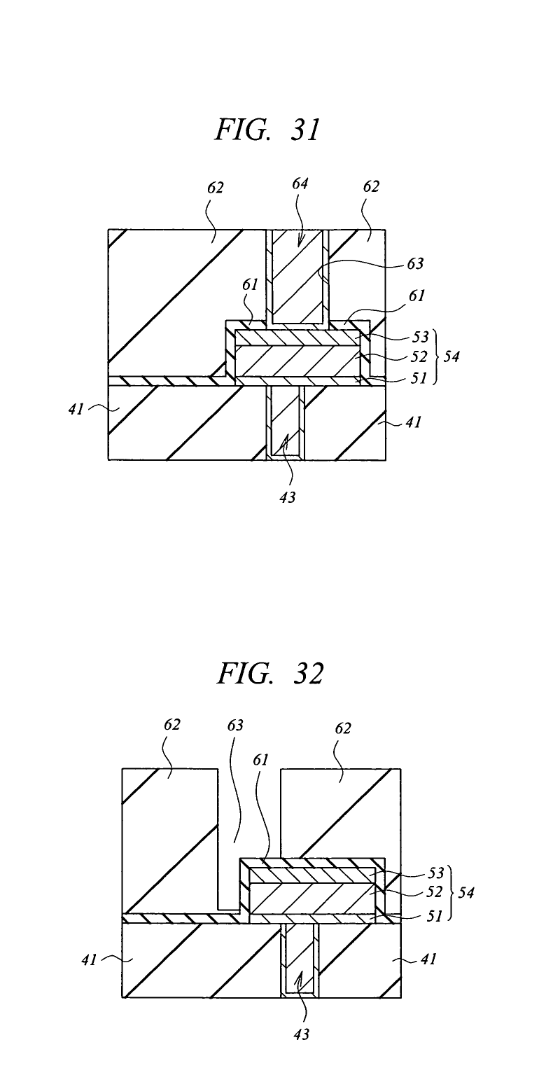

FIGS. 29 to 31 are cross-section views of main parts of the semiconductor device according to the present embodiment, depicting an area near the resistor element 54. FIG. 29 corresponds to a process stage identical to that of FIG. 18 described above, FIG. 30 corresponds to a process stage identical to that of FIG. 20 described above, and FIG. 31 corresponds to a process stage identical to that of FIG. 21 described above or after that.

In the present embodiment, as shown in FIG. 29, the insulation film 61 functioning as an etching stopper film is formed on the upper surface of the upper electrode film 53 of the resistor element 54. Therefore, in the process of forming the via hole 63 shown in FIG. 30, as described with reference to FIGS. 19 and 20, dry etching is first performed under the conditions where the insulation film (interlayer insulation film) 62 is more prone to be etched with the insulation film 61 functioning as an etching stopper film, and then etching is performed under the conditions where the insulation film 61 is more prone to be etched, thereby exposing the upper electrode film 53 at the bottom of the via hole 63. With this, as shown in FIG. 30, the via hole 63 causing the upper electrode film 53 with at least a part of it is exposed can be formed, and the upper electrode film 53 can be prevented from being excessively etched (over-etched) at the bottom of the via hole 63. Then, as shown in FIG. 31, the plug 64 is formed in the via hole 63. With this, it is possible to suppress or prevent the upper electrode film 53 from being partially made thinner at the bottom of the via hole 63, thereby mitigating or solving the first problem as described above with reference to the first comparative example shown in FIGS. 23 to 26. That is, in the present embodiment, since the insulation film 61 is used as an etching stopper film, over-etching of the upper electrode film 53 can be prevented. Also, etching damage at the time of dry etching for forming the via holes 63 and heat-load damage at the time of forming the conductive film for the plugs 64 (the conductive barrier film 67a or the tungsten film 67b) can be suppressed. Thus, changes in characteristics of the recording layer 52 in an area immediately under the plugs 64 can be suppressed or prevented, thereby achieving excellent reliability in electrical characteristics of the phase-change memory.

Also in the present embodiment, the insulation film 61 is formed also on the sidewalls of the resistor element 54. Thus, the insulation film 61 is also formed on the sidewalls of the recording layer 52. With this insulation film 61 on the sidewalls of the recording layer 52 functioning as a protective film, the problem at the time of occurrence of misalignment of the via hole 63 (the above-described second problem) is mitigated or solved.

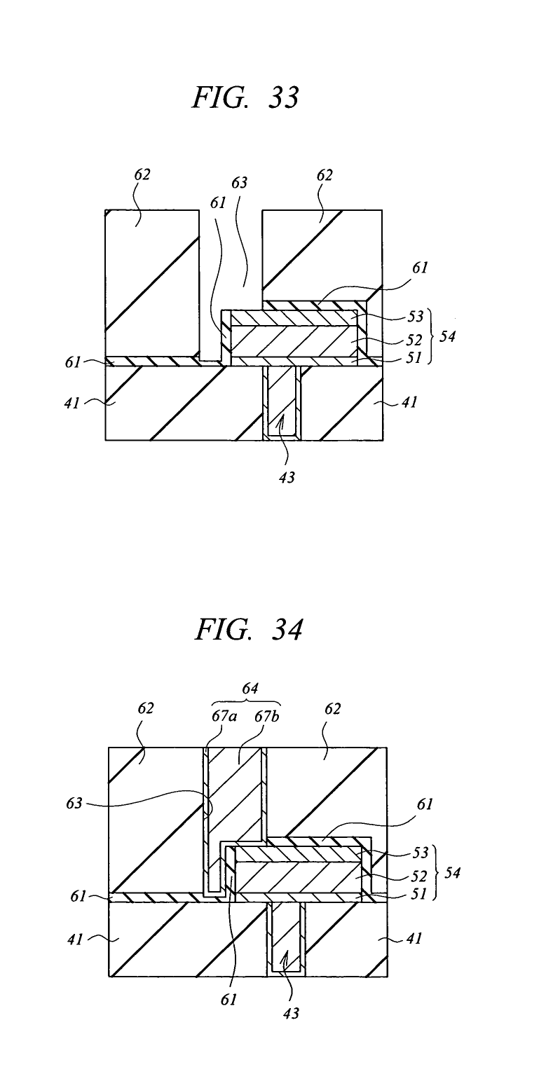

FIGS. 32 to 34 are cross-section views of main parts of the semiconductor device according to the present embodiment during a manufacturing process when misalignment of the via hole 63 occurs, depicting an area near the resistor element 54. FIG. 32 corresponds to a process stage identical to that of FIG. 19 described above, FIG. 33 corresponds to a process stage identical to that of FIG. 20 described above, and FIG. 34 corresponds to a process stage identical to that of FIG. 21 described above or after that.

After the structure of FIG. 29 is obtained, when the via hole 63 is misaligned at the time of forming the via hole 63, at the stage of the first dry etching described above with reference to FIG. 19, as shown in FIG. 32, the insulation film 61 functions as an etching stopper film, and the insulation film 61 is left on the upper electrode film 53 and a sidewall of the resistor element 54 (recording layer 52). Then, at the stage of the second dry etching described above with reference to FIG. 20, as shown in FIG. 33, the insulation film 61 on the upper electrode film 53 is removed to cause the upper electrode film 53 to be at least partially exposed from the via hole 63. By performing the second dry etching through anisotropic dry etching, the insulation film 61 is left on the sidewall of the resistor element 54, particularly on the sidewall of the recording layer 52. Therefore, as shown in FIG. 33, even if misalignment of the via hole 63 occurs, the recording layer 52 can be prevented from being exposed from the via hole 63.

Then, as shown in FIG. 34, the plug 64 is formed in the via hole 63. In the process of forming the conductive barrier film 67a for forming the plug 64, even if the recording layer 52 becomes at a high temperature, the recording layer 52 is not being exposed, and the insulation film 61 is present on the sidewall of the recording layer 52 and functions as a protective film, thereby preventing the recording layer 52 from being sublimated. With this, the second problem as described with reference to the second comparative example shown in FIGS. 27 and 28 can be mitigated or solved. In this manner, in the present embodiment, even if misalignment (alignment deviation) of the via hole 63 occurs, the sidewall of the recording layer 52 is protected by the insulation film 61. The material forming the recording layer 52 has a low sublimation temperature, and has a characteristic of being prone to sublimate by heat hysteresis at the time of forming a conductive film for the plug 64 (conductive barrier film 67a). However, with the insulation film 61 protecting the sidewall of the recording layer 52, sublimation of the recording layer 52 can be suppressed or prevented, thereby making it possible to manufacture a highly-integrated phase-change memory with excellent yields.

In this manner, in the present embodiment, the structure includes the insulation film 61 on the upper surface of the upper electrode film 53 and the sidewall of the recording layer 52 as an etching stopper film or a protective film. With this, manufacturing yields and reliability of the semiconductor device having a phase-change memory can be improved. Also, variations in driving voltage can be reduced, and the number of rewriting can be improved. As such, the performance of the semiconductor device can be improved.

Also, in the present embodiment, the protective film (insulation film 61) is formed on the upper electrode film 53 and the sidewall of the recording layer 52 through the same manufacturing process. Compared with the structure in which the protective film (etching stopper film) on the upper electrode film and the protective film on the sidewall of the recording layer 52 are formed through separate manufacturing processes, manufacturing cost can be reduced, thereby making it possible to manufacture inexpensive semiconductor devices.

Furthermore, in the present embodiment, sublimation of the recording layer 52 can be prevented, as described above. Therefore, at the time of forming the via hole 63, formation of a foreign substance near the lower portion of the via hole 63 can be suppressed and, even if a foreign substance is formed, it can be easily removed through cleaning. Since the recording layer 52 is protected by the insulation film 61, it is easy to remove a foreign substance in the via hole 63. With prevention of the occurrence of a foreign substance near the lower portion of the via hole 63, deterioration in characteristics, reliability, and yields of the phase-change memory due to parasitic resistance of a foreign matter can be prevented.

Still further, in the present embodiment, the insulation film 61 functions as an etching stopper film. Therefore, in an area above the upper electrode film 53, the insulation film 61 preferably has a film thickness thinner than the film thickness of the insulation film 62 and, more preferably, thinner than that of the upper electrode film 53. If the film thickness of the insulation film 61 is too thick and dry etching is performed on the insulation film 61 in a slightly over-etching manner in order to reliably expose the upper electrode film 53 at the bottom of the via hole 63, the amount of etching of the upper electrode film 53 may be increased. With the film thickness of the insulation film 61 thinner than the film thickness of the insulation film 62 and, more preferably, thinner than that of the upper electrode film 53, even if dry etching is performed on the insulation film 61 in a slightly over-etching manner in order to reliably expose the upper electrode film 53 at the bottom of the via hole 63, the amount of over-etching can be small. With this, the amount of etching of the upper electrode film 53 can be reduced, thereby more reliably preventing the upper electrode film 53 from being partially thinned at the bottom of the via hole 63.

Still further, in the present embodiment, the insulation film 61 is used as an etching stopper film. Therefore, for the insulation film 61, a material allowing an etching speed (etch rate) to be different from that of the insulation film 62 formed thereon as an interlayer insulation film is used. That is, for the insulation film 61, an insulation film with a large etching selectivity with respect to the interlayer insulation film (insulation film 62) formed thereon is used. Therefore, the insulation film 61 is made of a material different from that of the insulation film 62 as an interlayer insulation film. Since the insulation film 62 functions as an interlayer insulation film, it can be formed of, for example, a silicon oxide film. The insulation film 61 can be made of a material different from that of the insulation film 62 and, more preferably, can be formed of a silicon nitride film. With this, the etching selectivityn between the insulation film 61 and the insulation film 62 formed thereon as an interlayer insulation film can be increased. Still further, since the insulation film 61 is formed with a side surface of the recording layer 52 being exposed, the recording layer 52 may possibly be sublimated if the film-forming temperature of the insulation film 61 is higher than the sublimation temperature of the recording layer 52. However, with the insulation film 61 being formed of a silicon nitride film, the film-forming temperature of the insulation film 61 can be made relatively low, thereby allowing film formation at a temperature at which the recording layer 52 does not sublimate (for example, equal to or lower than 400 degrees Celsius). With this, sublimation of the recording layer 52 at the time of forming the insulation film 61 can be prevented, thereby further increasing reliability of the semiconductor device having a phase-change memory.

### Second Embodiment

In the first embodiment described above, the upper electrode film 53 and the recording layer 52 are patterned to form the resistor element 54, and then the insulation film 61 as an etching stopper film is formed so as to cover the resistor element 54. In the present embodiment, an insulation film 61a as an etching stopper film is formed before the recording layer 52 and the upper electrode film 53 are patterned.

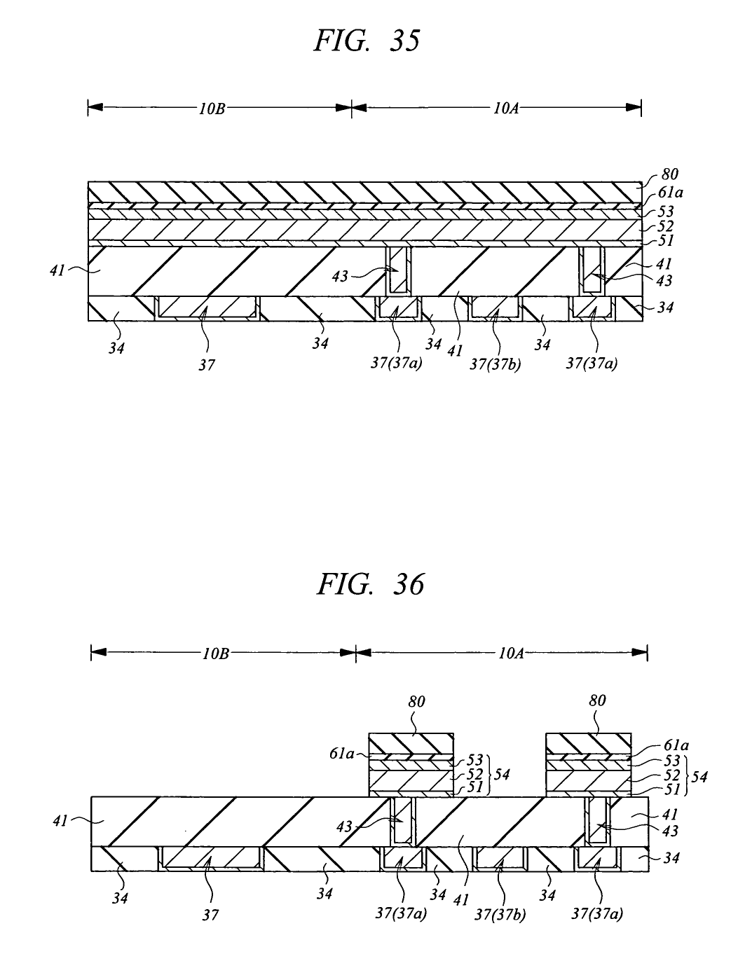

FIGS. 35 to 40 are cross-section views of main parts of a semiconductor device according to the present embodiment during the manufacturing process continued from FIG. 15 of the first embodiment. The manufacturing process up to FIG. 15 is similar to that of the first embodiment, and therefore is not described herein, and the process continued from FIG. 15 is now described. Here, for ease of understanding, in FIGS. 35 to 40, like in FIGS. 15 to 22 of the first embodiment, the insulation film 31 and portions corresponding to the structure therebelow in FIG. 14 are omitted.

After the structure shown in FIG. 15 is formed in a manner similar to that of the first embodiment, as shown in FIG. 35, the insulation film (etching stopper film) 61a is formed on the laminated film of the peel-preventive film 51, the recording layer 52, and the upper electrode film 53, that is, on the upper electrode film 53. The insulation film 61a is made of a material similar to that of the insulation film 61 according to the first embodiment (for example, silicon nitride film), and can be formed in a manner similar to that of the first embodiment. Also, the insulation film 61a has a film thickness similar to that of the insulation film 61 (for example, 5 to 20 nm).

Next, on the insulation film 61a, an insulation film 80 for hard mask is formed, which is made of silicon oxide, for example.

Next, as shown in FIG. 36, with a photoresist pattern (not shown) formed on the insulation film 80 through photolithography as an etching mask, dry etching is performed on the insulation film 80 for processing (patterning), and then this photoresist pattern is removed. Then, with the patterned insulation film 80 as a hard mask (etching mask), dry etching is performed on the upper electrode film 53, the recording layer 52, and the peel-preventive film 51 for processing (patterning). With this, a laminated film (laminated pattern) of the patterned insulation films 80 and 61a, upper electrode film 53, recording layer 52, and peel-preventive film 51 is formed. The resistor element 54 composed of the laminated pattern of the upper electrode film 53, the recording layer 52, and the peel-preventive film 51 is formed on the insulation film 41 with the plugs 43 embedded therein. Also, the insulation film 61a is formed on the (entire) upper surface of the upper electrode film 53, and the insulation film 80 is formed on that insulation film 61a. Here, in the present embodiment, the resistor element 54 is processed by using the insulation film 80 as a hard mask. Alternatively, formation of the insulation film 80 may be omitted, and the resistor element 54 may be processed by using only the photoresist pattern.

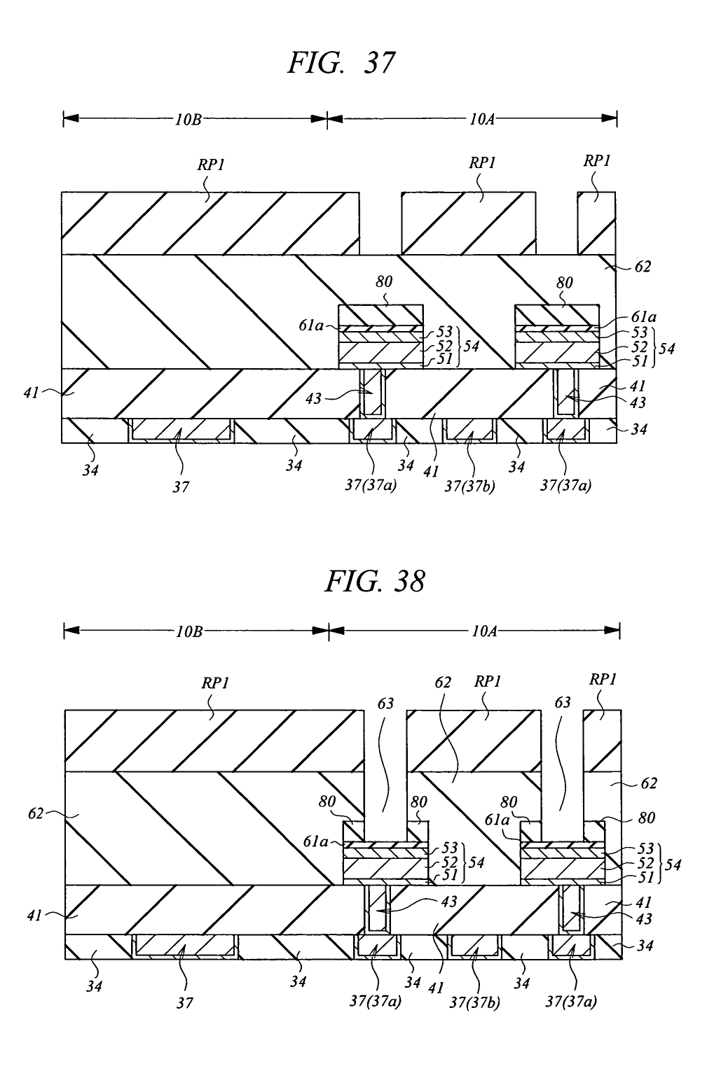

Next, as shown in FIG. 37, the insulation film 62 is formed on the insulation film 41 so as to cover the laminated pattern of the insulation films 80 and 61a, the upper electrode film 53, the recording layer 52, and the peel-preventive film 51. After formation of the insulation film 62, the upper surface of the insulation film 62 can be planarized, as required, through, for example, CMP. Then, by using photolithography, the photoresist pattern RP1 is formed on the insulation film 62.

Next, as shown in FIG. 38, with the photoresist pattern RP1 as an etching mask, dry etching (first dry etching) is performed on the insulation films 62 and 80, thereby forming the via holes 63 through the insulation films 62 and 80. As with the first dry etching in the first embodiment, at the time of this dry etching (first dry etching) of the insulation films 62 and 80, dry etching is performed under the conditions where the insulation films 62 and 80 (silicon oxide) are more prone to be etched than the insulation film 61a (silicon nitride) (that is, under conditions where an etching speed of the insulation films 62 and 80 is higher than an etching speed of the insulation film 61a), with the insulation film 61a functioning as an etching stopper. At this stage, the insulation film 61a is exposed at the bottom of the via holes 63. However, since the insulation film 61a functions as an etching stopper, etching stops with the insulation film 61a being exposed at the bottom of the via holes 63, and the upper electrode film 53 of the resistor element 54 is not exposed. Here in the present embodiment, a combination of the insulation film 62 and the insulation film 80 corresponds to the insulation film 62 in the first embodiment.

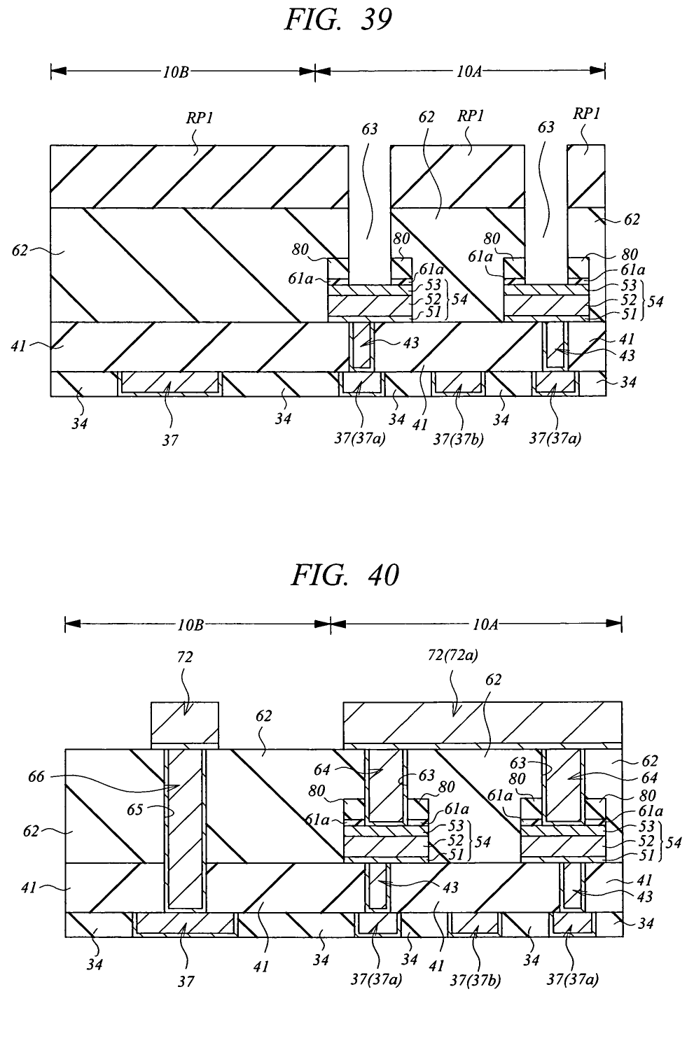

Then, as with the second dry etching in the first embodiment, as shown in FIG. 39, dry etching (second dry etching) is performed under the conditions where the insulation film 61a (silicon nitride) is more prone to be etched than the insulation films 62 and 80 (silicon oxide) (that is, under conditions where an etching speed of the insulation film 61a is higher than an etching speed of the insulation films 62 and 80). Then, the insulation film 61a exposed at the bottom of the via holes 63 is removed through dry etching. With this, at the bottom of the via holes 63, the upper electrode film 53 on the resistor element 54 is exposed. Then, the photoresist pattern RP1 is removed.

Here, at the stage before formation of the via holes 63, the state is such that the insulation film 61a is formed on the entire upper surface of the upper electrode film 53. However, at the time of forming the via holes 63, the insulation film 61a on the upper electrode film 53 is removed at the bottom of the via holes 63. Therefore, after formation of the via holes 63 and the plugs 64 (after manufacturing the semiconductor device), the insulation film 61a is formed on the upper surface of the upper electrode film 53 other than the portion exposed from the via holes 63 and under (below) the insulation film 62.

The manufacturing process thereafter is approximately similar to that of the first embodiment. That is, as shown in FIG. 40, the via hole 65 is formed through the insulation films 62 and 41, the plug 64 is formed in each of the via holes 63 and the plug 66 is formed in the via hole 65, and the wiring 72 is formed on the insulation film 62 with plugs 64 and 66 embedded therein.

In the present embodiment, the insulation film 61a as an etching stopper film is formed on the upper surface of the upper electrode film 53 of the resistor element 54. Therefore, as with the first embodiment, it is possible to suppress or prevent the upper electrode film 53 from being partially thinned at the bottom of the via holes 63, thereby mitigating or solving the first problem described above with reference to the first comparative example shown in FIGS. 23 to 26. That is, in the present embodiment, since the insulation film 61a is used as an etching stopper film, over-etching of the upper electrode film 53 can be prevented. Also, etching damage at the time of dry etching for forming the via holes 63 and heat-load damage at the time of forming the conductive film for the plugs 64 (the conductive barrier film 67a or the tungsten film 67b) can be suppressed. Thus, changes in characteristics of the recording layer 52 in an area immediately under the plugs 64 can be suppressed or prevented, thereby achieving excellent reliability in electrical characteristics of the phase-change memory.

In this manner, in the present embodiment, the structure includes the insulation film 61a on the upper surface of the upper electrode film 53 as an etching stopper film. With this, manufacturing yields and reliability of the semiconductor device having a phase-change memory can be improved. Also, variations in driving voltage can be reduced, and the number of rewriting can be improved. As such, the performance of the semiconductor device can be improved.

### Third Embodiment

In the first and second embodiments, the resistor element 54 is separated in a bit. In the present embodiment, the phase-change memory cell structure is such that the resistor element 54 is successively provided in a bit.

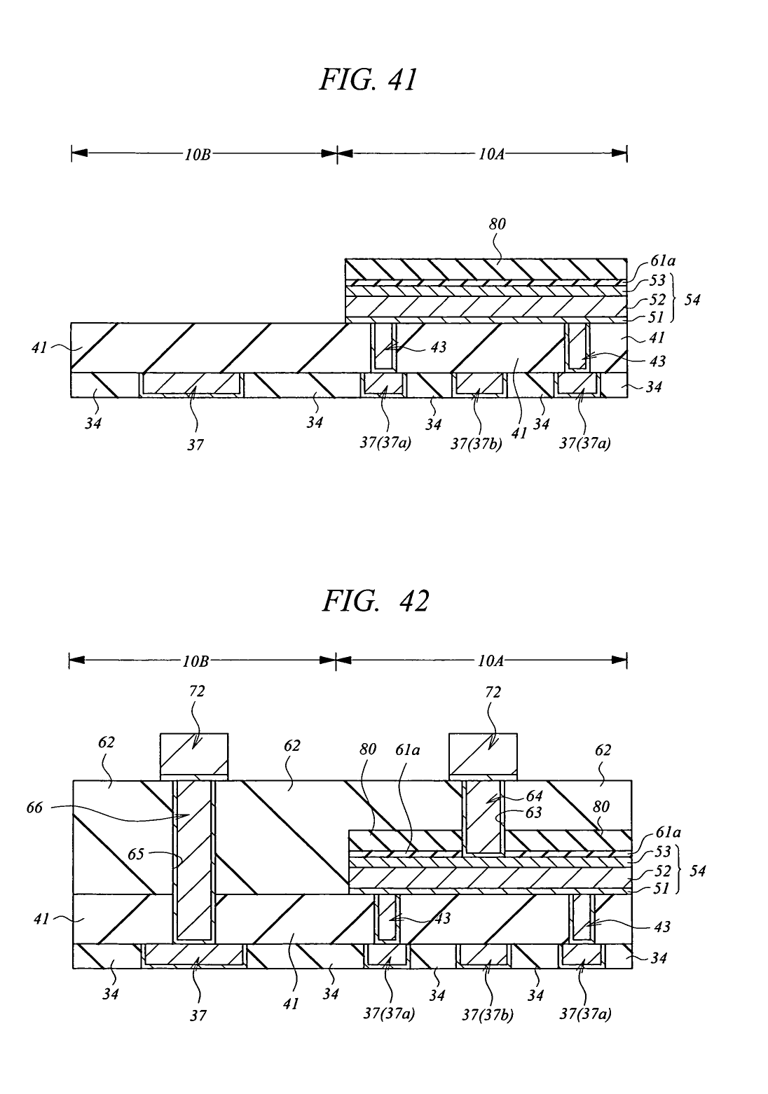

FIGS. 41 and 42 are cross-section views of main parts of a semiconductor device according to the present embodiment during the manufacturing process continued from FIG. 35 of the second embodiment. The manufacturing process up to FIG. 35 is similar to that of the second embodiment, and therefore is not described herein, and the process continued from FIG. 35 is now described. Here, for ease of understanding, in FIGS. 41 and 42, like in FIGS. 15 to 22 of the first embodiment, the insulation film 31 and portions corresponding to the structure therebelow in FIG. 14 are omitted.

After the structure shown in FIG. 35 is formed in a manner similar to that of the second embodiment, as shown in FIG. 41, with a photoresist pattern (not shown) formed on the insulation film 80 through photolithography as an etching mask, dry etching is performed on the insulation film 80 for processing (patterning), and then this photoresist pattern is removed. Then, with the patterned insulation film 80 as a hard mask (etching mask), dry etching is performed on the upper electrode film 53, the recording layer 52, and the peel-preventive film 51 for processing (patterning). With this, a laminated film (laminated pattern) of the patterned insulation films 80 and 61a, upper electrode film 53, recording layer 52, and peel-preventive film 51 is formed. The resistor element 54 composed of the laminated pattern of the upper electrode film 53, the recording layer 52, and the peel-preventive film 51 is formed on the insulation film 41 with the plugs 43 embedded therein. Also, the insulation film 61a is formed on the (entire) upper surface of the upper electrode film 53, and the insulation film 80 is formed on that insulation film 61a.

In the present embodiment, the resistor element 54 is processed in a stripe shape in a direction of the wiring (bit line) 72a shown in FIG. 4 according to the first embodiment. Also, in the present embodiment, the resistor element 54 is in a straight-line shape with the direction of the bit line being taken as a longitudinal direction. Alternatively, needless to say, the resistor element 54 may be in a non-straight-line shape.

The manufacturing process thereafter is approximately similar to that of the second embodiment. That is, as shown in FIG. 42, the insulation film 62 is formed in a manner similar to that of the first and second embodiment. Then, dry etching (first dry etching) is performed on the insulation films 62 and 80, with the insulation film 61a functioning as an etching stopper. Then, dry etching (second dry etching) is performed on the insulation film 61a to form the via hole 63 from which the upper electrode film 53 is exposed. Then, the via hole 65 is formed through the insulation films 62 and 41, and then the plug 64 is formed in the via hole 63 and the plug 66 is formed in the via hole 65. Then, the wiring 72 is formed on the insulation film 62 with the plugs 64 and 66 embedded therein.

Also in the present embodiment, effects similar to those in the second embodiment can be achieved.

Furthermore, in the present embodiment, since the resistor element 54 is successively provided in a bit, it is possible to manufacture a highly-integrated phase-change memory with excellent reliability with a small side-wall exposure area of the recording layer 52.

Furthermore, the present embodiment can be combined not only with the second embodiment but also with the first embodiment and each of the following embodiments.

### Fourth Embodiment

In the first embodiment, the etching stopper film on the upper surface of the upper electrode film 53 and the protective film on the sidewall of the recording layer 52 are formed of the same insulation film 61 in the same process. In the present embodiment, the etching stopper film on the upper surface of the upper electrode film 53 and the protective film on the sidewall of the recording layer 52 are separately formed. That is, in the present embodiment, a side-wall insulation film 61d is formed on the sidewall of the recording layer 52.

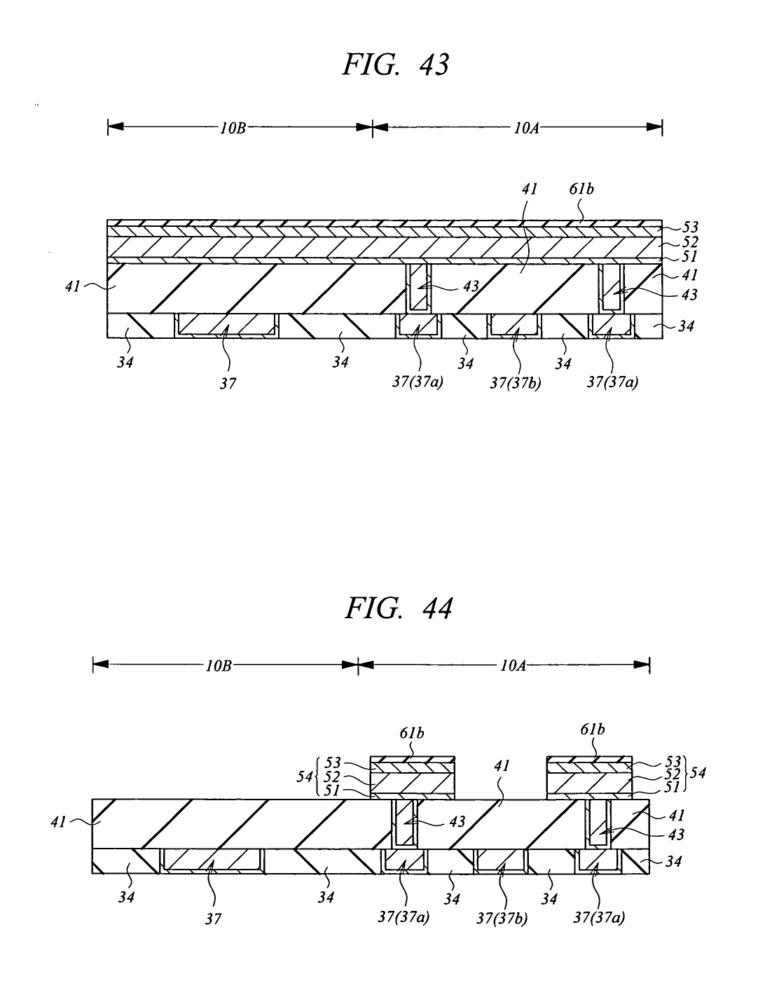

FIGS. 43 to 50 are cross-section views of main parts of a semiconductor device according to the present embodiment during the manufacturing process continued from FIG. 15 of the first embodiment. The manufacturing process up to FIG. 15 is similar to that of the first embodiment, and therefore is not described herein, and the process continued from FIG. 15 is now described. Here, for ease of understanding, in FIGS. 43 to 50, like in FIGS. 15 to 22 of the first embodiment, the insulation film 31 and portions corresponding to the structure therebelow in FIG. 14 are omitted.

After the structure shown in FIG. 15 is formed in a manner similar to that of the first embodiment, as shown in FIG. 43, an insulation film (etching stopper film) 61b is formed on the laminated film of the peel-preventive film 51, the recording layer 52, and the upper electrode film 53, that is, on the upper electrode film 53. The insulation film 61b is made of a material similar to that of the insulation film 61 according to the first embodiment (for example, silicon nitride film), and can be formed in a manner similar to that of the first embodiment. Also, the insulation film 61b has a film thickness similar to that of the insulation film 61 (for example, 5 to 20 nm).

Next, as shown in FIG. 44, with a photoresist pattern (not shown) formed on the insulation film 61b by using photolithography as an etching mask, dry etching is performed on the insulation film 61b, the upper electrode film 53, the recording layer 52, and the peel-preventive film 51 for processing (patterning). With this, a laminated film (laminated pattern) of the patterned insulation film 61b, upper electrode film 53, recording layer 52, and peel-preventive film 51 is formed. At this stage, the resistor element 54 composed of the laminated pattern of the upper electrode film 53, the recording layer 52, and the peel-preventive film 51 is formed on the insulation film 41 with the plugs 43 embedded therein. Also, the insulation film 61b is formed on the (entire) upper surface of the upper electrode film 53.

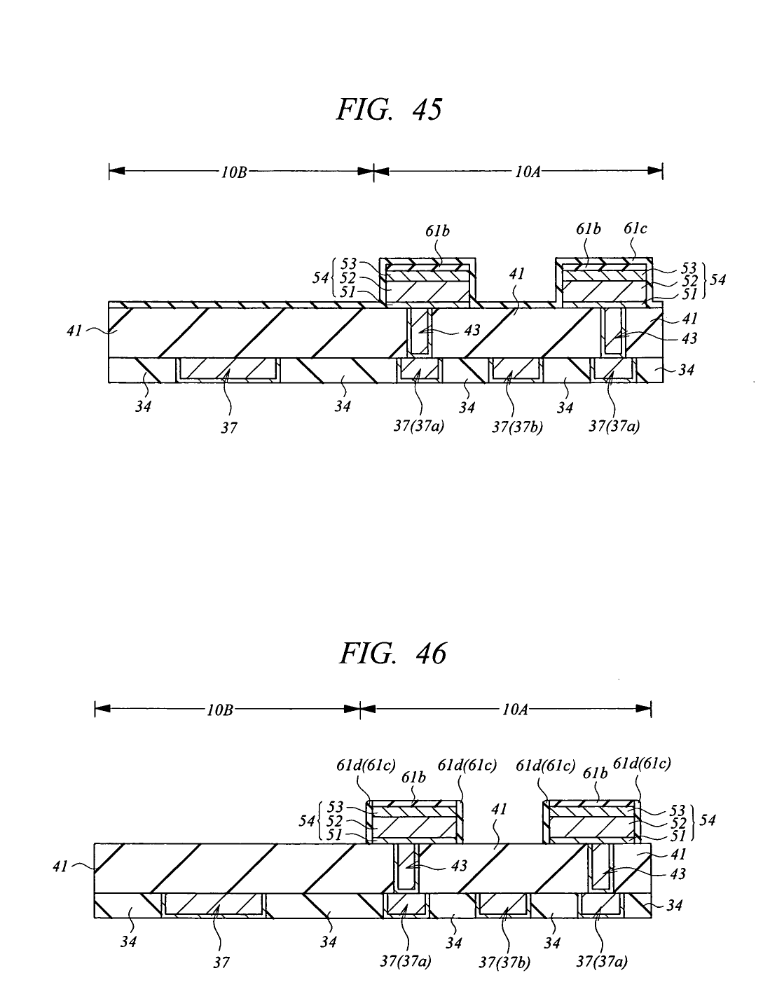

Next, as shown in FIG. 45, an insulation film 61c is formed on the insulation film 41 so as to cover the laminated pattern of the insulation film 61b, the upper electrode film 53, the recording layer 52, and the peel-preventive film 51. For this purpose, the insulation film 61c is formed on the insulation film 41 including the upper surface and side surfaces of the laminated pattern of the insulation film 61b, the upper electrode film 53, the recording layer 52, and the peel-preventive film 51. The insulation film 61c can have a film thickness (deposition film thickness) of, for example, 5 to 50 nm. The insulation film 61c is preferably formed of a material film allowing film formation at a temperature at which the recording layer 52 does not sublimate (for example, equal to or lower than 400 degrees Celsius). More preferably, if a silicon nitride film is used as the insulation film 61c, film formation is possible through, for example, plasma CVD, at a temperature at which the recording layer 52 does not sublimate (for example, equal to or lower than 400 degrees Celsius). With this, sublimation of the recording layer 52 at the time of film formation of the insulation film 61c can be prevented.

Next, as shown in FIG. 46, anisotropic etching is performed on the insulation film 61c. With this, the insulation film 61c is left on the sidewalls (side surfaces) of the laminated pattern of the insulation film 61b, the upper electrode film 53, the recording layer 52, and the peel-preventive film 51, and the insulation film 61c in other areas is removed. At this time, the insulation film 61b on the upper electrode film 53 is left. With this, the side-wall insulation film (sidewall, or side-wall spacer) 61d composed of the insulation film 61c is formed on the sidewalls (side surfaces) of the laminated pattern of the insulation film 61b, the upper electrode film 53, the recording layer 52, and the peel-preventive film 51. Therefore, the insulation film 61b is formed on the (entire) upper surface of the upper electrode film 53 of the resistor element 54, and the side-wall insulation film 61d is formed on the sidewalls (side surfaces) of the resistor element 54 including the sidewalls (side surfaces) of the recording layer 52.

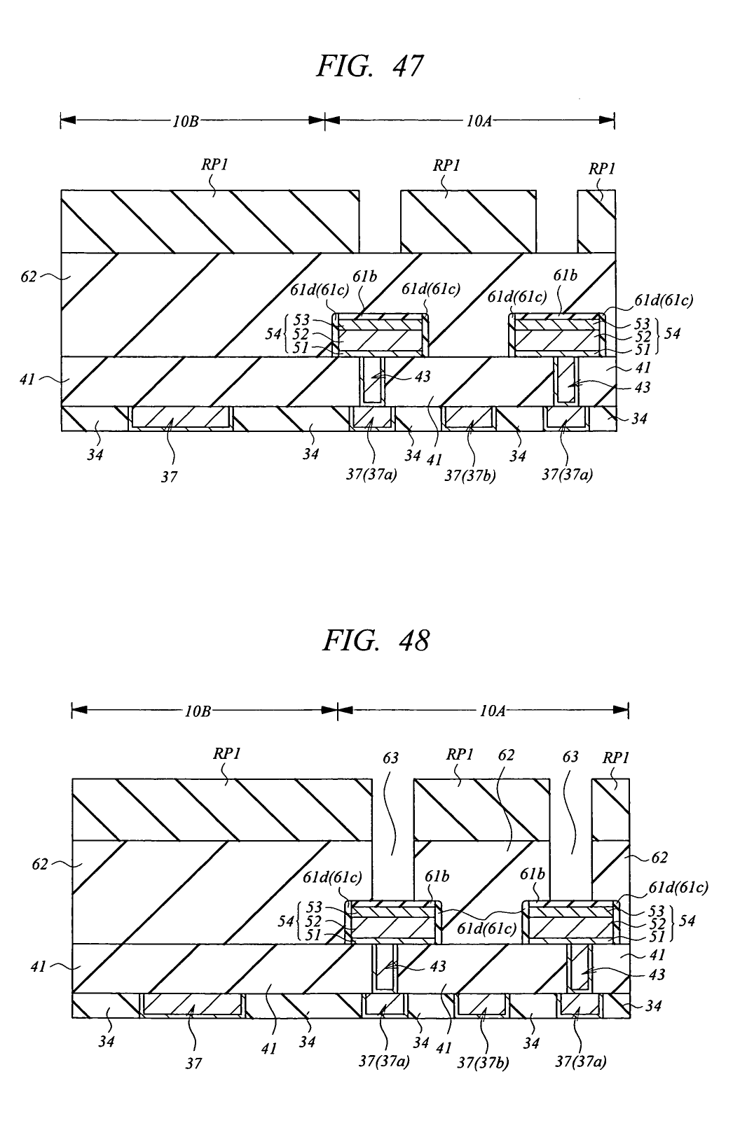

Next, as shown in FIG. 47, the insulation film (interlayer insulation film) 62 is formed on the insulation film 41 so as to cover the resistor element 54 (laminated pattern of the upper electrode film 53, the recording layer 52, and the peel-preventive film 51) having formed on its upper surface and sidewalls the insulation film 61b and the side-wall insulation film 61d. After formation of the insulation film 62, the upper surface of the insulation film 62 can be planarized, as required, through, for example, CMP. Then, by using photolithography, the photoresist pattern RP1 is formed on the insulation film 62.

Next, as shown in FIG. 48, with the photoresist pattern RP1 as an etching mask, dry etching (first dry etching) is performed on the insulation film 62, thereby forming the via holes 63 through the insulation film 62. As with the first dry etching according to the first embodiment, at the time of this dry etching (first dry etching) of the insulation film 62, dry etching is performed under conditions where the insulation film 62 (silicon oxide) is more prone to be etched than the insulation film 61b (silicon nitride) (that is, under conditions where an etching speed of the insulation film 62 is higher than an etching speed of the insulation film 61b), with the insulation film 61b functioning as an etching stopper film. At this stage, the insulation film 61b is exposed at the bottom of the via holes 63. However, since the insulation film 61b functions as an etching stopper, etching stops with the insulation film 61b being exposed at the bottom of the via holes 63, and the upper electrode film 53 of the resistor element 54 is not exposed.

Then, as with the second dry etching according to the first embodiment, dry etching (second dry etching) is performed under conditions where the insulation film 61b (silicon nitride) is more prone to be etched than the insulation film 62 (silicon oxide) (that is, under conditions where an etching speed of the insulation film 61b is higher than an etching speed of the insulation film 62). This dry etching is performed on the insulation film 61b exposed at the bottom of the via holes 63 for removal. With this, at the bottom of the via holes 63, the upper electrode film 53 of the resistor element 54 is exposed. Then, the photoresist pattern RP1 is removed.

Here, at the stage before formation of the via holes 63, the state is such that the insulation film 61b is formed on the entire upper surface of the upper electrode film 53. However, at the time of forming the via holes 63, the insulation film 61b on the upper electrode film 53 is removed at the bottom of the via holes 63. Therefore, after formation of the via holes 63 and the plugs 64 (after manufacturing the semiconductor device), the insulation film 61b is formed on the upper surface of the upper electrode film 53 other than the portion exposed from the via holes 63 and under the insulation film 62.

The manufacturing process thereafter is approximately similar to that of the first embodiment. That is, as shown in FIG. 50, the via hole 65 is formed through the insulation films 62 and 41, the plug 64 is formed in each of the via holes 63 and the plug 66 is formed in the via hole 65, and the wiring 72 is formed on the insulation film 62 with plugs 64 and 66 embedded therein.

Also in the present embodiment, effects approximately similar to those in the first embodiment can be achieved.

That is, in the present embodiment, the insulation film 61b as an etching stopper film is formed on the upper surface of the upper electrode film 53 of the resistor element 54. Therefore, as with the first embodiment, it is possible to suppress or prevent the upper electrode film 53 from being partially thinned at the bottom of the via holes 63, thereby mitigating or solving the first problem described above with reference to the first comparative example shown in FIGS. 23 to 26. That is, in the present embodiment, since the insulation film 61b is used as an etching stopper film, over-etching of the upper electrode film 53 can be prevented. Also, etching damage at the time of dry etching for forming the via holes 63 and heat-load damage at the time of forming the conductive film for the plugs 64 (the conductive barrier film 67a or the tungsten film 67b) can be suppressed. Thus, changes in characteristics of the recording layer 52 in an area immediately under the plugs 64 can be suppressed or prevented, thereby achieving excellent reliability in electrical characteristics of the phase-change memory.

Also, in the present embodiment, the side-wall insulation film 61d is formed on the sidewalls of the recording layer 52 (or the resistor element 54 including the recording layer 52). With this side-wall insulation film 61d on the sidewalls of the recording layer 52 functioning as a protective film, the problem at the time of occurrence of misalignment of the via hole 63 (the above-described second problem) is mitigated or solved.

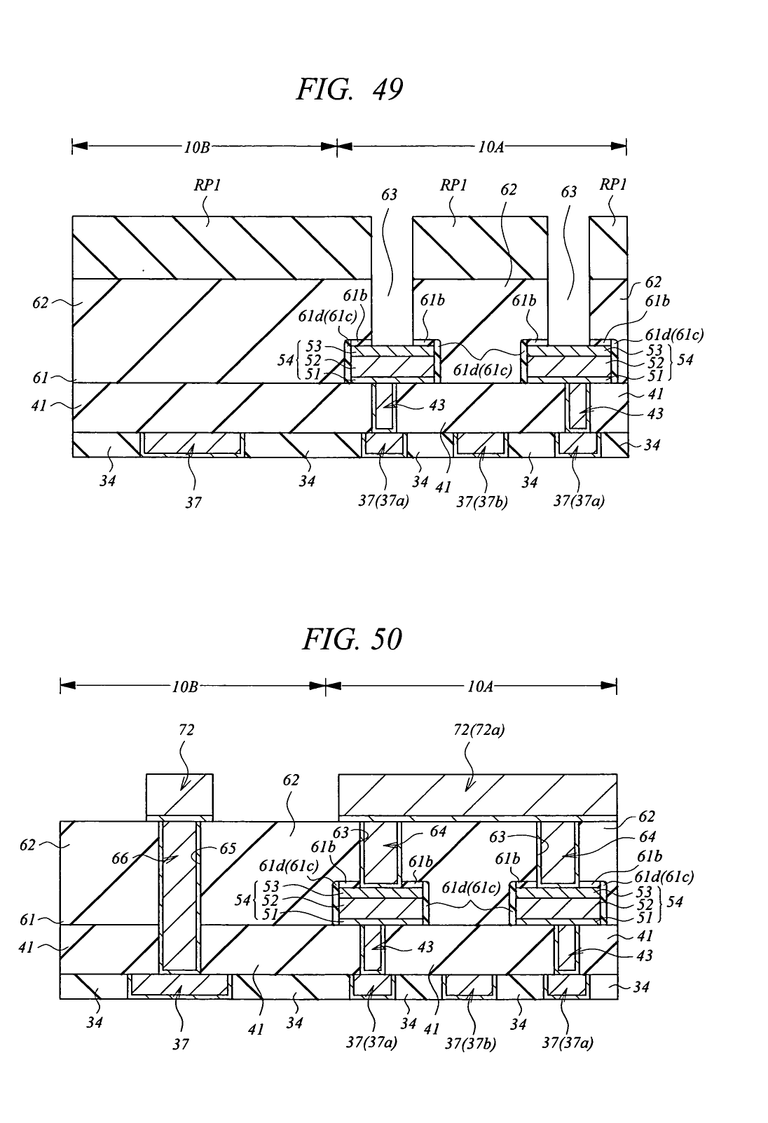

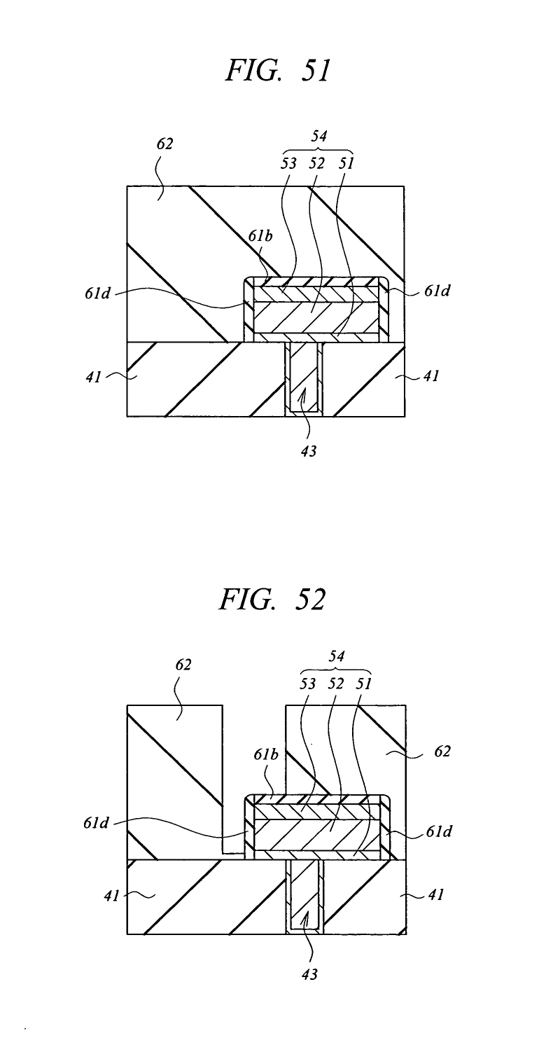

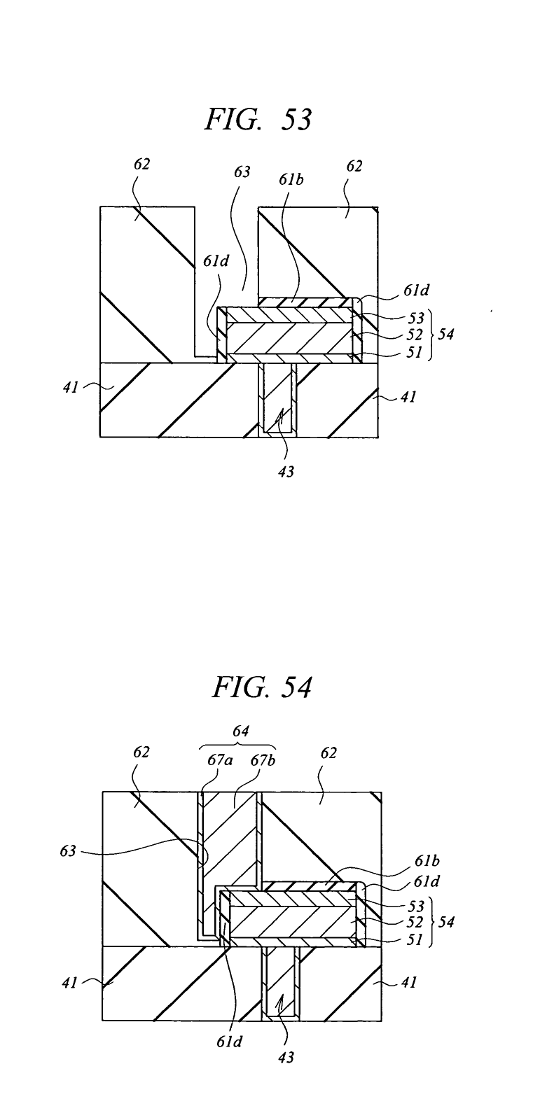

FIGS. 51 to 54 are cross-section views of main parts of the semiconductor device according to the present embodiment during a manufacturing process when misalignment of the via hole 63 occurs, depicting an area near the resistor element 54. FIG. 51 corresponds to a process stage identical to that of FIG. 47 described above, FIG. 52 corresponds to a process stage identical to that of FIG. 48 described above, FIG. 53 corresponds to a process stage identical to that of FIG. 49 described above, and FIG. 54 corresponds to a process stage identical to that of FIG. 50 described above.

In FIG. 51, the insulation film 61b functioning as an etching stopper film is formed on the upper surface of the upper electrode film 53 of the resistor element 54, whilst the side-wall insulation film 61d is formed on the sidewalls of the resistor element 54. After the structure of FIG. 51 is obtained, when the via hole 63 is misaligned at the time of forming the via hole 63, at the stage of the first dry etching described above with reference to FIG. 48, as shown in FIG. 52, the insulation film 61b and the side-wall insulation film 61d function as an etching stopper film, and the insulation film 61b is left on the upper electrode film 53, and the side-wall insulation film 61d is left on a sidewall of the resistor element 54. More preferably, if the side-wall insulation film 61d and the insulation film 61b are made of the same material, at the stage of the first dry etching, the insulation film 61b on the upper electrode film 53 and the side-wall insulation film 61d on the sidewall of the resistor element 54 can be reliably left. Then, at the stage of the second dry etching described above with reference to FIG. 49, as shown in FIG. 53, the insulation film 61b on the upper electrode film 53 is removed to cause the upper electrode film 53 to be at least partially exposed from the via hole 63. By performing the second dry etching through anisotropic dry etching, the insulation film 61d is left on the sidewall of the resistor element 54, particularly on the sidewall of the recording layer 52. Therefore, as shown in FIG. 53, even if misalignment of the via hole 63 occurs, the recording layer 52 can be prevented from being exposed from the via hole 63.

Then, as shown in FIG. 54, the plug 64 is formed in the via hole 63. In the process of forming the conductive barrier film 67a for forming the plug 64, even if the recording layer 52 becomes at a high temperature, the recording layer 52 is not being exposed, and the side-wall insulation film 61d is present on the sidewall of the recording layer 52 and functions as a protective film, thereby preventing the recording layer 52 from being sublimated. With this, the second problem as described with reference to the second comparative example shown in FIGS. 27 and 28 can be mitigated or solved. In this manner, in the present embodiment, even if misalignment (alignment deviation) of the via hole 63 occurs, the sidewall of the recording layer 52 is protected by the insulation film 61d. The material forming the recording layer 52 has a low sublimation temperature, and has a characteristic of being prone to sublimate by heat hysteresis at the time of forming a conductive film for the plug 64 (conductive barrier film 67a). However, with the side-wall insulation film 61d protecting the sidewall of the recording layer 52, sublimation of the recording layer 52 can be suppressed or prevented, thereby making it possible to manufacture a highly-integrated phase-change memory with excellent yields.

In this manner, in the present embodiment, the structure includes the insulation film 61b and the side-wall insulation film 61d on the upper surface of the upper electrode film 53 and the sidewall of the recording layer 52 as an etching stopper film or a protective film. With this, manufacturing yields and reliability of the semiconductor device having a phase-change memory can be improved. Also, variations in driving voltage can be reduced, and the number of rewriting can be improved. As such, the performance of the semiconductor device can be improved.

### Fifth Embodiment

In the fourth embodiment, the side-wall insulation film 61d is formed on the side surfaces (sidewalls) of the laminated film pattern of the insulation film 61b, the upper electrode film 53, the recording layer 52, and the peel-preventive film 51. The present embodiment corresponds to a case where an insulation film 80 is formed as a hard mask on the insulation film 61b as an etching stopper film in the fourth embodiment.

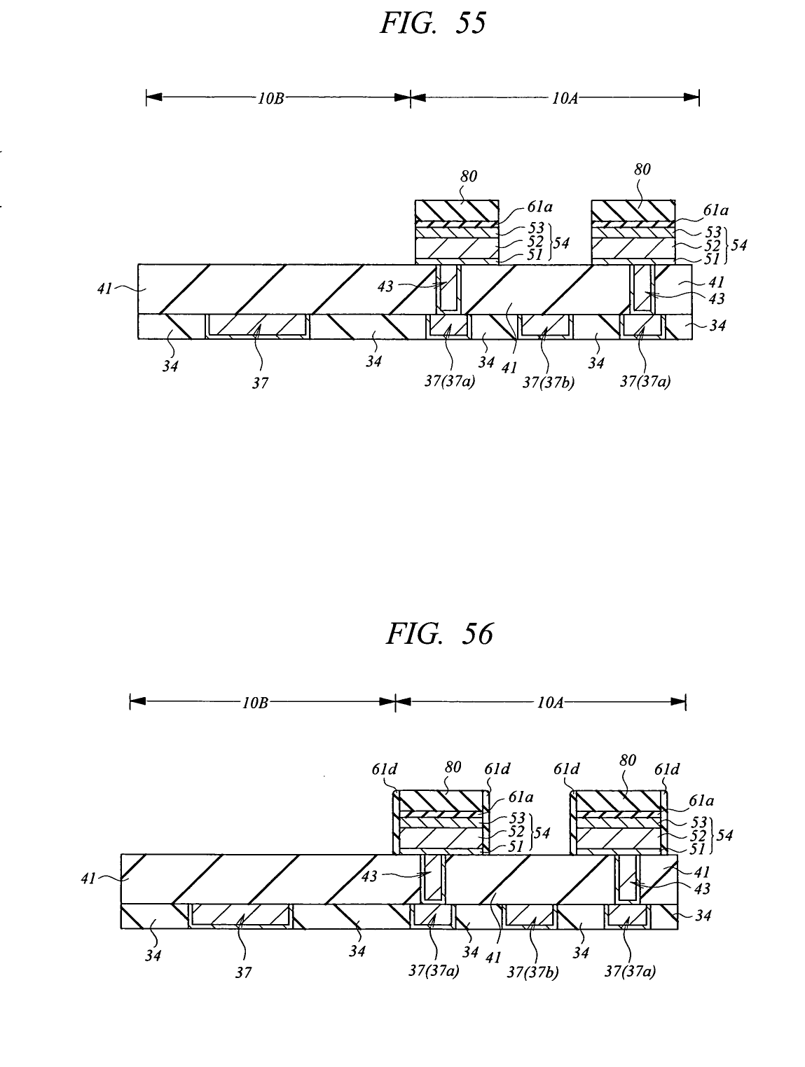

FIGS. 55 and 56 are cross-section views of main parts of a semiconductor device according to the present embodiment during the manufacturing process continued from FIG. 35 of the second embodiment. The manufacturing process up to FIG. 35 is similar to that of the second embodiment, and therefore is not described herein, and the process continued from FIG. 35 is now described. Here, for ease of understanding, in FIGS. 55 and 56, like in FIGS. 15 to 22 of the first embodiment, the insulation film 31 and portions corresponding to the structure therebelow in FIG. 14 are omitted.

After the structure shown in FIG. 35 is formed in a manner similar to that of the second embodiment, as with the second embodiment, as shown in FIG. 55, with a photoresist pattern (not shown) formed on the insulation film 80 by using photolithography as an etching mask, dry etching is performed on the insulation film 80 for processing (patterning), and then this photoresist pattern is removed. Then, with the patterned insulation film 80 as a hard mask (etching mask), dry etching is performed on the upper electrode film 53, the recording layer 52, and the peel-preventive film 51 for processing (patterning). With this, a laminated film (laminated pattern) of the patterned insulation films 80 and 61a, upper electrode film 53, recording layer 52, and peel-preventive film 51 is formed.

Next, as shown in FIG. 56, the side-wall insulation film 61d is formed on the sidewalls (side surfaces) of the laminated pattern of the insulation films 80 and 61a, the upper electrode film 53, the recording layer 52, and the peel-preventive film 51. The side-wall insulation film 61d can be formed in a manner approximately similar to that of the fourth embodiment. That is, the insulation film (61c) is formed on the insulation film 41 so as to cover the laminated pattern of the insulation films 80 and 61a, the upper electrode film 53, the recording layer 52, and the peel-preventive film 51, and then anisotropic etching is performed on this insulation film (61c). With this, the insulation film (61c) left on the sidewalls of the laminated pattern of the insulation films 80 and 61a, the upper electrode film 53, the recording layer 52, and the peel-preventive film 51 is taken as the side-wall insulation film 61d, and the insulation film (61c) in other areas is removed. The process thereafter is approximately similar to that of the second and fourth embodiments, and therefore is not described herein.

In the present embodiment, the structure is approximately similar to that of the fourth embodiment, except that the insulation film 80 for a hard mask for processing the resistor element 54 is formed on the insulation film 61a corresponding to the insulation film 61b, and the side-wall insulation film 61d is formed also on the side surfaces (sidewalls) of this insulation film 80.

Also in the present embodiment, effects approximately similar to those in the fourth embodiment can be achieved.

### Sixth Embodiment

In the fourth embodiment, the side-wall insulation film 61d is formed on the sidewalls of the recording layer 52 before the formation of the via hole 63. On the contrary, in the present embodiment, a side-wall insulation film 61f is formed on the sidewalls of the recording layer 52 after the formation of the via hole 63, and then a plug 64a is formed to fill a via hole 63a.

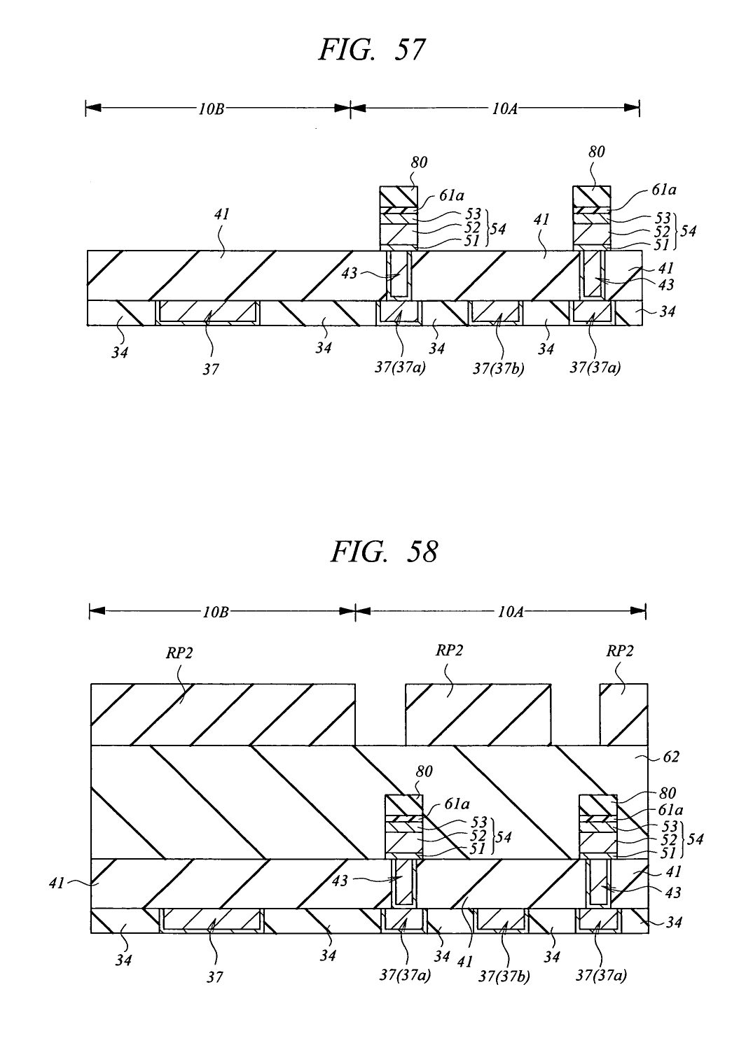

FIGS. 57 to 62 are cross-section views of main parts of a semiconductor device according to the present embodiment during the manufacturing process continued from FIG. 35 of the second embodiment. The manufacturing process up to FIG. 35 is similar to that of the second embodiment, and therefore is not described herein, and the process continued from FIG. 35 is now described. Here, for ease of understanding, in FIGS. 57 to 62, like in FIGS. 15 to 22 of the first embodiment, the insulation film 31 and portions corresponding to the structure therebelow in FIG. 14 are omitted.

After the structure shown in FIG. 35 is formed in a manner similar to that of the second embodiment, as shown in FIG. 57, with a photoresist pattern (not shown) formed on the insulation film 80 by using photolithography as an etching mask, dry etching is performed on the insulation film 80 for processing (patterning), and then this photoresist pattern is removed. Then, with the patterned insulation film 80 as a hard mask (etching mask), dry etching is performed on the upper electrode film 53, the recording layer 52, and the peel-preventive film 51 for processing (patterning). With this, a laminated film (laminated pattern) of the patterned insulation films 80 and 61a, upper electrode film 53, recording layer 52, and peel-preventive film 51 is formed. The resistor element 54 formed of the laminated pattern of the upper electrode film 53, the recording layer 52, and the peel-preventive film 51 is formed on the insulation film 41 with the plugs 43 embedded therein. Also, the insulation film 61a is formed on the (entire) upper surface of the upper electrode film 53, and the insulation film 80 is formed on that insulation film 61a. Here, in the present embodiment, the resistor element 54 is processed by using the insulation film 80 as a hard mask. Alternatively, formation of the insulation film 80 may be omitted, and the resistor element 54 may be processed by using only the photoresist pattern.

Next, as shown in FIG. 58, the insulation film 62 is formed on the insulation film 41 so as to cover the laminated pattern of the insulation films 80 and 61a, the upper electrode film 53, the recording layer 52, and the peel-preventive film 51. After formation of the insulation film 62, the upper surface of the insulation film 62 can be planarized, as required, through, for example, CMP. Then, by using photolithography, a photoresist pattern RP2 is formed on the insulation film 62. Then, the via hole 63a is formed from which the upper electrode film 53 of the resistor element 54 is exposed.

If the plane dimension of the resistor element 54 is reduced, the plane dimension of the memory cell of the phase-change memory can also be reduced, which is advantageous in downsizing the semiconductor device 1. Therefore, in the present embodiment, the plane dimension of the laminated film of the patterned insulation films 80 and 61a, upper electrode film 53, recording layer 52, and peel-preventive film 51 is reduced. However, if the plane dimension of the resistor element 54 is reduced, the aperture diameter of each via hole 63a (corresponding to the via hole 63 in the first embodiment) for exposing the upper electrode film 53 of the resistor element 54 becomes relatively large. With this, misalignment of the via holes 63a with respect to the resistor element 54 has to be tolerated.

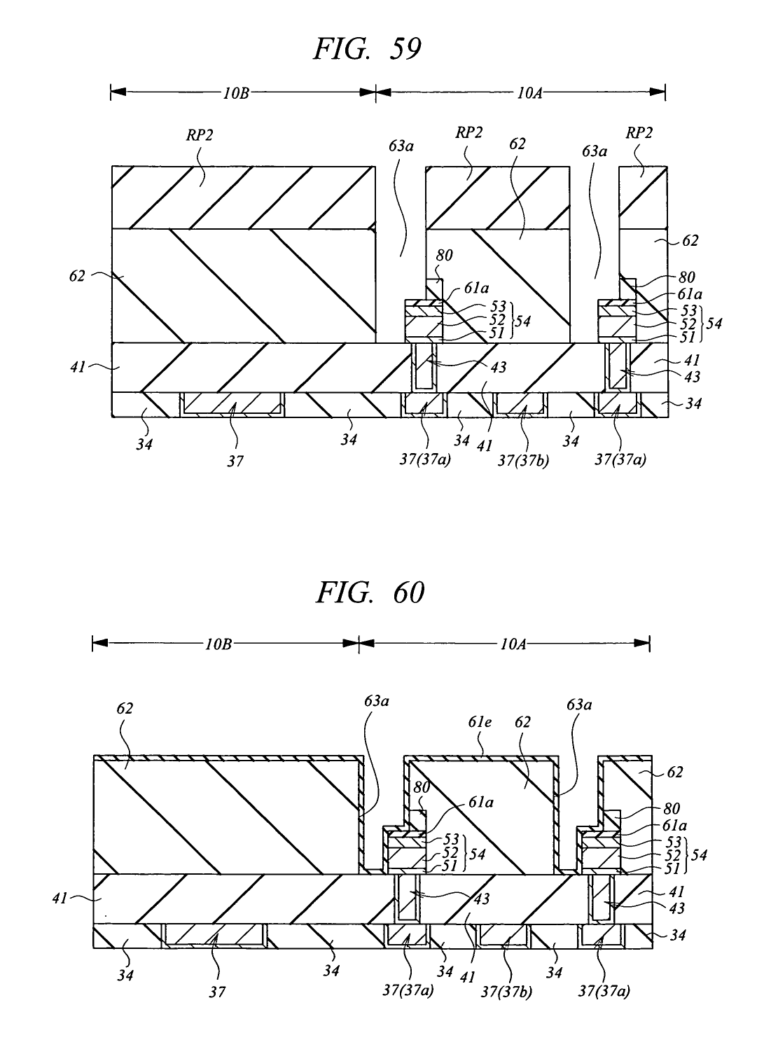

To form the via holes (openings) 63a, as shown in FIG. 59, with the photoresist pattern RP2 as an etching mask, dry etching is performed on the insulation film 62 and the insulation film 80, thereby forming via holes 63a through the insulation films 62 and 80. As with the first dry etching according to the first and second embodiments, at the time of this dry etching on the insulation films 62 and 80, dry etching is performed under conditions where the insulation films 62 and 80 (silicon oxide) are more prone to be etched than the insulation film 61a (silicon nitride) (that is, under conditions where an etching speed of the insulation films 62 and 80 is higher than an etching speed of the insulation film 61a), with the insulation film 61a functioning as an etching stopper. At this stage, the insulation film 61a is exposed at the bottom of the via holes 63a. However, since the insulation film 61a functions as an etching stopper, the upper electrode film 53 of the resistor element 54 is not exposed. Also, each via hole 63a is misaligned with respect to the resistor element 54, and at least a part of a sidewall (side surface) of the insulation film 61a and the resistor element 54 is exposed from the via hole 63a. Then, the photoresist pattern RP2 is removed.

Next, as shown in FIG. 60, an insulation film 61e is formed on the insulation film 62 including the bottom and sidewalls of the via holes 63a. With this, the insulation film 61e is formed also on the sidewall of the resistor element 54 exposed from the via hole 63a, that is, on the sidewall of the recording layer 52. The insulation film 61e can have a film thickness (deposition film thickness) of, for example, 5 to 50 nm. The insulation film 61e is preferably formed of a material film allowing film formation at a temperature at which the recording layer 52 does not sublimate (for example, equal to or lower than 400 degrees Celsius). More preferably, if a silicon nitride film is used as the insulation film 61e, film formation is possible through, for example, plasma CVD, at a temperature at which the recording layer 52 does not sublimate (for example, equal to or lower than 400 degrees Celsius). With this, sublimation of the recording layer 52 at the time of film formation of the insulation film 61e can be prevented.

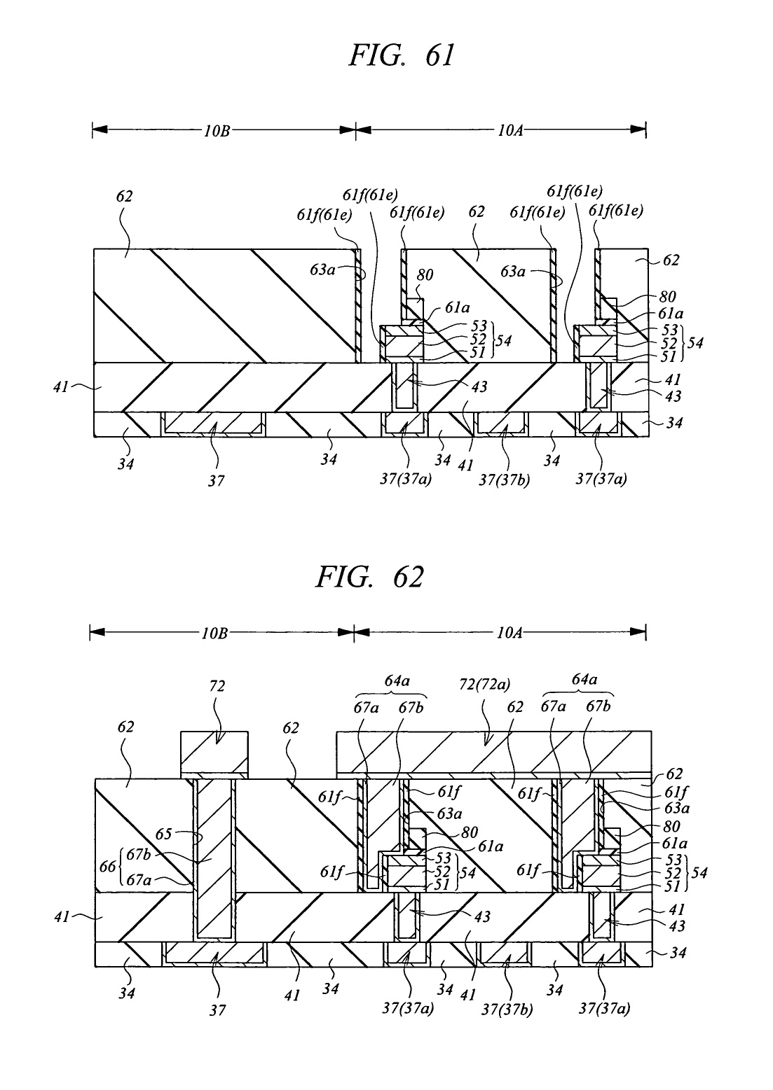

Next, as shown in FIG. 61, anisotropic etching is performed on the insulation films 61e and 61a. With this, the insulation film 61e is left on the sidewall of the via hole 63a and the sidewall of the resistor element 54 (that is, the insulation film 61e is left on the sidewall of the recording layer 52), and the insulation film 61e in other areas (that is, at the bottom of the via holes 63a and on the upper electrode film 53 of the resistor element 54) is removed. This etching process on the insulation film 61e and the insulation film 61a can be performed in a manner similar to that of the second dry etching according to the first embodiment. At this time, the insulation film 61a on the upper electrode film 53 is also removed, and at least a part of the upper electrode film 53 is exposed from the via hole 63a. To expose the upper electrode film 53 from the via hole 63a with the insulation films 61e and 61a on the upper electrode film 53 being removed, the insulation films 61e and 61a are preferably made of the same material. In this manner, at least a part of the upper electrode film 53 is exposed from the via hole 63a, and a side-wall insulation film (sidewall, or side-wall spacer) 61f composed of the insulation film 61e is formed on the sidewall of the via hole 63a and the side surface of the resistor element 54.

Here, at the stage before formation of the via holes 63a, the state is such that the insulation film 61a is formed on the entire upper surface of the upper electrode film 53. However, at the time of forming the via holes 63a, the insulation film 61b on the upper electrode film 53 is removed from the via holes 63a. Therefore, after formation of the via holes 63a and the plugs 64a (after manufacturing the semiconductor device), the insulation film 61a is formed on the upper surface of the upper electrode film 53 other than the portion exposed from the via holes 63a and under (below) the insulation film 62.

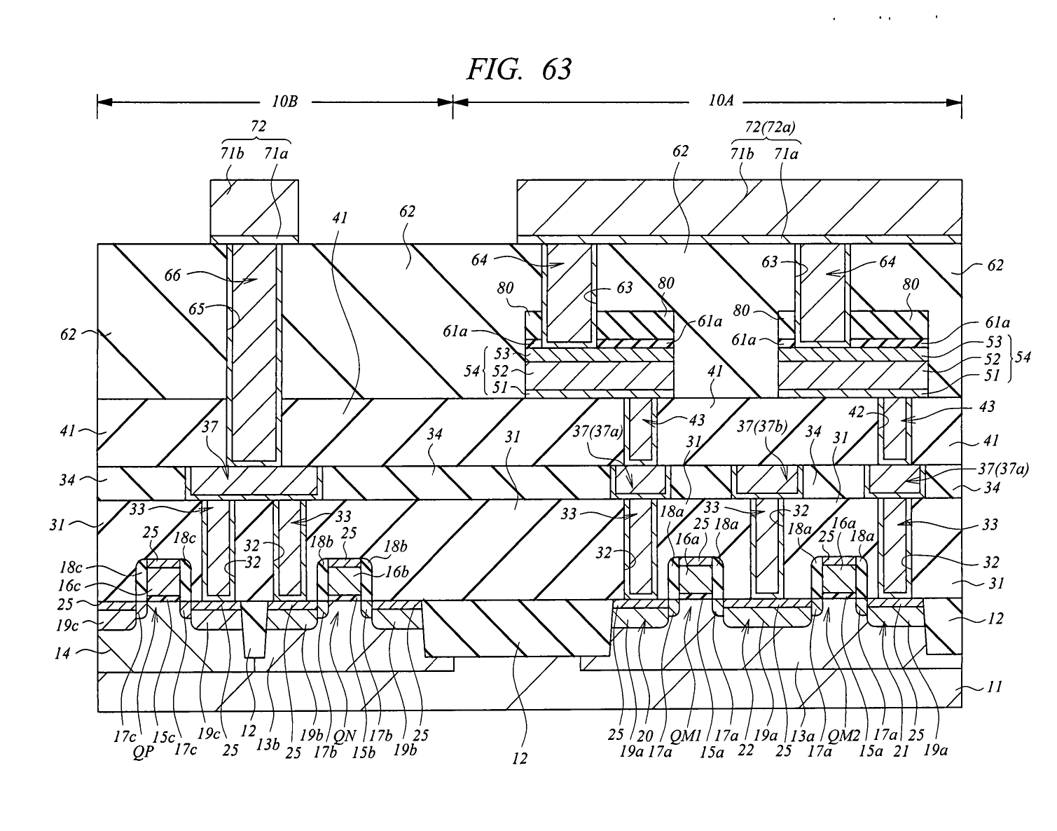

The manufacturing process thereafter is approximately similar to that of the first embodiment. That is, as shown in FIG. 62, the via hole 65 is formed through the insulation films 62 and 41, the plug 64a (corresponding to the above-described plug 64) is formed in each of the via holes 63a and the plug 66 is formed in the via hole 65, and the wiring 72 is formed on the insulation film 62 with plugs 64 and 66 embedded therein.

In the present embodiment, the insulation film 61a as an etching stopper film is formed on the upper surface of the upper electrode film 53 of the resistor element 54. Therefore, as with the first embodiment, it is possible to suppress or prevent the upper electrode film 53 from being thinned at the a part exposed from the via holes 63a, thereby mitigating or solving the first problem described above with reference to the first comparative example shown in FIGS. 23 to 26. That is, in the present embodiment, since the insulation film 61a is used as an etching stopper film, over-etching of the upper electrode film 53 can be prevented. Also, etching damage at the time of dry etching for forming the via holes 63a and heat-load damage at the time of forming the conductive film for the plugs 64a (the conductive barrier film 67a or the tungsten film 67b) can be suppressed. Thus, changes in characteristics of the recording layer 52 in an area immediately under the plugs 64a can be suppressed or prevented, thereby achieving excellent reliability in electrical characteristics of the phase-change memory.

Also, in the present embodiment, the side-wall insulation film 61f is formed on the sidewalls of the recording layer 52 (or the resistor element 54 including the recording layer 52). With this side-wall insulation film 61f on the sidewalls of the recording layer 52 functioning as a protective film, the problem at the time of occurrence of misalignment of the via hole 63a (the above-described second problem) is mitigated or solved.

That is, as shown in FIG. 61, the side-wall insulation film 61f is formed on the sidewall of the resistor element 54 exposed from the via hole 63a, and with this side-wall insulation film 61f preventing the recording layer 52 from being exposed therefrom, the plug 64a is formed in the via hole 63a. Therefore, in the process of forming the conductive barrier film 67a for forming the plug 64a, even if the recording layer 52 becomes at a high temperature, the recording layer 52 is not being exposed, and the side-wall insulation film 61f is present on the sidewall of the recording layer 52 and functions as a protective film, thereby preventing the recording layer 52 from being sublimated. With this, the second problem as described with reference to the second comparative example shown in FIGS. 27 and 28 can be mitigated or solved. In this manner, in the present embodiment, the via hole 63a is formed so as to expose the sidewall of the resistor element 54, but the sidewall of the recording layer 52 is protected by the side-wall insulation film 61f. The material forming the recording layer 52 has a low sublimation temperature, and has a characteristic of being prone to sublimate by heat hysteresis at the time of forming a conductive film for the plug 64a (conductive barrier film 67a). However, with the side-wall insulation film 61f protecting the sidewall of the recording layer 52, sublimation of the recording layer 52 can be suppressed or prevented, thereby making it possible to manufacture a highly-integrated phase-change memory with excellent yields.

In this manner, in the present embodiment, the structure includes the insulation film 61a and the side-wall insulation film 61f on the upper surface of the upper electrode film 53 and the sidewall of the recording layer 52 as an etching stopper film or a protective film. With this, manufacturing yields and reliability of the semiconductor device having a phase-change memory can be improved. Also, variations in driving voltage can be reduced, and the number of rewriting can be improved. As such, the performance of the semiconductor device can be improved.

Also in the present embodiment, the structure is such that the side-wall insulation film 61f is not formed on a side-wall portion of the recording layer 52 other than the sidewall of the recording layer 52 exposed from the via hole 63a due to alignment deviation of the via hole 63a. Since heat load on the order of 400 degrees Celsius occurs even at the time of forming the side-wall insulation film 61f (insulation film 61e), the reliability of the recording layer 52 may possibly be deteriorated, even though slightly. However, in the present embodiment, the side-wall insulation film 61f is not formed on the side-wall portion of the recording layer 52 other than the portion exposed from the via hole 63a. Thus, heat load due to formation of a superfluous side-wall insulation is suppressed, and a highly-integrated phase-change memory with excellent reliability can be manufactured.

Here in the present embodiment, after formation of the via holes 63a, the side-wall insulation film 61f is formed on the sidewall of the recording layer 52, and then the plugs 64a are formed so as to fill these via holes 63a, thereby tolerating misalignment and reducing the plane dimension of the resistor element 54. This reduction of the plane dimension of the resistor element 54 can also be achieved by forming a semiconductor device through the schemes described in the first, fourth, and fifth embodiments, in which the recording layer 52 is prevented from being exposed from the via hole 63 even with misalignment. That is, with the structure including the side-wall insulation film (61, 61d, 61f) on the sidewall of the recording layer 52, the plane dimension of the resistor element 54 can be reduced.

### Seventh Embodiment

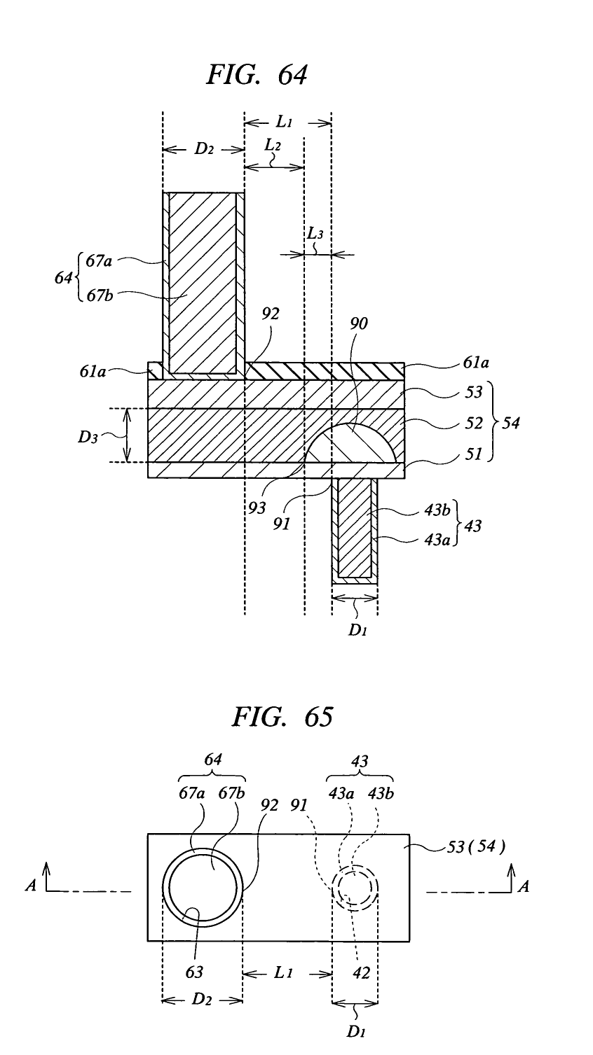

FIG. 63 is a cross-section view of main parts of a semiconductor device according to the present embodiment, and corresponds to FIG. 4 according to the first embodiment. FIG. 64 is a partially-enlarged cross-section view of an area near the resistor element 54 of the semiconductor device of FIG. 63. FIG. 65 is a plan view of main parts of the area near the resistor element 54 of the semiconductor device of FIG. 63. Here, for ease of understanding, FIG. 64 depicts the plug 43, the resistor element 54, the insulation film 61a, and the plug 64, and other components are omitted. Also, FIG. 65 depicts a positional relation (plan layout) among the plug 64, the resistor element 54, and the plug 43, and other components are omitted. Furthermore, FIG. 64 approximately corresponds to a section along an A-A line in FIG. 65.

In the present embodiment, the plug 64 (upper electrode contact) connected to an upper portion of the resistor element 54 (upper electrode film 53) is positioned so as to have an offset relation with the plug 43 (lower electrode plug) electrically connected to a lower portion of the resistor element 54. The structure of the semiconductor device according to the present embodiment other than the positional relation among the plug 64, the resistor element 54, and the plug 43 is approximately similar to that of the second embodiment, and therefore is not described herein. Also, a semiconductor device manufacturing process according to the present embodiment is approximately similar to that of the second embodiment, and therefore is not shown or described herein.

In the present embodiment, as shown in FIGS. 63 to 65, the memory cell structure is such that the plug 64 (upper electrode contact) electrically connected to the upper portion of the resistor element 54 (upper electrode film 53) and the plug 43 (lower electrode plug) electrically connected to the lower portion of the same resistor element 54 (on the lower surface side of the recording layer 52) have an offset relation. Therefore, the plug 64 and the plug 43 connected to the upper portion and the lower portion, respectively, of the same resistor element 54 are disposed so as to be prevented from being two-dimensionally overlaid with each other.

A crystalline/amorphous cycle (change between a crystalline state and an amorphous state) of the recording layer 52 of the phase-change memory occurs near an electrode (plug) having a small diameter or area of base. In the present embodiment, the cylindrically-shaped plugs 43 and 64 are assumed, a diameter D₁ of the plug 43 (lower electrode plug) is smaller than a diameter D₂ of the plug 64 (upper electrode plug) (D₁<D₂), and an area 90 where the crystalline/amorphous cycle of the recording layer 52 (chalcogenide recording material) is formed near the upper portion of the plug 43 (lower electrode plug).

In the present embodiment, the plug 64 and the plug 43 connected to the upper portion and the lower portion, respectively, of the same resistor element 54 are disposed so as to be prevented from being two-dimensionally overlaid with each other therefore, the area 90 where the crystalline/amorphous cycle of the recording layer 52 (chalcogenide recording material) occurs does not exist immediately below the via hole 63 and the plug 64 (upper electrode contact) filling the via hole 63. Therefore, etching damage at the time of dry etching for forming the via holes 63 and heat-load damage at the time of forming the conductive film for the plugs 64 (the conductive barrier film 67a or the tungsten film 67b) can be suppressed or prevented from being exerted on the area 90 where the crystalline/amorphous cycle of the recording layer 52 occurs. Thus, the characteristics of the area 90 where the crystalline/amorphous cycle of the recording layer 52 occurs (chalcogenide characteristics) become less prone to be changed, thereby making it possible to prevent deterioration in reliability of the electrical characteristics. Therefore, the performance and reliability of the semiconductor device having a phase-change memory can be improved. With this, the first problem as described above with reference to the first comparative example shown in FIGS. 23 to 25 can be mitigated.

To prevent the area 90 where the crystalline/amorphous cycle of the recording layer 52 occurs from being disposed immediately below the plug 64, as shown in FIGS. 64 and 65, a distance (distance in a direction parallel to the main surface of the semiconductor substrate 11) L₁ between an end (edge) 91 of the plug 43 (lower electrode plug) and an end (edge) 92 of the plug 64 (upper electrode contact) is preferably equal to or larger than 0 (L₁≧0). Here, as shown in FIG. 65, the end 91 of the plug 43 corresponds to an end positioned to be closest to the plug 64 on the upper surface of the plug 43 when the plugs 43 and 64 are two-dimensionally viewed, whilst the end 92 of the plug 64 corresponds to an end positioned to be closest to the plug 43 on the lower surface of the plug 64 when the plugs 43 and 64 are two-dimensionally viewed. Therefore, the distance L₁ corresponds to a maximum proximity in plane disposition of the plug 43 and the plug 64 connected to the same resistor element 54 (plane disposition when the upper surface of the plug 43 and the lower surface of the plug 64 are projected onto a plane parallel to the main surface of the semiconductor substrate 11). With the distance L₁ being set a value equal to or larger than 0 (L₁≧0), the plugs 64 and 43 connected to the upper portion and the lower portion, respectively, of the same resistor element 54 are not two-dimensionally overlaid with each other.

Also, as shown in FIG. 64, (the plane dimension of) the area 90 where the crystalline/amorphous cycle of the recording layer 52 occurs is larger than (the plane dimension of) the plug 43. Therefore, a distance (distance in a direction parallel to the main surface of the semiconductor substrate 11) L₂ between an end (edge) 93 of the area 90 where the crystalline/amorphous cycle of the recording layer 52 occurs and the end (edge) 92 of the plug 64 (upper electrode contact) is preferably equal to or larger than 0 (L₂≧0). Here, the end 93 of the area 90 corresponds to an end positioned in the area 90 that is closest to the plug 64 when the plug 64 and the area 90 are two-dimensionally viewed.

A distance L₃ between the end 91 of the plug 43 and the end 93 of the area 90 where the crystalline/amorphous cycle of the recording layer 52 occurs is, for example, on the order of ½ of a film thickness D₃ of the recording layer 52 (L₃=D₃/2), and on the order of 20 to 100 nm, for example.

The distance L₁ corresponds to a sum of the distance L₂ and the distance L₃ (L₁=L₂+L₃). Therefore, more preferably, the distance L₁ (maximum proximity of plain disposition of the plugs 43 and 64 connected to the same resistor element 54) is equal to or larger than ½ of the film thickness D₃ of the recording layer 52 (L₁≧D₃/2). With this, the entire area 90 where the crystalline/amorphous cycle of the recording layer 52 occurs can be positioned so as not to be present immediately under the via hole 63 and the plug 64 filling the via hole 63. Thus, etching damage at the time of dry etching for forming the via holes 63 and heat-load damage at the time of forming the conductive film for the plugs 64 can be more reliably prevented from being exerted onto the area 90 where the crystalline/amorphous cycle of the recording layer 52 occurs. Thus, changes in characteristics of the area 90 where the crystalline/amorphous cycle of the recording layer 52 occurs can be more reliably prevented, thereby further improving the electrical characteristics.

Here in the present embodiment, the shape of the plugs 43 and 64 is cylindrical shape, but, needless to say, can be arbitrary.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the first to seventh embodiments, the phase-change memory having memory cells each formed of one storage element (recoding layer 52) made of chalcogenide material and one transistor (MISFET QM1 or QM2) has been mainly described. However, the memory cell structure is not restricted to this. The phase-change memory according to the first to seventh embodiments is rewritable million times or more, and can be manufactured with high yields.

Also, advantageously, the number of rewriting can be further increased by forming a barrier film made of a nitride of a transition metal, such as TiAlN, an oxide, such as Cr—O, or others, near the recording layer 52 of chalcogenide; by using, as a material of the recording layer 52, a chalcogenide-based material having a content of Zn or Cd of 10 atom percents or more and a melting point equal to or higher than 1000 degrees Celsius; by using, as the upper electrode film 53, an alloy film of titanium and tungsten (for example, W80Ti20 (an alloy of 80% of tungsten and 20% of titanium)) or a laminated film of such an alloy and a tungsten film, or others.

Furthermore, as a matter of course, for the purpose of suppressing diffusion of heat required for changing a phase state of chalcogenide, a conductive film with a low thermal conductivity, such as ITO (mixture of oxides of indium and tin), can be interposed between chalcogenide (recording layer) and the upper electrode film.

Still further, needless to say, the present invention can be applied to a solid-electrolyte memory and RRAM (Resistance Random Access Memory), in which the storage element material (material of the recording layer 52) is chalcogenide and a metal oxide, respectively. For a resistance-variable storage element material, its resistance value has to be scaled so as to support the device characteristics required. The present invention is particularly effective when a thin-film upper electrode film has to be used because the resistance value is scaled due to a thinner film thickness of the storage material film.

The present invention is suitable when applied to a semiconductor device including a phase-change memory and a method of manufacturing such a semiconductor device.

1. A semiconductor device comprising:
a semiconductor substrate;
a laminated pattern formed on the semiconductor substrate, the laminated pattern having a recording layer and an upper electrode film on the recording layer;
a first insulation film formed on an upper surface of the upper electrode film;
a second insulation film formed on the semiconductor substrate so as to cover the laminated pattern;
an opening formed on the second insulation film so as to expose at least a part of the upper electrode film; and a conductive portion formed in the opening and electrically connected to the upper electrode film, wherein
the first insulation film is formed on the upper surface of the upper electrode film other than the part exposed from the opening, and below the second insulation film, the first insulation film being thinner than the second insulation film and being made of a material different from a material of the second insulation film.

2. The semiconductor device according to claim 1, wherein
the recording layer is made of a phase-change material with a resistance value varying through heat treatment.

3. The semiconductor device according to claim 1, wherein
the recording layer is formed of a chalcogenide layer.

4. The semiconductor device according to claim 1, wherein
the first insulation film has a film thickness thinner than a film thickness of the upper electrode film.

5. The semiconductor device according to claim 1, wherein
the first insulation film is a film functioning as an etching stopper when dry etching is performed on the second insulation film to form the opening.

6. The semiconductor device according to claim 1, wherein
the first insulation film is formed of a silicon nitride film.

7. The semiconductor device according to claim 1, wherein
the second insulation film is an interlayer insulation film.

8. The semiconductor device according to claim 1, wherein
the upper electrode film is formed of either one of a tungsten film and a tungsten alloy film.

9. The semiconductor device according to claim 1, wherein
the first insulation film is also formed on a sidewall of the recording layer.

10. The semiconductor device according to claim 1, wherein
a third insulation film made of a material different from the material of the second insulation film is formed on a sidewall of the recording layer.

11. The semiconductor device according to claim 10, wherein
the third insulation film is made of a material identical to the material of the first insulation film.

12. The semiconductor device according to claim 1, wherein
the recording layer is a recording layer for information of a phase-change memory.

13-20. (canceled)
